(19) United States
(12) Patent Application Publication
(10) Pub. No.: US 2014/0060643 A1
(43) Pub. Date: Mar. 6, 2014

(54) Light Absorbing Oxide Materials for Photovoltaic and Photocatalytic Applications and Devices

(71) Applicants: Lane W. MARTIN, Champaign, IL (US); Sungki LEE, Urbana, IL (US); Brent A. APGAR, Urbana, IL (US)

(72) Inventors: Lane W. MARTIN, Champaign, IL (US); Sungki LEE, Urbana, IL (US); Brent A. APGAR, Urbana, IL (US)

(21) Appl. No.: 14/018,350

(22) Filed: Sep. 4, 2013

Related U.S. Application Data
(60) Provisional application No. 61/697,158, filed on Sep. 5, 2012.

(51) Int. Cl. B01J 23/83; H01L 31/0264; B01J 23/22; B01J 23/58; B01J 23/34

(52) U.S. Cl. CPC B01J 23/83; B01J 23/58; B01J 23/34; B01J 23/22; H01L 31/0264
USPC 136/256; 502/1

(57) ABSTRACT

Provided are materials, methods and devices for absorption of visible or solar terrestrial electromagnetic radiation. The disclosed materials, methods and devices employ a multi-component oxide material comprising a solar terrestrial light absorbing metallic oxide and a catalytic oxide to achieve conversion of absorbed visible or solar terrestrial electromagnetic radiation into useful work, such as for photocatalytic or photovoltaic applications.

### CROSS REFERENCE TO RELATED APPLICATION

This application claims the benefit of and priority to U.S. Provisional Application 61/697,158, filed on Sep. 5, 2012, which is hereby incorporated by reference in its entirety.

### BACKGROUND

This invention is in the field of light absorbing materials. This invention relates generally to light absorbing oxide composite materials for use in photovoltaic and photocatalytic applications.

Traditional photovoltaic materials typically comprise native semiconductors, such as silicon based single crystal, polycrystalline or thin film type photovoltaic cells. Various other semiconducting materials find use in photovoltaic devices, though their practical utility can be limited, as many semiconductor materials possess a large band gap, limiting their absorption to the ultraviolet region of the electromagnetic spectrum.

Various avenues have been explored for better utilization of the visible region of the electromagnetic spectrum, including enhancing the absorption by the semiconducting materials through use of light absorbing dyes and quantum dot technology. There remains, however, a need for enhanced light-absorbing systems.

### SUMMARY

The present invention provides a solar terrestrial light absorbing composite, useful, for example, in photovoltaic and photocatalytic applications. The solar terrestrial light absorbing composites described herein include all oxide composites. One benefit of using oxides as the active materials for these composites is that the composites exhibit excellent stability. The oxide materials are stable when exposed to oxidizing environments, such as air and water. Little or no degradation to the materials occurs during the formation and processing of the material due to exposure to air. This provides a substantial enhancement over traditional materials where oxygen is an undesirable component, for example, because the formation of insulating oxide layers over active photocatalyst or photovoltaic materials, such as silicon, when exposed to air can degrade, diminish or otherwise render the photocatalyst or photovoltaic materials useless without additional processing or refinement.

The use of all oxide materials provides additional benefits relating to the performance of the composites. In traditional photocatalysts and photovoltaics where oxides are not used as active materials, when two materials meet at an interface diffusion can occur between the materials, resulting in the unwanted presence of the diffused material in active components of the photocatalysts and photovoltaics. This can also occur when only one material is an oxide. Often, such diffusion results in degraded performance. The all oxide composites described herein are not detrimented in this way, because the oxide materials comprising the active components are typically stable and exhibit no or only minimal diffusion when placed at an interface.

In one aspect, provided is a solar terrestrial light absorbing composite. In a specific embodiment, a solar terrestrial light absorbing composite of this aspect comprises a chemically-stable catalytic oxide structure; and a solar terrestrial light absorbing conductive metallic oxide structure positioned in contact with the chemically-stable catalytic oxide structure. In embodiments, absorption of electromagnetic radiation, such as solar terrestrial electromagnetic radiation or visible electromagnetic radiation, by the solar terrestrial light absorbing conductive metallic oxide structure forms charge carriers in the solar terrestrial light absorbing conductive metallic oxide structure that are transferred to the chemically-stable catalytic oxide structure. In embodiments, absorption of electromagnetic radiation, such as solar terrestrial electromagnetic radiation or visible electromagnetic radiation, by the solar terrestrial light absorbing conductive metallic oxide structure forms charge carriers of sufficient energy for transfer of the charge carriers to the chemically-stable catalytic oxide structure. In embodiments, a chemically-stable catalytic oxide structure comprises a layer, a crystal, a crystallite or another amount or region of chemically-stable catalytic oxide molecules. In embodiments, a solar terrestrial light absorbing conductive metallic oxide structure comprises a layer, a crystal, a crystallite or another amount or region of solar terrestrial light absorbing conductive metallic oxide molecules, materials or solutions, such as solid solutions.

Absorption of solar terrestrial or visible electromagnetic radiation by the solar terrestrial light absorbing conductive metallic oxide structure is advantageous, for example, as this provides a way to utilize a wide range of electromagnetic energies to perform useful work, such as by creating a photovoltage or a photocurrent or to provide energy for oxidation of, for reduction of or for producing radical species from a variety of chemical species. In embodiments, absorption of electromagnetic radiation having a wavelength between 280 nm and 1000 nm, between 380 and 800 nm or between 400 and 760 nm by the solar terrestrial light absorbing conductive metallic oxide structure forms photo-excited charge carriers. In embodiments, absorption of electromagnetic radiation having a wavelength between 280 nm and 1000 nm, between 380 and 800 nm or between 400 and 760 nm by the solar terrestrial light absorbing conductive metallic oxide structure forms hot-carriers that are injected to the chemically-stable catalytic oxide from the solar terrestrial light absorbing conductive metallic oxide structure.

In embodiments, the solar terrestrial light absorbing conductive metallic oxide structure is strongly absorbing and weakly reflecting in the visible region of the electromagnetic spectrum. In a specific embodiment, a solar terrestrial light absorbing composite is a visible light absorbing composite. In embodiments, the solar terrestrial light absorbing conductive metallic oxide structure is a visible light absorbing conductive metallic oxide structure. Useful solar terrestrial light absorbing conductive metallic oxide structures include those having an absorption coefficient greater than 1.0×10⁴ cm⁻¹, greater than 0.5×10⁵ cm⁻¹, greater than 1.0×10⁵ cm⁻¹, greater than 1.5×10⁵ cm⁻¹ or between 0.5×10⁵ cm⁻¹ and 4.0×10⁵ cm⁻¹ for electromagnetic radiation having wavelengths between 280 nm and 1000 nm, between 380 nm and 800 nm or between 400 nm and 760 nm. Useful solar terrestrial light absorbing conductive metallic oxide structures include those having a reflectance less than 50%, less than 40% or less than 25% for electromagnetic radiation having wavelengths between 280 nm and 1000 nm, between 380 nm and 800 nm or between 400 nm and 760 nm. Optionally, the solar terrestrial light absorbing conductive metallic oxide structure has an absorption coefficient greater than 1.0×10⁴ cm⁻¹, greater than 0.5×10⁵ cm⁻¹, greater than 1.0×10⁵ cm⁻¹, greater than 1.5×10⁵ cm⁻¹ or between 0.5×10⁵ cm⁻¹ and 4.0×10⁵ cm⁻¹ for at least some wavelengths of electromagnetic radiation between 280 nm and 1000 nm, between 380 nm and 800 nm or between 400 nm and 760 nm. Optionally, the solar terrestrial light absorbing conductive metallic oxide structures comprises a film having a thickness of 25 nm or less or 25 nm or greater and an absorbance greater than 25%, or a film having a thickness of 50 nm or less or 50 nm or greater and an absorbance greater than 30%, a film having a thickness of 100 nm or less or 100 nm or greater and an absorbance greater than 65%, where the absorbance refers to electromagnetic radiation having wavelengths between 280 nm and 1000 nm, between 380 nm and 800 nm or between 400 nm and 760 nm. Optionally, the solar terrestrial light absorbing conductive metallic oxide structures comprises a film having a thickness of 25 nm or less or 25 nm or greater and an absorbance greater than 25%, or a film having a thickness of 50 nm or less or 50 nm or greater and an absorbance greater than 40%, or a film having a thickness of 100 nm or less or 100 nm or greater and an absorbance greater than 60%, where the absorbance refers to AM1.5G solar spectrum radiation having wavelengths between 280 nm and 1000 nm, between 380 nm and 800 nm or between 400 nm and 760 nm.

In embodiments, the solar terrestrial light absorbing conductive metallic oxide structure is a conducting material. For example, in embodiments, the solar terrestrial light absorbing conductive metallic oxide structure has a carrier concentration greater than 10²⁰ cm⁻³, greater than 10²¹ cm⁻³ or greater than 10²² cm⁻³. Optionally, the solar terrestrial light absorbing conductive metallic oxide structure has a room temperature resistivity less than 2000 μΩ-cm, less than 1500 μΩ-cm, less than 500 μΩ-cm, less than 400 μΩ-cm or less than 300 μΩ-cm. In various embodiments, the solar terrestrial light absorbing conductive metallic oxide structure has a room temperature carrier mobility selected from the range of 0.1 to 10 cm²V⁻¹ s⁻¹, selected from the range of 0.15 to 7 cm² V⁻¹ s⁻¹ or selected from the range of 0.2 to 2 cm² V⁻¹ s⁻¹.

The electronic properties of the solar terrestrial light absorbing composite are optionally selected to provide beneficial or advantageous materials for a specific application, such as a photovoltaic or photocatalytic application. For example, in some embodiments, the solar terrestrial light absorbing conductive metallic oxide structure comprises one or more dopants selected from the group consisting of an alkali metal, an alkaline earth metal, a transition metal, a rare earth metal, a group III element, a group IV element, a group V element, a group VI element and a group VII element. In some embodiments, the solar terrestrial light absorbing conductive metallic oxide structure comprises a p-type material, such as an undoped p-type material or a p-type material achieved by including one or more dopants. In some embodiments, the solar terrestrial light absorbing conductive metallic oxide structure comprises an n-type material, such as an undoped n-type material or an n-type material achieved by including one or more dopants.

In embodiments, the chemical composition of the solar terrestrial light absorbing conductive metallic oxide structure is selected to provide beneficial or advantageous properties for a specific application, such as a photovoltaic or photocatalytic application. Useful solar terrestrial light absorbing conductive metallic oxide structures include, but are not limited to, those comprising binary metal oxide, a ternary metal oxide, a quarternary metal oxide or a greater metal oxide. Optionally, the solar terrestrial light absorbing conductive metallic oxide structures comprises a metal oxide selected from the group consisting of RuO₂, IrO₂, a vanadium oxide, Fe₃O₄, PbO, FeO, SrO, NiO, MnO₂, Mn₂O₃ and any combination of these. Useful solar terrestrial light absorbing conductive metallic oxide structures include, but are not limited to, those comprising a metal oxide having a formula Aₘ₊₁MₘO₃ₘ₊₁, AMO₃ or A′_{y}A″_{y-1} MO₃, where A, A′ and A″ are independently an alkali metal, an alkaline earth metal, a rare earth metal or a transition metal, where M is a transition metal, such as Mn, V, Ti, Cu, Cr, Fe, Co, Ni, Zn, Zr, Nb, Mo, Tc, Ru, or Rh, where m is an integer greater than or equal to 1 and where 0≦y≦1. For embodiments where y is equal to 0 or 1, such a composition is equivalent to A″MO₃ or A′MO₃, respectively. Optionally, each of A, A′ and A″ are independently metals including, but not limited to Na, K, Ca, Sr, La, Ba, Bi, Pr, Nd, Sm, Gd or Y. In a specific embodiment, the solar terrestrial light absorbing conductive metallic oxide structure comprises a metal oxide including, but not limited to, one or more of SrRuO₃, LaNiO₃, SrVO₃, La_{0.7}Sr_{0.3}MnO₃, La_{0.5}Sr_{0.5}CoO₃, La₁₋ₓSrₓMnO₃, La₁₋ₓSrₓCoO₃, where 0≦x≦1 and any materials derived from these. In embodiments, the solar terrestrial light absorbing conductive metallic oxide structure comprises a metal oxide including, but not limited to, one or more of CaₓSrₓ₋₁RuO₃, Ca₂₋ₓSrₓRuO₄, La₁₋ₓCaₓMnO₃, CaₓSrₓ₋₁VO₃, LaₓSrₓ₋₁VO₃, LaₓSrₓ₋₁NiO₃, Sr₁₋ₓNbO₃, LaₓSr₁₋ₓTiO₃, LaₓSrₓ₋₁CuO₃, LaₓSrₓ₋₁Mn_{y}Co_{1-y}O₃, SrFeO₃, CoₓNi₁₋ₓFeO₄, NiₓMg₁₋ₓFe₂O₄, ZnₓFe₁₋ₓO, SrTiO₃, La₂ₓSr₂₋₂ₓTiO₅, La₂ₓSr₂₋₂ₓTi₃O₉, La₂ₓSr₂₋₂ₓTi₂O₇, Sr₃Ti₂O₇, PbTiO₃, Sm₂Ti₂S₂O₅, K_{2-x-y}RbₓCs_{y}La₂Ti₃O₁₀, PbBi₄Ti₄O₁₅, BaTi₄O_{g}, K_{2-x-y}RbₓNa_{y}Ti₆O₁₃, La₄CaTi₅O₁₇, TiₓZr_{1.x}(PO₄)₄, Rb₄ₓK₄₋₄ₓTaₘNb₆₋ₘO₁₇, Li_{1-x-y}NaₓKₓTaO₃, La_{1/3}TaO₃, InTaO₄, Sr_{1-x-y}BaₓSn_{y}Ta₂O₆, Ni_{1-x-y}MnₓCo_{y}Ta₂O₆, Cr₁₋ₓFeₓTaO₄, Ca₂Ta₂O₇, BiLa₁₋ₓYₓTaO₇, Sr₂₋₂ₓLa₂ₓTa₂O₇, H₂₋₂ₓK₂ₓLa_{2/3}Ta₂O₇, H₂SrTa₂O₇, K₂Sr_{1.5}Ta₃O₁₀, KBa₂Ta₃O₁₀, Sr₄₋₄ₓBa₄ₓTa₂O₉, Sr₅₋₅ₓBa₅ₓTa₄O₁₅, K₃Ta₃Si₂O₁₃, K₃Ta₃B₂O₁₂, Y_{3-x-y}YbₓGd_{y}TaO₇, LnTaO₄ (where Ln is La, Ce, Pr, Nd or Sm), RbLnTa₂O₇ (where Ln is La, Pr, Nd or Sm), M₄Nb₆O₁₇ (where M is K or Rb) and K₄Nb₆O₁₇—TiO₂ intercalated, where 0≦x≦1 and where 0≦y≦1.

In a specific embodiment, the solar terrestrial light absorbing conductive metallic oxide structure comprises one or more of SrRuO₃, LaNiO₃, SrVO₃, La_{0.7}Sr_{0.3}MnO₃, La_{0.5}Sr_{0.5}CoO. In a specific embodiment, the solar terrestrial light absorbing conductive metallic oxide structure comprises a solar terrestrial light absorbing correlated metal oxide or a solar terrestrial light absorbing correlated metallic oxide.

In embodiments, the crystal structure or orientation of the solar terrestrial light absorbing conductive metallic oxide structure is selected to provide beneficial or advantageous properties for a specific application, such as a photovoltaic or photocatalytic application. In one embodiment, the solar terrestrial light absorbing conductive metallic oxide structure is an epitaxial-oriented film, a (001)-oriented film, a (110)-oriented film, a (111)-oriented film or other epitaxially oriented film. In some embodiments, the solar terrestrial light absorbing conductive metallic oxide structure is a non-epitaxial film, a polycrystalline film or an amorphous film. In some embodiments, the solar terrestrial light absorbing conductive metallic oxide structure comprises a metal or metallic oxide having a perovskite structure, such as a transition metal-based perovskite. Optionally, the solar terrestrial light absorbing conductive metallic oxide structure comprises a metal oxide having a perovskite structure selected from the group consisting of a ruthenium-based perovskite, a manganese-based perovskite, a cobalt-based perovskite, a vanadium-based perovskite, a nickel-based perovskite, a niobium-based perovskite, a titanium-based perovskite and any combination of these. In some embodiments, the solar terrestrial light absorbing conductive metallic oxide structure comprises a metal or metallic oxide having a non-perovskite structure. In some embodiments, the solar terrestrial light absorbing conductive metallic oxide structure comprises a metal or metallic oxide having a pyrochlore structure having a formula A₂BO₇, a wüstite structure having a formula AₓB₁₋ₓO, a magnetite structure having a formula A₂ₓB₂₋₂ₓO₃, a layered perovskite structure having a formula AₘBₘO₃ₘ₊₂, AₘBₘ₋₁O₃ₘ, A_{m/2}BₘO₃ₘ₊₁ or AₘBₘ₋₁O₃ₘ₊₂, a Dion-Jacobsen structure having a formula A[Bₘ₋₁CₘO₃ₘ₊₁], a Ruddlesden-Popper structure having a formula A₂[Bₘ₋₁CₘO₃ₘ₊₁] or Bₘ₋₁CₘO₃ₘ₊₁, an Aurivillius structure having a formula (Bi₂O₂)₂+[Bₘ₋₁CₘO₃ₘ₊₁]²⁻, a Columbite structure having a formula AB₂O₆, a Brownmillerite structure having a formula A₂B₂₋₂ₓC₂ₓO₅ or a Ilmenite structure having a formula ABO₃, wherein A, B and C are independently an alkali metal, an alkaline earth metal, a rare earth metal or a transition metal and wherein m is an integer greater than or equal to 1; and wherein 0≦x≦1. In some embodiments, the solar terrestrial light absorbing conductive metallic oxide structure comprises a metal or metallic oxide having an oxypnictide structure, such as a metal oxide comprising LaOₓF₁₋ₓFeAs, LaOₓF₁₋ₓFeAs, CeFeAsOₓF₁₋ₓ, SmFeAsOₓF₁₋ₓ, LaₓY₁₋ₓFeAsO_{y}, NdFeAsOₓF₁₋ₓ, PrFeAsOₓF₁₋ₓ, GdFeAsOₓ or SmFeAsOₓ, wherein 0≦x≦1 and wherein 0≦y≦1. Optionally, the solar terrestrial light absorbing conductive metallic oxide structure comprises a cuprate superconducting oxide, such as, but not limited to, a YBa₂Cu₃O₇ type superconductor, a Bi₂Sr₂Ca₂Cu₃O₁₀ type superconductor or a HgBa₂Ca₂Cu₃O₈ type superconductor.

As with the solar terrestrial light absorbing conductive metallic oxide structure, the properties and chemical composition of the chemically-stable catalytic oxide structure are, in embodiments, selected to advantageously benefit the use in a specific application. For example, in embodiments, the chemically-stable catalytic oxide structure component of the solar terrestrial light absorbing composite does not significantly absorb electromagnetic radiation having wavelengths between 280 nm and 1000 nm, does not significantly absorb electromagnetic radiation having wavelengths between 380 nm and 800 nm or does not significantly absorb electromagnetic radiation having wavelengths between 400 nm and 760 nm. Optionally, the chemically-stable catalytic oxide structure is transparent to at least some wavelengths of electromagnetic radiation between 280 nm and 1000 nm or is transparent to at least some wavelengths of electromagnetic radiation between 380 nm and 800 nm or between 400 nm and 760 nm, such as when provided as a thin film. In a specific embodiment, the chemically-stable catalytic oxide structure has an absorption coefficient less than 10³ cm⁻¹ for at least some wavelengths of electromagnetic radiation between 280 nm and 1000 nm, for at least some wavelengths of electromagnetic radiation between 400 nm and 1000 nm, for at least some wavelengths of electromagnetic radiation between 380 nm and 800 nm or for at least some wavelengths of electromagnetic radiation between 400 nm and 760 nm. Transparent chemically-stable catalytic oxide structures are useful to minimize blocking of visible or solar terrestrial electromagnetic radiation from an underlying solar terrestrial light absorbing conductive metallic oxide structure.

In embodiments, the chemically-stable catalytic oxide structure comprises a metal oxide. Optionally, the chemically-stable catalytic oxide structure comprises a metal nitride or a metal oxide in which a portion of the oxide component is replaced by a nitride component. Useful chemically-stable catalytic oxide structures include, but are not limited to, those comprising a metal oxide selected from the group consisting of: an alkali metal oxide, an alkaline earth metal oxide, a transition metal oxide, a rare-earth metal oxide and any combination of these. Optionally, the chemically-stable catalytic oxide structure comprises a binary metal oxide, such as a metal oxide selected from the group consisting of: TiO₂, ZnO, Cu₂O, CuO, Fe₂O₃, CaO, MgO, La₂O₃, Ta₂O₅, PbO, SnO₂, Bi₂O₃, WO₃, CeO₂, In₂O₃, Nb₂O₅, SiO₂, Al₂O₃, ZrO₂, Cr₂O₃, Ga₂O₃, BaO and any combination of these. In specific embodiments, the chemically-stable catalytic oxide structure comprises titanium dioxide or anatase titanium dioxide.

In embodiments, the crystal structure or orientation of the chemically stable catalytic oxide structure is selected to provide beneficial or advantageous properties for a specific application, such as a photovoltaic or photocatalytic application. Optionally, the chemically-stable catalytic oxide structure comprises a metal oxide having a perovskite structure, such as a metal oxide having a transition metal-based perovskite structure or a metal oxide having a perovskite structure selected from the group consisting of: a titanium-based perovskite, a tantalum-based perovskite, a niobium-based perovskite, an iron-based perovskite, a cobalt-based perovskite, a chromium-based perovskite, a nickel-based perovskite, a manganese-based perovskite, a vanadium-based perovskite, a zirconium-based perovskite, a zinc-based perovskite and any combination of these. In embodiments, the chemically-stable catalytic oxide structure comprises a metal oxide having a non-perovskite structure. In embodiments, the chemically-stable catalytic oxide structure comprises a metal oxide having a pyrochlore structure having a formula A₂BO₇, a wüstite structure having a formula AₓB₁₋ₓO, a magnetite structure having a formula A₂ₓB₂₋₂ₓO₃, a layered perovskite structure having a formula AₘBₘO₃ₘ₊₂, AₘBₘ₋₁O₃ₘ, A_{m/2}BₘO₃ₘ₊₁ or AₘBₘ₋₁O₃ₘ₊₂, a Dion-Jacobsen structure having a formula A[Bₘ₋₁CₘO₃ₘ₊₁], a Ruddlesden-Popper structure having a formula A₂[Bₘ₋₁CₘO₃ₘ₊₁] or Bₘ₋₁CₘO₃ₘ₊₁, an Aurivillius structure having a formula (Bi₂O₂)₂+[Bₘ₋₁CₘO₃ₘ₊₁]²⁻, a Columbite structure having a formula AB₂O₆, a Brownmillerite structure having a formula A₂B₂₋₂ₓC₂ₓO₆ or a Ilmenite structure and having a formula ABO₃, or wherein A, B and C are independently an alkali metal, an alkaline earth metal, a rare earth metal or a transition metal and wherein m is an integer greater than or equal to 1; and wherein 0≦x≦1. In embodiments, the chemically-stable catalytic oxide structure comprises a pucherite, dreyerite, clinobisvanite type, NaClO₄-type structure, anhydrite, barite, AgMnO₄-type structure, Scheelite, CsIO₄-type structure, crocoite, monazite, selenite-anhydrite, zircon, quartz-analog, BPO₄-type structure, AlPO₄-type structure, rutile-analog, berlinite, stibiotantalite, MgWO₄-type structure, zirconia-analog, BaUO₄-type structure, CaUO₄-type structure, vorlanite, or a fluorite-analog type metal oxide having a formula ABO₄, wherein A and B are independently an alkali metal, an alkaline earth metal, a rare earth metal or a transition metal.

In embodiments, the chemically-stable catalytic oxide structure comprises a trirutile-type oxide, NiAs-type oxide, CdI₂-type oxide, Rosiaite-type oxide, Tl₂TeO₆-type, MnSb₂O₆-type oxide, ZnTa₂O₆-type oxide, α-PbO₂-type oxide, columbite, CoSb₂O₆, CoTa₂O₆, ReCr₂O₆, where Re is a rare earth element, CrTa₂O₆, TeCr₂O₆, Cr₂WO₆, CuSb₂O₆, FeTa₂O₆, TeFe₂O₆, TeMn₂O₆, MoRh₂O₆, NiSb₂O₆, NiTa₂O₆, URh₂O₆, VTa₂O₆, WV₂O₆ or a rutile-analog type metal oxide having a formula AB₂O₆, wherein A and B are independently an alkali metal, an alkaline earth metal, a rare earth metal or a transition metal.

In embodiments, the chemically-stable catalytic oxide structure comprises a metal oxide semiconductor. Useful semiconductors for the chemically-stable catalytic oxide structure comprise those having a band gap greater than or equal to 1.0 eV, greater than or equal to 2.0 eV, greater than or equal to 3.0 eV or selected from the range of 3.0 eV to 4.0 eV. Optionally, the chemically-stable catalytic oxide structure comprises a p-type material, such as an undoped p-type material or a p-type material achieved by including one or more dopants. Optionally, the chemically-stable catalytic oxide structure comprises an n-type material, such as an undoped n-type material or an n-type material achieved by including one or more dopants. In some embodiments, the chemically-stable catalytic oxide structure comprises a material that makes an electronic contact with the solar terrestrial light absorbing conductive metallic oxide structure that is ohmic in nature, Schottky in nature or flat band. In some embodiments, the chemically-stable catalytic oxide structure has a carrier concentration less than 10¹⁸ cm⁻³ or less than 10¹⁷ cm⁻³. Optionally, the chemically-stable catalytic oxide structure comprises one or more dopants selected from the group consisting of an alkali metal, an alkaline earth metal, a transition metal, a rare earth metal, a group III element, a group IV element, a group V element, a group VI element and a group VII element.

Optionally, the properties of both the solar terrestrial light absorbing conductive metallic oxide structure and the chemically-stable catalytic oxide structure are simultaneously selected to advantageously benefit the use in a specific application. For example, in one embodiment, the chemically-stable catalytic oxide structure has a carrier concentration less than 10¹⁸ cm⁻³ or less than 10¹⁷ cm⁻³ and the solar terrestrial light absorbing conductive metallic oxide structure has a carrier concentration greater than 10²⁰ cm⁻³, greater than 10²¹ cm⁻³ or greater than 10²² cm⁻³. In embodiments, a ratio of a carrier concentration greater of the conductive metallic oxide to a carrier concentration of the chemically-stable catalytic oxide is 10 or more, 100 or more, 1000 or more, 10000 or more, 100000 or more or 1000000 or more. In embodiments, such a combination of carrier concentrations results in full or partial depletion of at least a portion of the chemically-stable catalytic oxide, such as a portion adjacent to a junction between the solar terrestrial light absorbing conductive metallic oxide and the chemically-stable catalytic oxide. In embodiments, achieving full or partial depletion of at least a portion of the chemically-stable catalytic oxide is dependent upon the ratio of carrier concentrations of the solar terrestrial light absorbing conductive metallic oxide to the chemically-stable catalytic oxide and the thicknesses of the chemically-stable catalytic oxide and the solar terrestrial light absorbing conductive metallic oxide.

In embodiments, a built-in electric field is present between the solar terrestrial light absorbing conductive metallic oxide structure and the chemically-stable catalytic oxide structure. In other embodiments, no built-in electric field is present between the solar terrestrial light absorbing conductive metallic oxide structure and the chemically-stable catalytic oxide structure. The presence of a built-in electric field is optionally provided by selecting suitable identities for the solar terrestrial light absorbing conductive metallic oxide structure and the chemically-stable catalytic oxide structure, such as identities based on the work function of the solar terrestrial light absorbing conductive metallic oxide structure and energy separation between the Fermi state and the vacuum level of the chemically-stable catalytic oxide structure (the E_{F} of the chemically-stable catalytic oxide structure).

In embodiments, the solar terrestrial light absorbing conductive metallic oxide structure and the chemically-stable catalytic oxide structure are selected such that the solar terrestrial light absorbing composite comprises a heterojunction, such as a multilayer heterojunction, a Schottky junction or an ohmic junction. In specific embodiments, the solar terrestrial light absorbing composite comprises an n-n Schottky junction, an n-n ohmic junction, a p-n Schottky junction or a p-n ohmic junction. Optionally, a Schottky barrier height between the chemically-stable catalytic oxide and the solar terrestrial light absorbing conductive metallic oxide structure is greater than 0 eV, greater than 0.5 eV or greater than 1.0 eV, less than 0.5 eV or less than 1.0 eV.

In embodiments, the physical dimensions, structure and component thicknesses of the solar terrestrial light absorbing composite are selected so as to impart beneficial properties advantageous for a specific application. For example, in embodiments, the solar terrestrial light absorbing composite comprises a powder, a bilayer film, a membrane attached directly or indirectly to a fabric or a building material, a core-shell material, a core-shell nanomaterial, a coated nanowire material or a core-shell nanowire material. In embodiments, the solar terrestrial light absorbing conductive metallic oxide structure has a physical dimension selected from between 1 nm and 10 μm, selected from between 1 and 100 nm, selected from between 5 nm and 50 nm or selected from between 10 nm and 20 nm. Optionally, the solar terrestrial light absorbing conductive metallic oxide structure comprises crystals or crystallites having a physical dimension selected from between 1 nm and 10 μm, selected from between 1 and 100 nm, selected from between 5 nm and 50 nm or selected from between 10 nm and 20 nm. In embodiments, the chemically-stable catalytic oxide structure has a physical dimension selected from between 1 nm and 10 μm, selected from between 1 and 100 nm, selected from between 5 nm and 50 nm or selected from between 10 nm and 20 nm. Optionally, the chemically-stable catalytic oxide structure comprises crystals or crystallites having a physical dimension selected from between 1 nm and 10 μm, selected from between 1 and 100 nm, selected from between 5 nm and 50 nm or selected from between 10 nm and 20 nm.

In specific embodiments, the solar terrestrial light absorbing composite comprises a multilayer film. In an embodiment, a first layer of the multilayer film comprises the solar terrestrial light absorbing conductive metallic oxide structure and a second layer of the multilayer film comprises the chemically-stable catalytic oxide structure. Optionally, the first layer has a thickness selected from between 0.1 nm and 1000 nm, selected from between 1 nm and 500 nm, selected from between 5 nm and 100 nm, selected from between 10 nm and 50 nm or selected from between 100 nm and 300 nm. Optionally, the second layer has a thickness selected from between 0.1 nm and 10000 nm, selected from between 1 nm and 500 nm, selected from between 5 nm and 100 nm, selected from between 10 nm and 50 nm or selected from between 100 nm and 300 nm. In embodiments, the multilayer film further comprising one or more additional layers each independently in contact with one or both of the first layer and the second layer. In embodiments, an additional layer comprises a substrate layer. In embodiments, an additional layer comprises an electrode layer. Optionally, a multilayer film comprises a plurality of layers of different solar terrestrial light absorbing conductive metallic oxide structures positioned beneath a layer of the chemically-stable catalytic oxide structure.

In embodiments, the solar terrestrial light absorbing composites described above are useful in a variety of applications. For example, in an embodiment, the solar terrestrial light absorbing composite is used as a photocatalytic material. For example, in an embodiment, the solar terrestrial light absorbing composite is used as a photovoltaic material or in a photovoltaic device. For example, in an embodiment, the solar terrestrial light absorbing composite is used in organic chemical synthesis. For example, in an embodiment, the solar terrestrial light absorbing composite is used in organic chemical decomposition. For example, in an embodiment, the solar terrestrial light absorbing composite is used in solar fuel synthesis. For example, in an embodiment, the solar terrestrial light absorbing composite is used for air cleaning. For example, in an embodiment, the solar terrestrial light absorbing composite is used as an antibacterial, antiviral or in sterilization. For example, in an embodiment, the solar terrestrial light absorbing composite is used as a self-cleaning material. For example, in an embodiment, the solar terrestrial light absorbing composite is used in water splitting.

In an exemplary embodiment, the solar terrestrial light absorbing composite is used in a photochemical synthesis process. For example, the solar terrestrial light absorbing composite is optionally used to provide energy to an endothermic reaction, whereby higher energy reaction products are created from lower energy starting materials. In embodiments, energy is provided for a reaction by way of absorption of electromagnetic radiation by the solar terrestrial light absorbing conductive metallic oxide structure followed by transfer of charge carriers to the chemically-stable catalytic oxide structure, where the charge carriers can subsequently participate in a chemical reaction. In this way, for example, the solar terrestrial light absorbing composite provides benefits via alternative synthetic routes, the ability to use reduced cost feedstocks, the ability to reduce the number of synthetic steps to create a chemical reaction product, or the ability to reduce the energy required to create a chemical reaction product, particularly when compared with conventional chemical synthesis that starts with high energy feedstocks or that require high energy input. In embodiments, the solar terrestrial light absorbing composite also provides for the ability to use energy from solar terrestrial electromagnetic radiation to drive chemical reactions without the need to resort to exposing chemical reactants to ultraviolet electromagnetic radiation which can potentially result in unwanted side reactions or degradation of the chemical reactants. In another embodiment, the solar terrestrial light absorbing composite is optionally used to drive an exothermic reaction.

In an exemplary embodiment, the solar terrestrial light absorbing composite is used in a gas separation process, such as in a carbon sequestration process, in a high efficiency gas turbine or in a fuel cell. In embodiments, a solar terrestrial light absorbing composite is used to cleave gas phase molecules, such as O₂, into atomic and/or ionic components which are transported through at least a portion of the solar terrestrial absorbing composite, an ionic conductor, a membrane or a surface to facilitate separation. The use of the solar terrestrial absorbing composites provides benefits by increasing the availability of low cost and low energy separation routes that would otherwise require substantial energy input, via mechanical energy, electrical energy or high energy electromagnetic radiation, such as ultraviolet electromagnetic radiation. In embodiments, energy is provided for the molecular cleavage by way of absorption of electromagnetic radiation by the solar terrestrial light absorbing conductive metallic oxide structure followed by transfer of charge carriers to the chemically-stable catalytic oxide structure, where the charge carriers can subsequently be utilized in molecular cleavage. Once separated, in embodiments, the atomic or ionic substitutes are optionally used in a chemical reaction, such as in a molecular recombination reaction, for example where oxygen atoms or ions are recombined to form O₂ gas, where heat released by the recombined or formed gas phase molecules could benefit diffusion of the gas phase molecules away from the surface of the solar terrestrial absorbing composite, membrane or ionic conductor. In further embodiments, additional reactions can take place by controlling incoming electromagnetic radiation to drive energetically favorable reactions, such as in the case of oxygen, by controlling the amount of ultraviolet electromagnetic radiation, the fraction of ozone, NOx or other products can be controlled.

In another aspect, provided are photovoltaic devices. In embodiments, a photovoltaic device comprises a solar terrestrial absorbing composite, such as described above. In a specific embodiment, a photovoltaic device of this aspect comprises a substrate; a solar terrestrial light absorbing conductive metallic oxide layer provided over at least a portion of the substrate; a chemically-stable catalytic oxide layer provided over and in contact with at least a portion of the solar terrestrial light absorbing conductive metallic oxide layer; and a transparent conducting electrode layer provided over and in contact with at least a portion of the chemically-stable catalytic oxide layer. In embodiments, absorption of electromagnetic radiation, such as visible or solar terrestrial electromagnetic radiation, by the solar terrestrial light absorbing conductive metallic oxide layer forms charge carriers in the solar terrestrial light absorbing conductive metallic oxide layer that are transferred to the chemically-stable catalytic oxide layer. In embodiments, absorption of visible or solar terrestrial electromagnetic radiation by the solar terrestrial light absorbing conductive metallic oxide layer forms charge carriers of sufficient energy for subsequent transfer of the charge carriers to the chemically-stable catalytic oxide layer. In embodiments, absorption of electromagnetic radiation having a wavelength between 280 nm and 1000 nm, between 380 nm and 800 nm or between 400 nm and 760 nm by the solar terrestrial light absorbing conductive metallic oxide layer forms photo-excited charge carriers. Optionally, absorption of electromagnetic radiation having a wavelength between 280 nm and 1000 nm, between 380 nm and 800 nm or between 400 nm and 760 nm by the solar terrestrial light absorbing conductive metallic oxide layer forms hot-carriers that are injected to the chemically-stable catalytic oxide layer from the solar terrestrial light absorbing conductive metallic oxide layer.

As described above with respect to the solar terrestrial absorbing composite, selection of the chemical composition, optical properties, electrical properties, structural orientation and physical dimensions for specific photovoltaic device embodiments can achieve beneficial advantages. In a specific embodiment, for example, the solar terrestrial light absorbing conductive metallic oxide layer has a thickness selected from the range of 0.1 nm to 1000 nm, selected from the range of 5 nm to 250 nm or selected from the range of 10 nm to 100 nm. In a specific embodiment, the chemically-stable catalytic oxide layer has a thickness selected from the range of 0.1 nm to 10000 nm, selected from the range of 5 nm to 250 nm or selected from the range of 50 nm to 150 nm. Optionally, the substrate has a thickness selected from the range of 5 nm to 1000 μm, selected from the range of 5 nm to 25 μm or selected from the range of 50 nm to 10 μm.

In embodiments, the transparent conducting electrode layer comprises a transparent conducting oxide or a transparent conducting polymer. In an embodiment, the transparent conducting electrode layer has a thickness selected from the range of 5 nm to 250 nm, selected from the range of 10 nm to 100 nm or selected from the range of 50 nm to 150 nm. Optionally, the transparent conducting electrode layer comprises a material selected from the group consisting of: Indium Tin Oxide (ITO), Aluminum Zinc Oxide (AZO), indium-doped cadmium-oxide, carbon nanotubes, Fluorine-doped Tin Oxide (FTO), graphene, networks of polymers such as, but not limited to, poly(3,4-ethylenedioxythiophene) and any combination of these.

In embodiments, the solar terrestrial light absorbing conductive metallic oxide layer and the chemically-stable catalytic oxide layer comprise a heterojunction, such as a multilayer heterojunction. In embodiments, the solar terrestrial light absorbing conductive metallic oxide layer and the chemically-stable catalytic oxide layer comprise an n-n Schottky junction, an n-n ohmic junction, a p-n Schottky junction or a p-n ohmic junction.

Optionally, selection of the orientation of the solar terrestrial light absorbing conductive metallic oxide layer or the substrate layer provides for an avenue for controlling specific properties of the device, such as to achieve beneficial advantages for a specific application. In an embodiment, the solar terrestrial light absorbing conductive metallic oxide layer is provided with a (001), (110), (111) or other orientation or polycrystalline orientation over the substrate. In a specific embodiment, the substrate layer comprises one or more materials including, but not limited to SrTiO₃, LaAlO₃ DyScO₃, LSAT, GdScO₃, TbScO₃, sapphire, MgO, MgAl₂O₄, a semiconductor, Si, GaN, a metal, NdGaO₃, YAlO₃, Gadolinium Gallium Garnet (GGG), LiAlO₂, LiGaO₂, LiNbO₃, LiTaO₃, SrLaAlO₄, SrLaGaO₄, TiO₂, Yttrium Aluminum Garnet (YAG), Y:ZrO₂ (YSZ), ZnO₂, alkali halide and alkaline earth halide substrates such as, but not limited to BaF₂, CaF₂, KBr, MgF₂, KCl, and NaCl, semiconducting substrates such as Si, Ge, GaN, GaAs, GaP, GaSb, ZnS, ZnSe, ZnTe, and metal substrates including but not limited to Cu, Li, Mo, Ni, Pt, Au, Ag, Ti, Ta, Zr, steel (stainless, high-carbon, low-carbon, and alloy) including alloys made from these metals and graphite or any combination of these.

In another aspect, provided is a photocatalytic material. In embodiments, a photocatalytic material comprises a solar terrestrial absorbing composite, such as described above. In a specific embodiment of this aspect, a photocatalytic material of this aspect comprises a chemically-stable catalytic oxide structure and a solar terrestrial light absorbing conductive metallic oxide structure positioned in contact with the chemically-stable catalytic oxide structure. In embodiments, absorption of electromagnetic radiation, such as visible or solar terrestrial electromagnetic radiation, by the solar terrestrial light absorbing conductive metallic oxide structure forms charge carriers in the solar terrestrial light absorbing conductive metallic oxide structure that are transferred to the chemically-stable catalytic oxide structure. In embodiments, absorption of visible or solar terrestrial electromagnetic radiation by the solar terrestrial light absorbing conductive metallic oxide structure forms charge carriers of sufficient energy for subsequent transfer of the charge carriers to the chemically-stable catalytic oxide structure.

Optionally, the chemically stable catalytic oxide structure comprises a coating over the solar terrestrial light absorbing conductive metallic oxide structure. In embodiments, the chemically-stable catalytic oxide structure and the solar terrestrial light absorbing conductive metallic oxide structure are provided as one or more mixtures, structures or compositions including, but not limited to, a colloid, an emulsion, a solution, a dispersion, a suspension, a foam, a paint, a coating, a particle, a nanoparticle, a core-shell material, a nanowire, a nanotube, a porous material, a thin film, a thick film, a plate, a ceramic part, a ceramic tile, a gel, a network structure, a mesh, a foil, a gauze, a sponge or a membrane.

In specific embodiments, the photocatalytic material exhibits a mass-normalized photocatalytic activity greater than 2 times, greater than 5 times, greater than 10 times or greater than 20 times a mass-normalized photocatalytic activity of the chemically-stable catalytic oxide structure alone.

In specific embodiments, the photocatalytic material further comprises an aqueous solution in contact with the chemically-stable catalytic oxide structure. In embodiments, the photocatalytic material is positioned such that the chemically-stable catalytic oxide structure is positioned in contact with an aqueous solution or with a gas. In embodiments, the photocatalytic material is positioned such that the chemically-stable catalytic oxide structure and/or the solar terrestrial light absorbing conductive metallic oxide structure receives electromagnetic radiation, such as direct solar electromagnetic radiation or solar terrestrial electromagnetic radiation from the sun.

In another aspect, provided are methods of creating hot-carriers. In an embodiment, a method of this aspect comprises the steps of providing a solar terrestrial absorbing composite and exposing the solar terrestrial absorbing composite material to visible or solar terrestrial electromagnetic radiation. In embodiments, the solar terrestrial absorbing composite comprises a solar terrestrial absorbing composite described above, a photocatalytic material described above or a photovoltaic device described above. In a specific embodiment, the solar terrestrial absorbing composite comprises a chemically-stable catalytic oxide structure and a solar terrestrial light absorbing conductive metallic oxide structure positioned in contact with the chemically-stable catalytic oxide structure. In embodiments, absorption of electromagnetic radiation, such as visible or solar terrestrial electromagnetic radiation, by the solar terrestrial light absorbing conductive metallic oxide structure forms charge carriers in the solar terrestrial light absorbing conductive metallic oxide structure that are transferred to the chemically-stable catalytic oxide structure. In embodiments, absorption of visible or solar terrestrial electromagnetic radiation by the solar terrestrial light absorbing conductive metallic oxide structure forms charge carriers of sufficient energy for subsequent transfer of the charge carriers to the chemically-stable catalytic oxide structure. Optionally, the solar terrestrial light absorbing conductive metallic oxide structure absorbs electromagnetic radiation having wavelengths selected between 280 nm and 1000 nm, between 380 nm and 800 nm or between 400 nm and 760 nm to create the hot-carriers.

In another aspect, provided are methods of generating a photocurrent or a photovoltage. In an embodiment, a method of this aspect comprises the steps of providing a photovoltaic device and exposing the photovoltaic device to visible or solar terrestrial electromagnetic radiation. In embodiments, the photovoltaic device comprises a solar terrestrial absorbing composite described above, a photocatalytic material described above or a photovoltaic device described above. In a specific embodiment, the photovoltaic device comprises a substrate; a solar terrestrial light absorbing conductive metallic oxide layer provided over at least a portion of the substrate; a chemically-stable catalytic oxide layer provided over and in contact with at least a portion of the solar terrestrial light absorbing conductive metallic oxide layer; and a transparent conducting electrode layer provided over and in contact with at least a portion of the chemically-stable catalytic oxide layer. In embodiments, absorption of electromagnetic radiation, such as visible or solar terrestrial electromagnetic radiation, by the solar terrestrial light absorbing conductive metallic oxide layer forms charge carriers in the solar terrestrial light absorbing conductive metallic oxide layer that are transferred to the chemically-stable catalytic oxide layer. In embodiments, absorption of visible or solar terrestrial electromagnetic radiation by the solar terrestrial light absorbing conductive metallic oxide layer forms charge carriers of sufficient energy for subsequent transfer of the charge carriers to the chemically-stable catalytic oxide layer, thereby generating a photocurrent or photovoltage. Optionally, the solar terrestrial light absorbing conductive metallic oxide layer absorbs electromagnetic radiation having wavelengths selected between 280 nm and 1000 nm, between 380 nm and 800 nm or between 400 nm and 760 nm to generate the photocurrent or photovoltage.

In another aspect, provided are methods of photocatalytically oxidizing, reducing or producing radical species from a substance. In an embodiment, a method of this aspect comprises the steps of providing a photocatalytic material, contacting the photocatalytic material with the substance, exposing the photocatalytic material to visible or solar terrestrial electromagnetic radiation and oxidizing, reducing or producing radical species from at least a portion of the substance in contact with the photocatalytic material. In embodiments, the photocatalytic material comprises a solar terrestrial absorbing composite described above, a photocatalytic material described above or a photovoltaic device described above. In a specific embodiment, the photocatalytic material composite comprises a chemically-stable catalytic oxide structure and a solar terrestrial light absorbing conductive metallic oxide structure positioned in contact with the chemically-stable catalytic oxide structure.

In embodiments, absorption of electromagnetic radiation, such as visible or solar terrestrial electromagnetic radiation, by the solar terrestrial light absorbing conductive metallic oxide structure forms charge carriers in the solar terrestrial light absorbing conductive metallic oxide structure that are transferred to the chemically-stable catalytic oxide structure. In embodiments, absorption of visible or solar terrestrial electromagnetic radiation by the solar terrestrial light absorbing conductive metallic oxide structure forms charge carriers of sufficient energy for subsequent transfer of the charge carriers to the chemically-stable catalytic oxide structure. In embodiments, the solar terrestrial light absorbing conductive metallic oxide structure absorbs visible or solar terrestrial electromagnetic radiation to activate the photocatalytic material. In embodiments, the substance is present in a gas, such as air, or in an aqueous solution. In exemplary embodiments, the substance comprises water, an organic pollutant, an organic chemical, an inorganic pollutant, a volatile organic compound, carbon dioxide, carbon monoxide, nitric oxide, nitrogen dioxide, sulfur dioxide, benzene, an organic dye, a pharmaceutical, a hormone, a cosmetic, a feed-stock chemical or any mixture or combination comprising one or more of these.

Without wishing to be bound by any particular theory, there can be discussion herein of beliefs or understandings of underlying principles relating to the invention. It is recognized that regardless of the ultimate correctness of any mechanistic explanation or hypothesis, an embodiment of the invention can nonetheless be operative and useful.

### BRIEF DESCRIPTION OF THE DRAWINGS

FIG. 1A provides a schematic illustration of a solar terrestrial absorbing composite embodiment. FIG. 1B provides a schematic perspective illustration of a photovoltaic device embodiment.

FIG. 2 provides data showing θ-2θ X-ray diffraction scan of 50 nm epitaxial thin films of SrRuO₃, SrVO₃, and La_{0.7}Sr_{0.3}MnO₃ on SrTiO₃ (001) and of La_{0.5}Sr_{0.5}CoO₃ and LaNiO₃ on LaAlO₃ (001) (top to bottom).

FIG. 3 provides data showing reflectance (R, left ordinate) and absorption coefficient (α, right ordinate) for 50 nm thin films of SrRuO₃, LaNiO₃, SrVO₃, La_{0.7}Sr_{0.3}MnO₃, and La_{0.5}Sr_{0.5}CoO₃ (left to right) with corresponding schematic band diagrams for the materials depicted below.

FIG. 4a provides a schematic diagram of photovoltaic device geometry consisting of 100 nm ITO/100 nm TiO₂/50 nm “metallic” oxide heterojunction devices. FIG. 4b provides data showing short-circuit current density (JSC) as a function of photon energy measured under AM1.5G illumination with various longpass glass filters.

FIG. 5a provides mass normalized methylene blue (MB) degradation activity for 10 nm TiO₂/50 nm “metallic” oxide heterojunctions devices under AM1.5G illumination (*Degussa P25). FIG. 5b provides a schematic diagram of photocatalytic geometry consisting of 10 nm TiO₂/50 nm “metallic” oxide heterojunction devices. FIGS. 5c-5g provide schematic band diagrams for the photocatalytic devices for SrVO₃, LaNiO₃, SrRuO₃, La_{0.5}Sr_{0.5}CoO₃, La_{0.7}Sr_{0.3}MnO₃, respectively. The relative reduction/oxidation potentials for pH 7 water shown to scale on left.

FIG. 6a provides data showing temperature dependent resistivity and FIG. 6b provides room temperature mobility (μ), resistivity (ρ), and carrier concentration (N) for 50 nm thin films.

FIGS. 7a-7e provide data showing Refractive index (n) and extinction coefficient (k) for 50 nm thin films of (FIG. 7a) SrRuO₃, (FIG. 7b) LaNiO₃, (FIG. 7c) SrVO₃, (FIG. 7d) La_{0.7}Sr_{0.3}MnO₃, and (FIG. 7e) La_{0.5}Sr_{0.5}CoO₃ as measured via ellipsometry.

FIG. 8a provides data showing current density as a function of applied voltage for ITO/TiO₂/0.5% Nb-doped SrTiO₃ (001) heterostructure. The top and bottom graphs show the same data on linear and log scales, respectively, along with the red lines with are the fits to the Richardson-Nordheim equation. FIG. 8b illustrates schematic band diagram showing the relative alignment of bands and the effective Schottky barrier height at the ITO/TiO₂ interface. FIG. 8c provides data showing current density as a function of applied voltage for ITO/TiO₂/SrRuO₃/SrTiO₃ (001) heterostructure. The top and bottom graphs show the same data on linear and log scales, respectively, along with the red lines with are the fits to the Richardson-Nordheim equation.

FIGS. 9a-9e provide data showing light and dark current-voltage characteristics of 100 nm ITO/100 nm TiO2/50 nm “metallic” oxide photovoltaic device taken with different longpass glass filters (the number in the key represents the optical density of 2 (λ_{OD2}) of the filter for devices based on (FIG. 9a) SrRuO₃, (FIG. 9b) LaNiO₃, (FIG. 9c) SrVO₃, (FIG. 9d) La_{0.7}Sr_{0.3}MnO₃, and (FIG. 9e) La_{0.5}Sr_{0.5}CoO₃. FIG. 9f depicts the legend for FIGS. 9a-9e.

FIG. 10a provides data showing the various longpass glass filters used in Example 1 including the filter name, the λ_{OD2}, and the transmitted light intensity. FIG. 10b provides data showing transmittance of the various longpass glass filters across the visible light range. FIG. 10b provides data showing light intensity transmitted through each longpass glass filter overlaid on the AM1.5G light spectrum.

FIGS. 11a-11e illustrate proposed band diagrams for the photovoltaic devices based on (FIG. 11a) SrRuO₃, (FIG. 11b) LaNiO₃, (FIG. 11c) SrVO₃, (FIG. 11d) La_{0.5}Sr_{0.5}CoO₃, and (FIG. 11e) La_{0.7}Sr_{0.3}MnO₃.

FIG. 12a depicts the closed-loop MB decoloration experimental setup under defocused illumination. FIG. 12b provides a schematic illustration of the sample mounting. FIG. 12c provides data showing transmittances of MB solution as compared to DI water. FIG. 12d provides data showing time-dependent auto-oxidation of MB.

FIG. 13 provides data showing normalized methylene blue (MB) concentration time trace for 10 nm TiO₂/50 nm “metallic” oxide heterojunctions devices and control standards (Glass slide and 150 nm TiO₂) under AM1.5G illumination.

FIG. 14a provides data showing reflectance and FIG. 14b provides data showing absorption coefficient (a) of a 50 nm SrRuO₃/SrTiO₃ (001) heterostructures as measured via photospectrometry (orange) and ellipsometry (blue). The inset of FIG. 14b shows the absorbance from 25, 50, and 100 nm thick SrRuO₃/SrTiO₃ (001) heterostructures. FIG. 14c provides data showing the absorption spectrum of 100 nm TiO₂ and 25, 50, and 100 nm SrRuO₃ films overlaid on the AM1.5G spectrum.

FIG. 15a provides data showing light and dark current-voltage characteristics of a 100 nm ITO/100 nm TiO₂/10 nm SrRuO₃ device taken with different longpass glass filters (the number in the key represents the λ_{OD2} of the filter). FIG. 15b provides data showing short-circuit current density (J_{SC}) as a function of photon energy for devices with 10 and 50 nm of SrRuO₃ measured under AM1.5G illumination with various longpass glass filters as compared to the dark diode current through the device (J₀) and the absorbance of the SrRuO₃ and TiO₂ films. FIG. 15c illustrates a schematic band diagram of hot-carrier injection in the ITO/TiO₂/SrRuO₃ Schottky junction device.

FIG. 16a provides data showing rate constants and activity and FIG. 16b provides data showing mass-normalized photocatalytic activity of methylene blue photodegradation for 10 nm TiO₂/x nm SrRuO₃ heterostructures. FIG. 16c illustrates proposed band diagram of how the hot-carrier injection gives rise to the photocatalytic response.

FIG. 17a, FIG. 17b and FIG. 17c provide data showing optical conductivity of 50, 10, and 5 nm thick SrRuO₃ thin films, respectively.

FIG. 18 provides data showing θ-2θ X-ray diffraction scan of a TiO₂/SrRuO₃/SrTiO₃ (001) heterostructure.

FIG. 19a provides data showing refractive index (n) and FIG. 19b provides data showing extinction coefficient (k) for a model 50 nm SrRuO₃/SrTiO₃ (001) heterostructure as measured via ellipsometry. FIG. 19c provides data showing transmittance and FIG. 19d provides data showing reflectance of 25, 50, and 100 nm SrRuO₃/SrTiO₃ (001) heterostructures and a bare SrTiO₃ substrate as measured via photospectrometry.

FIGS. 20a and 20b provide data showing light and dark current-voltage characterization of ITO/TiO₂/SrRuO₃ heterostructures with various longpass glass filters for heterostructures with (FIG. 20a) 10 nm and (FIG. 20b) 50 nm of SrRuO₃. FIG. 20c depicts the legend for FIGS. 20a and 20b.

FIGS. 21a and 21b provide data showing enhanced photocatalytic activities of 10 nm TiO₂/5, 10, 20, 50, and 75 nm SrRuO₃ devices as measured under (FIG. 21a) light filter with a ΨC-11UV cutoff filter and (FIG. 21b) with AM1.5 light.

### DETAILED DESCRIPTION

In general the terms and phrases used herein have their art-recognized meaning, which can be found by reference to standard texts, journal references and contexts known to those skilled in the art. The following definitions are provided to clarify their specific use in the context of the invention.

“Chemically-stable” refers to the ability of a material to withstand exposure to aqueous environments when exposed to visible, UV and/or infrared electromagnetic radiation without dissolving, reacting or otherwise being damaged, such as by hydrolysis or an oxidation reaction. In embodiments, chemically-stable materials can withstand exposure to aqueous environments when exposed to visible, UV and/or infrared electromagnetic radiation for days, weeks or months at a time without undergoing significant and/or permanent damage.

“Catalytic oxide” refers to a solid material comprising oxygen and one or more metals on which photochemical, electrochemical and/or photo-electrochemical reactions can take place. In some embodiments, a catalytic oxide comprises a semiconducting oxide having a band gap. In some embodiments, a semiconducting catalytic oxide absorbs incident electromagnetic radiation having a photon energy greater than the band gap and transmits electromagnetic radiation having a photon energy less than the band gap. In some embodiments, a catalytic oxide participates in a catalytic reaction by first absorbing electromagnetic radiation or receiving charge carriers created by absorption of electromagnetic radiation by a solar terrestrial light absorbing conductive metallic oxide structure in electrical communication with the catalytic oxide and then promoting, driving or otherwise participating in a reaction with a substance present at a surface of the catalytic oxide.

“Solar terrestrial electromagnetic radiation” refers to electromagnetic radiation that can be detected by the human eye and nearby wavelength regimes, such as portions of the ultraviolet and infrared regions of the electromagnetic spectrum. In embodiments, solar terrestrial electromagnetic radiation refers to electromagnetic radiation produced by the sun and which reaches the surface of the Earth. In embodiments, solar terrestrial electromagnetic radiation optionally refers to electromagnetic radiation having wavelengths between 280 nm and 4000 nm or optionally electromagnetic radiation having wavelengths between 280 nm and 1200 nm. In embodiments, solar terrestrial electromagnetic radiation refers to electromagnetic radiation having wavelengths between 280 nm and 4000 nm or optionally between 280 nm and 1200 nm, and includes electromagnetic radiation that is absorbed and/or transmitted by the Earth's atmosphere. In embodiments, solar terrestrial electromagnetic radiation includes portions of the ultraviolet region of the electromagnetic spectrum. In embodiments, solar terrestrial electromagnetic radiation includes portions of the infrared region of the electromagnetic spectrum. Solar terrestrial electromagnetic radiation includes the visible light region of the electromagnetic spectrum, for example electromagnetic radiation having wavelengths between 380 nm and 800 nm. In embodiments, solar terrestrial electromagnetic radiation refers to electromagnetic radiation having wavelengths between 280 nm and 1000 nm, electromagnetic radiation having wavelengths between 380 nm and 800 nm or electromagnetic radiation having wavelengths between 400 nm and 760 nm. In certain embodiments, solar terrestrial electromagnetic radiation includes electromagnetic radiation having wavelengths found in the AM1.5G solar spectrum. In embodiments, solar terrestrial electromagnetic radiation is produced by the sun. In embodiments, solar terrestrial electromagnetic radiation is produced by an artificial light source, such as a lamp, laser, LED or other light producing device.

“Solar terrestrial light absorbing” refers to the ability of a material to absorb solar terrestrial electromagnetic radiation. In embodiments, a solar terrestrial absorbing material undergoes electronic transitions in which electrons in the material are promoted to higher energy states due to the absorption of solar terrestrial electromagnetic radiation. In embodiments the phrase “light absorbing” contrasts with the optical property of transparent materials in which a portion, all or a majority of electromagnetic radiation is transmitted to underlying materials. In embodiments, a solar terrestrial absorbing material has an absorption coefficient greater than 1.0×10⁴ cm⁻¹, greater than 0.5×10⁵ cm⁻¹, greater than 1.0×10⁵ cm⁻¹, greater than 1.5×10⁵ cm⁻¹ or between 0.5×10⁵ cm⁻¹ and 4.0×10⁵ cm⁻¹ for electromagnetic radiation having wavelengths between 280 nm and 1000 nm. In embodiments, a solar terrestrial absorbing material has absorption coefficients greater than 1.0×10⁴ cm⁻¹, greater than 0.5×10⁵ cm⁻¹, greater than 1.0×10⁵ cm⁻¹, greater than 1.5×10⁵ cm⁻¹ or between 0.5×10⁵ cm⁻¹ and 4.0×10⁵ cm⁻¹ for at least some wavelengths of electromagnetic radiation between 280 nm and 1000 nm, such as at least some wavelengths of electromagnetic radiation between 380 nm and 800 nm or such as at least some wavelengths of electromagnetic radiation between 400 nm and 760 nm.

The terms “visible light” and “visible electromagnetic radiation” interchangeably refer to electromagnetic radiation that can be detected by the human eye and, optionally, nearby wavelength regimes, such as portions of the ultraviolet and infrared regions of the electromagnetic spectrum. In embodiments, visible electromagnetic radiation comprises photons of sufficient energy to induce electronic transitions of certain materials where electrons are promoted from a lower energy level to a higher energy level. In embodiments, visible electromagnetic radiation comprises electromagnetic radiation having wavelengths between 380 nm and 800 nm, between 380 nm and 760 nm, between 400 nm and 800 nm or between 400 nm and 760 nm. In certain embodiments, visible light includes electromagnetic radiation having wavelengths found in the AM1.5G solar spectrum, such as wavelengths between about 380 nm and 800 nm.

“Visible light absorbing” refers to the ability of a material to absorb visible electromagnetic radiation. In embodiments, a visible light absorbing material undergoes electronic transitions in which electrons in the material are promoted to higher energy states due to the absorption of visible electromagnetic radiation. In embodiments, a visible light absorbing material has an absorption coefficient greater than 1.0×10⁴ cm⁻¹, greater than 0.5×10⁵ cm⁻¹, greater than 1.0×10⁵ cm⁻¹, greater than 1.5×10⁵ cm⁻¹ or between 0.5×10⁵ cm⁻¹ and 4.0×10⁵ cm⁻¹ for electromagnetic radiation having wavelengths between 380 nm and 800 nm or wavelengths between 400 nm and 760 nm. In embodiments, a visible light absorbing material has absorption coefficients greater than 1.0×10⁴ cm⁻¹, greater than 0.5×10⁵ cm⁻¹, greater than 1.0×10⁵ cm⁻¹, greater than 1.5×10⁵ cm⁻¹ or between 0.5×10⁵ cm⁻¹ and 4.0×10⁵ cm⁻¹ for at least some wavelengths of electromagnetic radiation between 380 nm and 800 nm or wavelengths between 400 nm and 760 nm.

“Conductive metallic oxide” refers to a material comprising oxygen and one or more metals, metalloids, or semiconductors and that exhibits conducting behavior consistent with that of a metal, for example, having an electrical conductivity similar to that of a metal, such as having a resistivity less than 2000 μΩ-cm. In embodiments, conductive metallic oxides have carrier concentrations greater than 10²⁰ cm⁻³, greater than 10²¹ cm⁻³ or greater than 10²² cm⁻³. In embodiments, conductive metallic oxides have room-temperature resistivities less than 2000 μΩ-cm, less than 1500 μΩ-cm, less than 500 μΩ-cm, less than 400 μΩ-cm or less than 300 μΩ-cm. In embodiments, conductive metallic oxides have room-temperature carrier mobilities selected from the range of 0.1 to 10 cm² V⁻¹ s⁻¹, selected from the range of 0.15 to 7 cm² V⁻¹ s⁻¹ or selected from the range of 0.2 to 2 cm² V⁻¹ s⁻¹. In embodiments, a conductive metallic oxide is not an insulating material. In embodiments, some metallic oxides are well described by classical band theory. In embodiments, the electronic structure of a metallic oxide is not accurately described by the electronic structure of the metallic component and the electronic structure of the oxygen alone and may be referred to herein as a “correlated metal oxide” or a “correlated metallic oxide.” In embodiments, the electronic structure of correlated metal or metallic oxides is more accurately described by interactions between both the electronic structures of the metal/metallic component and the oxygen. In some embodiments, correlated metal or metallic oxides are conducting materials. In some embodiments, correlated metal or metallic oxides have a Fermi level that resides in an electronic band of the material. In some embodiments, the invention provides light absorbing composites, photovoltaic devices and/or photocatalytic materials comprising a terrestrial solar light absorbing conductive metallic oxide. In some embodiments, the invention provides light absorbing composites, photovoltaic devices and/or photocatalytic materials comprising a visible light absorbing conductive metallic oxide.

“Absorption coefficient” refers to a quantitative measure of the affinity for a material to absorb electromagnetic radiation. In embodiments, the absorption coefficient of a material provides a measure of how strongly absorbing a material is for electromagnetic radiation of a specific wavelength or over a specific wavelength range. In embodiments, the absorption coefficient can be derived or calculated from the material's absorption cross-section or from the material's extinction coefficient.

“Charge carriers” refers to carriers of electric charge in a conducting or semiconducting material. In embodiments, charge carriers are electrons or moving vacancies in an electronic band (“holes”) or moving defects or impurity species. In embodiments, charge carriers are created, moved or separated or have their energy changed in a conducting or semiconducting material by absorption of electromagnetic radiation. In embodiments, charge carriers can pass from one material to another material. In embodiments, charge carriers are present in a conductive metallic oxide at a concentration greater than 10²⁰ cm⁻³, greater than 10²¹ cm⁻³ or greater than 10²² cm⁻³. In embodiments, the rate at which charge carriers are created, moved or separated in an absorbing material is related or proportional to an amount of light absorbed by the material.

“Photo-excited carriers” refers to conductors of electric charge that are created by absorption of electromagnetic radiation. In some embodiments, photo-excited carriers are created in a semiconducting material by absorption of electromagnetic radiation having an energy greater than or equal to the band gap of the semiconducting material.

“Hot-carriers” refers to conductors of electric charge that possess sufficient energy such that the conductors can transition across a junction between two materials or across a junction between two materials and still possess excess energy.

“Optical conductivity” refers to a property of a conducting material that provides an indication of the ease or difficulty of conducting charges through the material when the material is exposed to electromagnetic radiation, for example visible electromagnetic radiation.

“Carrier concentration” refers to a property of a conducting or semiconducting material and reflects the populations of electrons and holes in a conducting or semiconducting material that participate in conduction of electrical charge.

“Resistivity” refers to a property of a material that provides an indication of the ease or difficulty of flowing electric current through the material. In embodiments, the resistivity of a material changes as the temperature of the material changes. “Room temperature resistivity” refers to the resistivity of a material at room temperature or about 300 K.

“Carrier mobility” refers to a property of a material that provides an indication of the ease or difficulty of moving an electric charge through the material when exposed to an electric field. In embodiments, the carrier mobility of a material changes as the temperature of the material changes. “Room temperature carrier mobility” refers to the carrier mobility of a material at room temperature or about 300 K.

“Reflectance” refers to the fraction or percentage of electromagnetic radiation that is reflected by a material or at an interface between two materials.

“p-type material” refers to material in which the primary charge carriers are holes or in which the free hole concentration is larger than the free electron concentration.

“n-type material” refers to material in which the primary charge carriers are electrons or in which the free electron concentration is larger than the free hole concentration.

“Dopant” refers to impurities in a pure semiconductor that alter the electrical or optical properties of the semiconductor. In embodiments, dopants are positioned in a semiconductor crystal structure in place of a semiconductor. Dopants include p-type and n-type dopants.

“Semiconductor” refers to any material that is an insulator at very low temperatures, but which has an appreciable electrical conductivity at temperatures of about 300 Kelvin. In the present description, use of the term semiconductor is intended to be consistent with use of this term in the art of microelectronics and electrical devices. Typical semiconductors include element semiconductors, such as silicon, germanium and diamond, and compound semiconductors, such as group IV compound semiconductors such as SiC and SiGe, group III-V semiconductors such as AlSb, AlAs, Aln, AlP, BN, GaSb, GaAs, GaN, GaP, InSb, InAs, InN, and InP, group III-V ternary semiconductors alloys such as AlxGa1-xAs, group II-VI semiconductors such as CsSe, CdS, CdTe, ZnO, ZnSe, ZnS, and ZnTe, group I-VII semiconductors CuCl, group IV-VI semiconductors such as PbS, PbTe and SnS, layer semiconductors such as PbI₂, MoS₂ and GaSe, oxide semiconductors such as CuO, Cu₂O and TiO₂.

The term semiconductor includes intrinsic semiconductors and extrinsic semiconductors that are doped with one or more selected materials, including semiconductor having p-type doping materials (also known as p-type or p-doped semiconductor) and n-type doping materials (also known as p-type or n-doped semiconductor), to provide beneficial electrical properties useful for a given application or device. The term semiconductor includes composite materials comprising a mixture of semiconductors and/or dopants. Impurities of semiconductor materials are atoms, elements, ions and/or molecules other than the semiconductor material(s) themselves or any dopants provided to the semiconductor material.

“Band gap” refers to the difference energy levels between the top of the valence band and the bottom of the conduction band in a semiconducting material.

“Trirutile,” “pucherite,” “dreyerite,” “clinobisvanite,” “perovskite,” “pyrochlore,” “oxypnictide,” “NaClO₄-type structure,” “anhydrite,” “barite,” “AgMnO₄-type structure,” “Scheelite,” “CsIO₄-type structure,” “crocoite,” “monazite,” “selenite-anhydrite,” “zircon,” “quartz-analog,” “BPO₄-type structure,” “AlPO₄-type structure,” “rutile-analog,” “berlinite,” “stibiotantalite,” “MgWO₄-type structure,” “zirconia-analog,” “BaUO₄-type structure,” “CaUO₄-type structure,” “vorlanite,” and “fluorite-analog type” refers to specific crystal structures of various materials. For example, in embodiments, a perovskite structure refers to a crystal structure of the same type as that of calcium titanium oxide (CaTiO₃). In embodiments, for example, a pyrochlore structure refers to the crystal structure Fd-3m.

“Photocatalytic” refers to a process for accelerating or driving a chemical reaction using energy from electromagnetic radiation.

“Photovoltaic” refers to a method for generation of a voltage or current by absorption of electromagnetic radiation, such as visible electromagnetic radiation. In exemplary embodiments, photovoltaics convert electromagnetic radiation from sunlight into electrical energy.

“Heterojunction” refers to the interface between two materials having unequal band gaps or where the energies of the valence bands, the conduction bands or both in the materials are not equal or are misaligned.

“Ohmic junction” refers to an interface between two materials in which the Schottky barrier height is small enough to permit the flow of electrons in both directions. In embodiments, an “n-n ohmic junction” refers to an ohmic junction in which the primary charge carriers in both materials are electrons.

“Schottky junction” refers to an interface between two materials in which the Schottky barrier height is large enough to inhibit the flow of charges through the junction in one direction. In embodiments, an “n-n Schottky junction” refers to a Schottky junction in which the primary charge carriers in both materials are electrons. In embodiments, a “p-n Schottky junction” refers to a Schottky junction in which the primary charge carrier is electrons in one material and holes in the other material.

“Schottky barrier height” refers to an energy difference at a junction between two materials, such as a semiconducting material and a conducting material. In one embodiment, the Schottky barrier height is the energy difference between the Fermi level of the conducting material and the energy of the conduction band of the semiconducting material at the interface between the materials. In another embodiment, the Schottky barrier height is the energy difference between the Fermi level of the conducting material and the energy of the valence band of the semiconducting material at the interface between the materials.

“Crystal” and “crystalline” refers to a material in which the material's substituent components (e.g., atoms, molecules, ions) are arranged in an ordered pattern in three dimensions. In embodiments, crystalline materials possess a crystal structure, referring to the ordered arrangement in the crystal. Crystals typically possess permissible cleavage directions depending on the crystal structure and lattice system of the crystal.

“Crystallites” refers to the individual crystalline components of a polycrystalline, fragmented or fractured crystalline material. In embodiments, each individual crystalline component has a size dimension on the order of micrometers or smaller.

“Transparent conducting electrode” refers to material that is useful for carrying charges but, at the same time, permits the transmission of electromagnetic radiation through the material. In embodiments, a transparent conducting electrode permits transmission of a majority of incident visible electromagnetic radiation. Useful transparent conducting electrodes include, but are not limited to, transparent conducting oxides and transparent conducting polymers.

“Mass-normalized photocatalytic activity” refers to a measure of a material's photocatalytic ability to decompose a specified substance when the material is exposed to electromagnetic radiation that is normalized by the mass of the material. In embodiments, a mass-normalized photocatalytic activity provides for a way to quantify and compare the photocatalytic ability of two different materials.

Provided herein are materials, methods and devices for absorption of visible or solar terrestrial electromagnetic radiation. The disclosed materials, methods and devices employ a multi-component oxide material comprising a solar terrestrial light absorbing metallic oxide and a chemically-stable catalytic oxide to achieve conversion of absorbed visible or solar terrestrial electromagnetic radiation into useful work, such as for photocatalytic or photovoltaic applications.

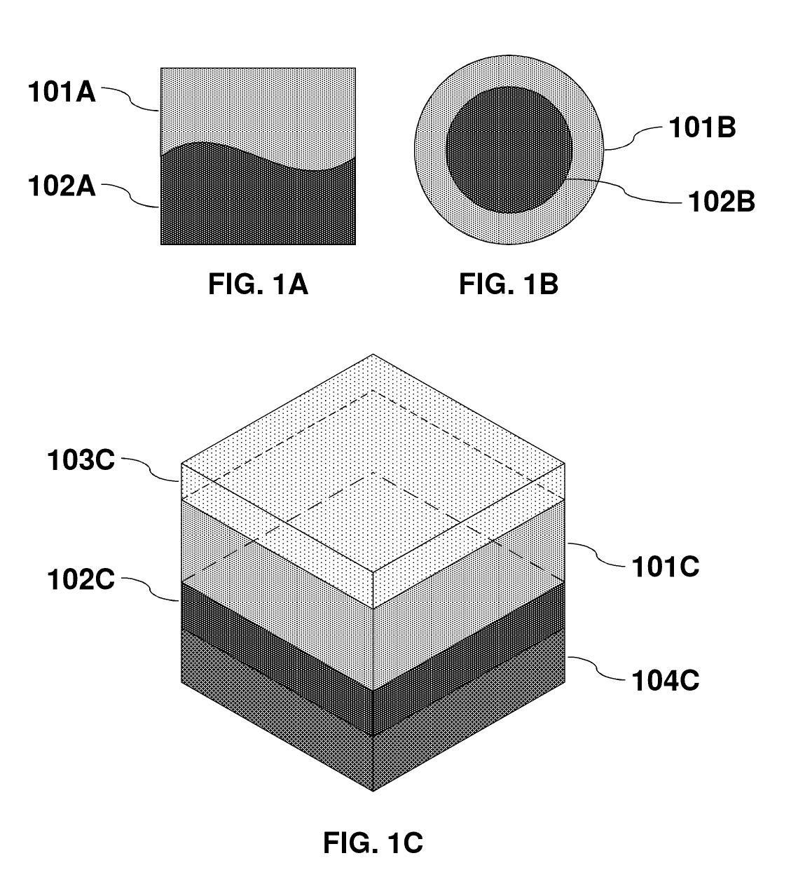

FIG. 1A illustrates a solar terrestrial light absorbing composite embodiment comprising chemically-stable catalytic oxide structure 101A and solar terrestrial light absorbing conductive metallic oxide structure 102A. In the embodiment shown, in FIG. 1A, chemically-stable catalytic oxide structure 101A and solar terrestrial light absorbing conductive metallic oxide structure 102A are in direct physical contact with one another. The solar terrestrial light absorbing composite of FIG. 1A can take on any suitable shape or size, whether provided in powder form, in a multilayer form, as a membrane attached directly or indirectly to another device or material, as a core-shell material or as a coated nanowire material. In an embodiment as a photocatalytic material, chemically-stable catalytic oxide structure 101A is provided in contact with, for example, an aqueous solution or a gaseous mixture including materials to be oxidized, reduced or converted to radical species by the photocatalytic material.

FIG. 1B illustrates a photocatalytic material embodiment comprising chemically-stable catalytic oxide structure 101B and solar terrestrial light absorbing conductive metallic oxide structure 102B. The embodiment shown in FIG. 1B is constructed as a core-shell material, where the core comprises solar terrestrial light absorbing conductive metallic oxide structure 102B and the shell comprises chemically-stable catalytic oxide structure 101B. In exemplary embodiments, multiple core-shell photocatalytic materials are provided in a solvent, such as in an emulsion, in a dispersion or in a suspension to provide a photocatalytic solution.

FIG. 1C illustrates a photovoltaic device embodiment comprising chemically-stable catalytic oxide layer 101C, solar terrestrial light absorbing conductive metallic oxide layer 102C, transparent conducting electrode layer 103C and substrate 104C. Although FIG. 1C depicts transparent conducting electrode layer 103C covering all of chemically-stable catalytic oxide layer 101C, in other embodiments, transparent conducting electrode layer 103C only covers a portion of chemically-stable catalytic oxide layer 101C. Under illumination by visible or solar terrestrial electromagnetic radiation from a source oriented above transparent conducting electrode layer 103C, in embodiments, visible or solar terrestrial electromagnetic radiation will be transmitted through transparent conducting electrode layer 103C and chemically-stable catalytic oxide layer 101C to reach solar terrestrial light absorbing conductive metallic oxide layer 102C where at least a portion of the visible or solar terrestrial electromagnetic radiation is absorbed, thus transparent conducting electrode layer 103C and chemically-stable catalytic oxide layer 101C are schematically depicted as transparent. In embodiments, photo-excited charge carriers are created in solar terrestrial light absorbing conductive metallic oxide layer 102C by absorption of visible or solar terrestrial electromagnetic radiation, and, if energetically and electronically feasible, at least a portion of the created charge carriers are transferred to chemically-stable catalytic oxide layer 101C where the charge carriers may be subsequently transferred to transparent conducting electrode layer 103C for use, for example, in an external circuit.

The invention may be further understood by the following non-limiting examples.

### Example 1

### Enhanced Photoelectrochemical Activity in all-Oxide Heterojunction Devices Based on Correlated “Metallic” Oxides

This Example describes n-n Schottky, n-n ohmic, and p-n Schottky heterojunctions based on TiO₂/correlated “metallic” oxide couples, which exhibit strong solar light absorption driven by the unique electronic structure of the “metallic” oxides. Photovoltaic and photocatalytic responses are driven by hot electron injection from the “metallic” oxide into the TiO₂, enabling new modalities of operation for energy systems.

Solar photocatalysis, or the direct conversion of solar terrestrial energy to chemical energy, is being considered for a range of applications including the generation of chemical fuels, environmental remediation of organic chemical pollution, and others. At its most basic, a photocatalytic cell provides a photo-anode and -cathode for oxidation and reduction reactions, respectively. The requirements for high-performance solar photocatalytic material systems are clear: broad absorption of the solar spectrum, efficient transfer of charge to the solid-liquid interface, and chemical stability under illumination in solution.

Traditional semiconductors such as silicon and GaAs have band gap energies that permit them to absorb a large portion of the solar spectrum; however, these materials are not stable in solution. Wide band gap oxide materials, by comparison, often possess excellent chemical stability in solution but their large band gap energies make them poor visible light absorbers. A natural approach, then, is to combine these two materials into single systems such as core-shell nanoparticles and heterojunction films. In such semiconductor/oxide heterostructures, however, the transfer of photoexcited carriers to the oxide surface may be limited due to the electronic mismatch of the materials and oxidation of the light-absorbing semiconductor which can detrimentally affect charge transport.

This example describes the investigation of a new variation of this methodology whereby chemically compatible correlated “metallic” oxides are integrated with the model n-type, wide band gap oxide semiconductor TiO₂ to produce high-performance photocatalytic heterojunctions. These composite structures operate on the principle of hot carrier injection from the “metallic” oxide into the TiO₂. These effects are made possible by harnessing the diverse range of correlated electron physics of common “metallic” oxide materials including n-type LaNiO₃, SrRuO₃, and SrVO₃ and p-type La_{0.5}Sr_{0.5}CoO₃ and La_{0.7}Sr_{0.3}MnO₃. These materials have been extensively explored (individually) for their novel electronic transport, magnetic properties, and other exotic physical phenomena and are widely utilized as epitaxial bottom electrodes in ferroic heterostructures. Despite previous work, the potential of these systems for energy applications has only begun to be explored. In the end, the unique electronic structure and density of states (DOS) of these correlated “metallic” oxides gives rise to dramatically different optical properties as compared to traditional metals including strong visible light absorption that significantly enhances photocatalytic activity and enables the study of n-n Schottky, n-n ohmic, and p-n Schottky heterojunctions with TiO₂. This example compares and contrasts the relative merits of these heterojunction types and explores enhancements in activity made possible by using these systems.

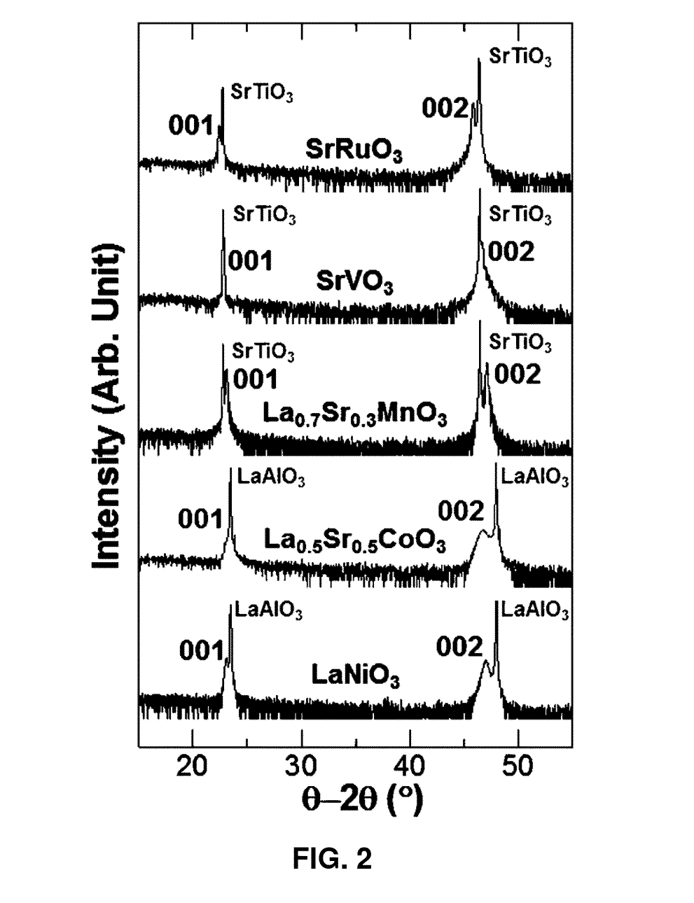

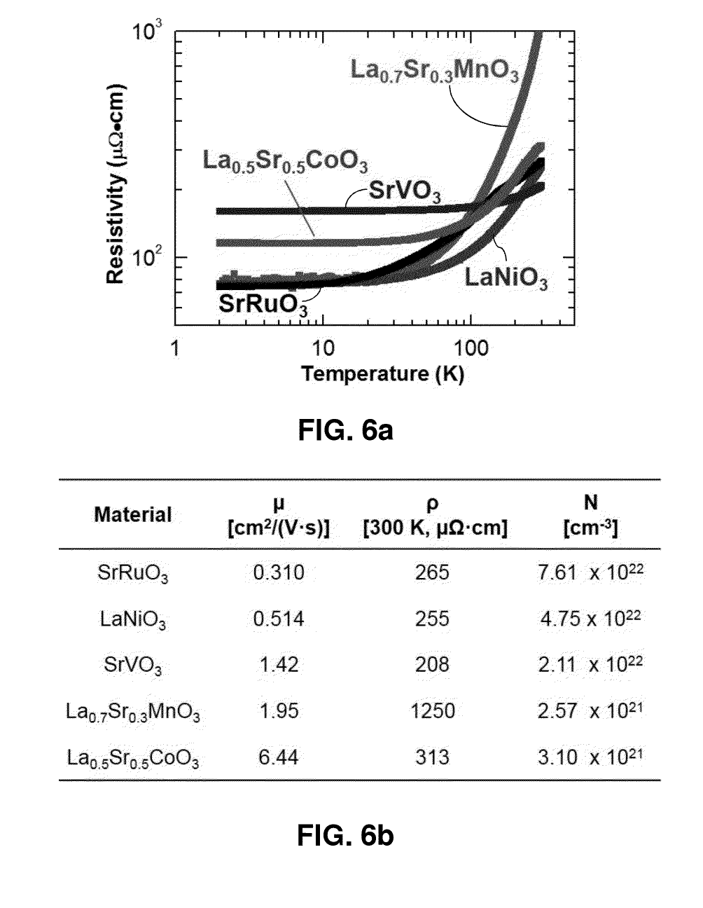

50 nm thick epitaxial thin films of the correlated “metallic” oxides SrRuO₃, LaNiO₃, SrVO₃, La_{0.7}Sr_{0.3}MnO₃, and La_{0.5}Sr_{0.5}CoO₃ were grown on SrTiO₃ (001) and LaAlO₃ (001) substrates via pulsed-laser deposition (see below). In all cases, high-quality single-phase films of the “metallic” oxides grow (001)-oriented, in a cube-on-cube fashion (FIG. 2). The films exhibit metal-like conductivity consistent with prior reports (see FIG. 6a). While often referred to as “metals” due to the presence of decreasing resistivity with temperature, these materials are not “metals” in the traditional sense. Unlike classical metals which owe their electrical transport properties to free electrons, the electrical transport properties observed in these correlated “metallic” oxides come from a combination of complex electronic structures, electron correlations, defect-induced self-doping, cation alloying, and other effects. Transport measurements of these materials reveal high carrier concentrations (>10²¹-10²² cm⁻³) and low majority carrier mobility (0.1-10 cm²/V-s) (FIG. 6b).

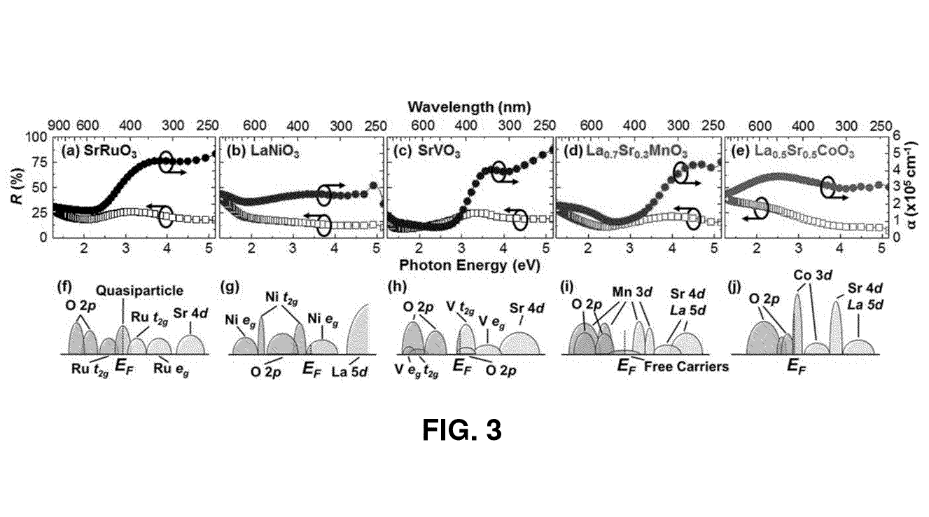

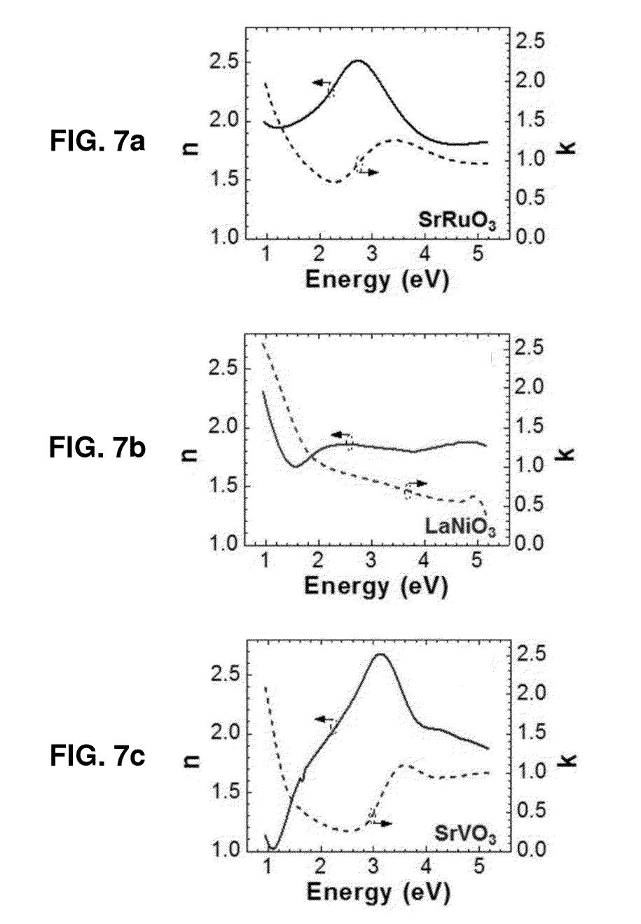

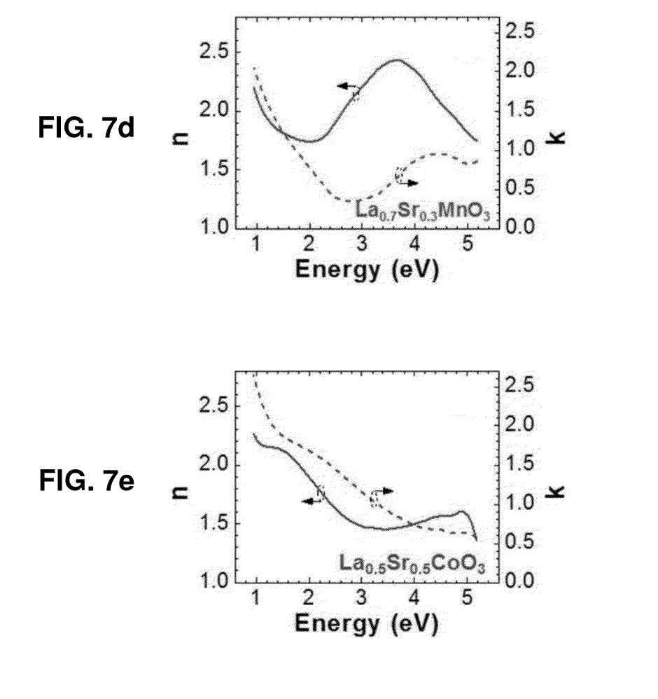

Although the electronic transport, magnetic and electronic structure, and other aspects of these materials have been widely studied, the optical properties have not. Overall, the ability of a material to absorb light is a complex function of the electron energy-momentum (E-k) band structure and the electronic DOS. Due to the interest in these materials in the condensed matter physics community, the electronic structure of these “metallic” oxides has been studied extensively and quick analysis of this data suggests that these materials could be promising candidates for strong light absorption. In this spirit, this example explores a range of correlated “metallic” oxides using spectroscopic ellipsometry to extract the reflectance (R) and absorption coefficient (a) from the optical constants n and k (see FIGS. 7a-7e). FIG. 3 provides R and a for the n-type materials SrRuO₃, LaNiO₃, and SrVO₃ and the p-type materials La_{0.7}Sr_{0.3}MnO₃ and La_{0.5}Sr_{0.5}CoO₃ are provided.

Effective light absorbing materials should possess low reflectance, as is observed for all the “metallic” oxides studied herein. Additionally, the measured reflectance values can be used to calculate the total reflectance of the AM1.5G spectrum for La_{0.5}Sr_{0.5}CoO₃, LaNiO₃, SrRuO₃, La_{0.7}Sr_{0.3}MnO₃, and SrVO₃ to be 33%, 26%, 23%, 20% and 17%, respectively. These values are significantly lower than those of traditional metals (generally >90%) and comparable to traditional semiconductors such as In_{0.10}Ga_{0.90}As (37%). All the films are visibly opaque and the optical properties are independent of the underlying substrate. SrRuO₃, SrVO₃, and La_{0.7}Sr_{0.3}MnO₃ (FIG. 3) show similar trends in both reflectance and absorption coefficient—relatively flat, low reflectance at all wavelengths and a strong up-turn in the absorption coefficient near 3.1 eV or 400 nm. LaNiO₃ and La_{0.5}Sr_{0.5}CoO₃, on the other hand (FIG. 3), show reflectance that steadily increases with increasing wavelength and relatively invariant absorption coefficients across the entire range of wavelengths. The implications of these observations for energy applications are illustrated by the fact that a 50 nm thick film of La_{0.5}Sr_{0.5}CoO₃, LaNiO₃, SrRuO₃, La_{0.7}Sr_{0.3}MnO₃, and SrVO₃ will absorb 53%, 50%, 44%, 41%, and 33%, respectively, of the AM1.5G spectrum from 280 to 1300 nm which is comparable to the 50% absorbed by 50 nm of In_{0.10}Ga_{0.90}As and much greater than the 0.62% absorbed by 50 nm of TiO₂, respectively (details of this calculation are provided below).

The absorption coefficient and reflectance may be understood in terms of the differences in electronic structure of the individual materials. All the systems studied herein are known to possess overlapping electronic bands of different types within the range of excitation energies provided by the AM1.5G spectrum (±4.5 eV of the Fermi energy, E_{F}). This continuous DOS provides for a large range of optical transitions and the observed non-zero absorption across the entire wavelength range studied. The fine structure of the absorption can be understood as a result of slight differences in the DOS. The following discussion provides schematic illustrations of the DOS of these “metallic” oxides and is meant to provide a qualitative picture of the possible mechanisms for light absorption based on prior studies of the electronic structure of these materials.

Beginning first with SrRuO₃, there is a high electronic DOS at the E_{F} associated with a quasiparticle band and occupied and unoccupied portions of the split Ru t_{2g} bands as a result of electron correlations (FIG. 3). As a result, there is essentially a continuous DOS above E_{F} which allows for optical inter- and intra-band transitions between states and corresponding continuous light absorption across the solar spectrum with the rise in absorption at 2.5 eV originating from electron transitions from the occupied O 2p band to the unoccupied t_{2g} band. Likewise, in LaNiO₃, where electron correlations are stronger, the Ni t_{2g} and e_{g} bands are also split, but there is no quasiparticle band and the principal transitions from visible light are almost entirely from the occupied, upper t_{2g} and O 2p bands (just below the E_{F}) to the unoccupied upper e_{g} band leading to a relatively invariant absorption coefficient (FIG. 3). In SrVO₃, however, electron correlations result in a splitting of the V t_{2g} and e_{g} bands, with the E_{F} located within the overlap of the upper t_{2g} and O 2p bands (FIG. 3). Unlike in SrRuO₃ and LaNiO₃, however, there is an energy gap just below E_{F} which results in the rise in absorption coefficient at around 3 eV when electrons are excited from the occupied O 2p band to E_{F}.

Similar effects exist in La_{0.7}Sr_{0.3}MnO₃ and La_{0.5}Sr_{0.5}CoO₃ (although the DOS sub-band structure for both materials is more complex than for the n-type oxides as a result of magnetic and spin-lattice effects) where the DOS below the E_{F} is primarily of O 2p character and the above-E_{F} DOS primarily has Mn or Co 3d character. The overlap of these two bands occurs around E_{F} and yields a continuous DOS. In the case of La_{0.7}Sr_{0.3}MnO₃, the DOS at E_{F} is relatively low as compared to the DOS located within a few eV on either side of E_{F} resulting in a small, but continuous absorption of light and a strong turn-on of absorption at around 3.2 eV (FIG. 3). In La_{0.5}Sr_{0.5}CoO₃ the DOS at the E_{F} is considerably higher compared to the DOS within a few eV on either side of E_{F} giving rise to a high, yet relatively invariant absorption coefficient (FIG. 3).

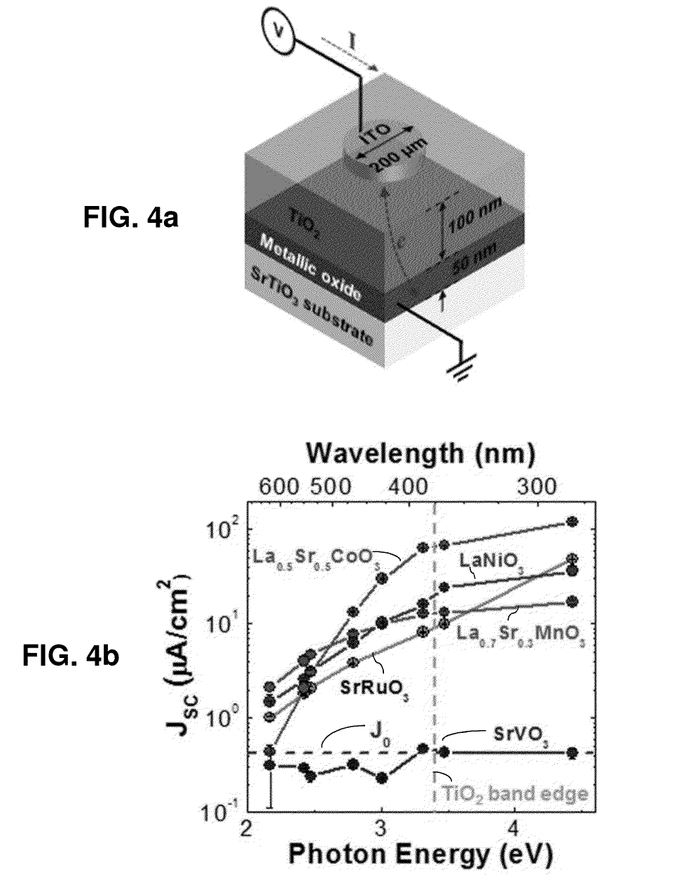

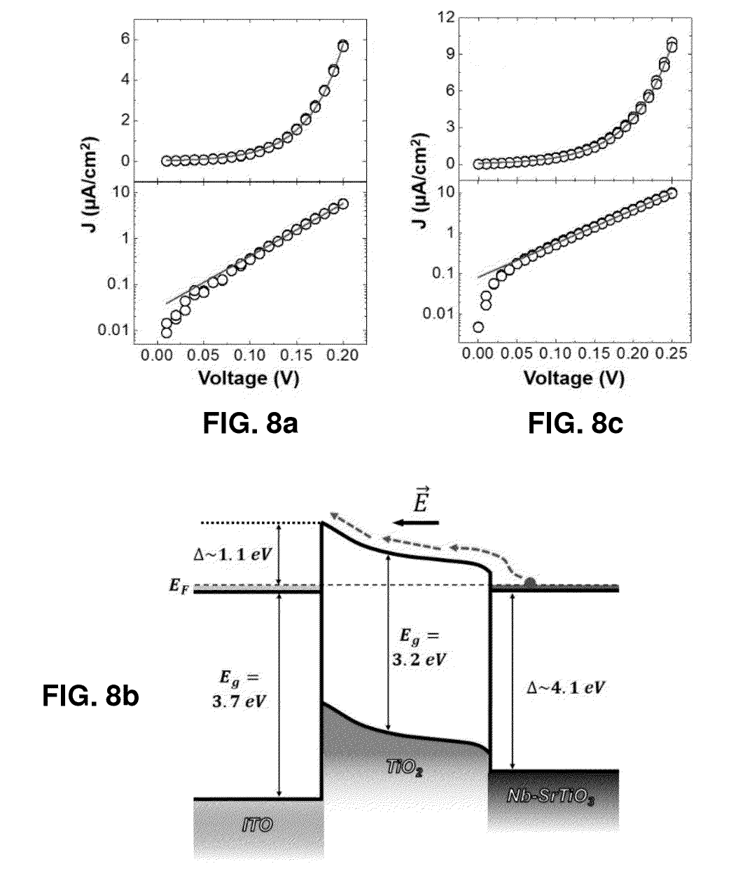

In turn, these materials can be used as the foundation for a range of energy devices. Model photovoltaic devices are probed to provide insight into the nature of the TiO₂/“metallic” oxide junction type and the nature of the photocurrent generation to inform the use of these materials as photocatalysts. The photovoltaic devices studied here have a generic structure of 100 nm 10% SnO₂-doped In₂O₃ (ITO)/100 nm anatase TiO₂/50 nm “metallic” oxide (FIG. 4a). Dark current-voltage (1-V) studies have been completed on these heterojunctions to extract values for the TiO₂/“metallic” oxide barrier heights (see, FIGS. 8a and 8b). Based on published values of work functions for these “metallic” oxide materials, the expected Schottky barrier heights between the TiO₂ and SrRuO₃, La_{0.7}Sr_{0.3}MnO₃, LaNiO₃, La_{0.5}Sr_{0.5}CoO₃, and SrVO₃ are 1.3±0.1 eV, 1.1±0.1 eV, ˜1.0 eV, 0.7±0.5 eV, and 0 eV, respectively. The error bars represent the range of work functions reported in the literature and the value for LaNiO₃ (˜1.0 eV) is based on only one published value. When possible, standard Richardson-Nordheim equation fitting procedures are applied to the dark I-V data to extract experimental barrier heights. For all materials, the experimentally measured barrier heights are consistent with those values noted above; however, for devices based on LaNiO₃ and La_{0.5}Sr_{0.5}CoO₃ the ideality factor from the fit was >2 and thus the accuracy of those fits are questioned. Regardless, these analyses allow for the identification of three different classes of heterojunctions—n-n Schottky (based on SrRuO₃ and LaNiO₃), n-n ohmic junctions (based on SrVO₃), and p-n Schottky (based on La_{0.7}Sr_{0.3}MnO₃ and La_{0.5}Sr_{0.5}CoO₃) junctions.

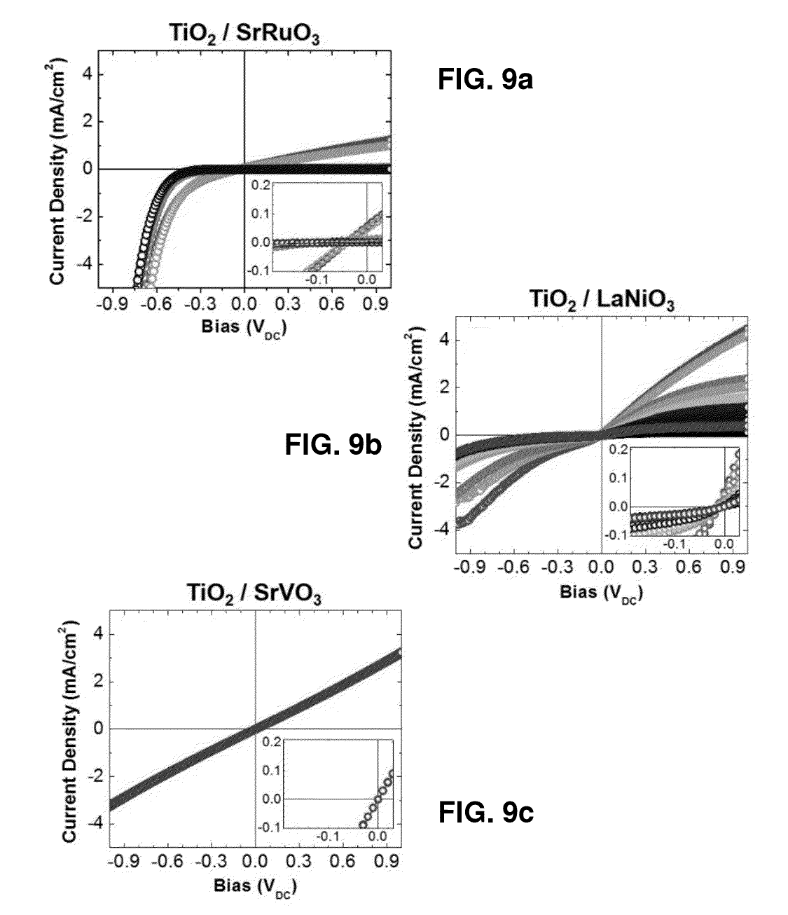

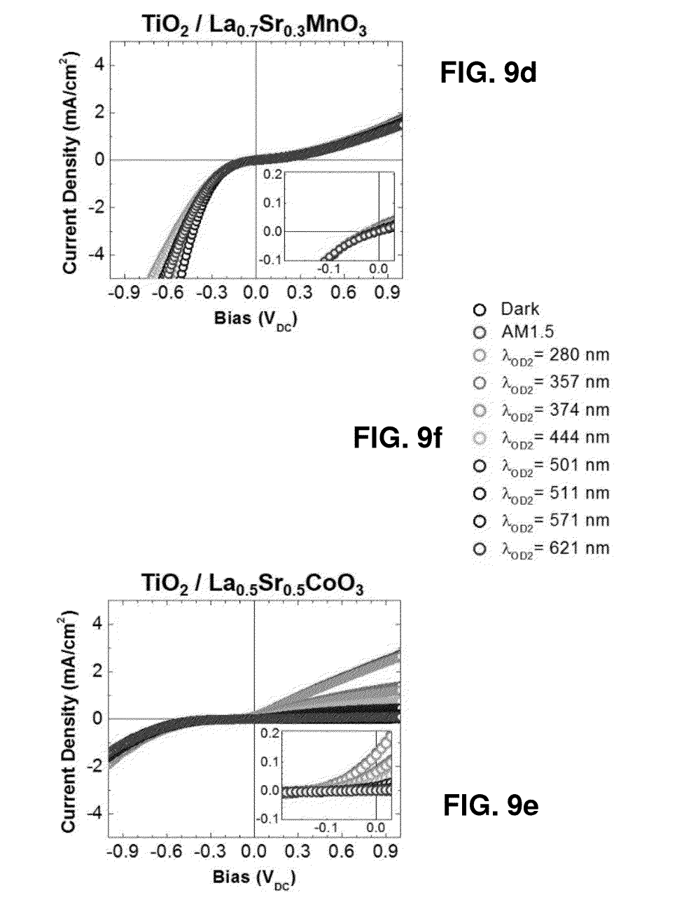

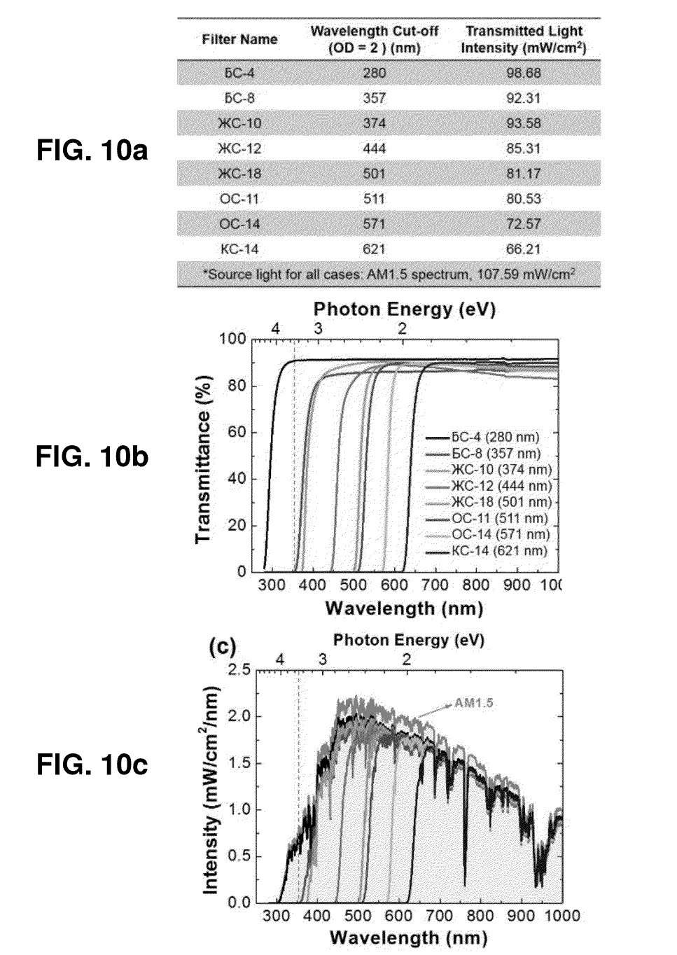

Light I-V studies were completed under illumination by AM1.5G light that was filtered to remove progressively longer wavelengths (details of all light-based measurements are provided below). Full light I-V data sets as a function of cut-off wavelength are provided (along with data on the light filters, FIGS. 9a-9e and FIGS. 10a and 10b), but for simplicity the short circuit current density (J_{SC}) is plotted as a function of the cut-off photon energy (FIG. 4b). For all devices, except that based on SrVO₃, the J_{SC} is observed to be one-to-two orders-of-magnitude larger than the current density in the dark at zero voltage bias (J₀). It is also noted that despite the differences in heterojunction type, the same sign of photocurrent for all TiO₂/“metallic” oxide devices is observed and that although there are variations in the absorption coefficients of the various “metallic” oxide layers across the range of wavelengths studied, normalization of the J_{SC} by the absorbed light intensity across this same range has a negligible effect on the trends observed here.

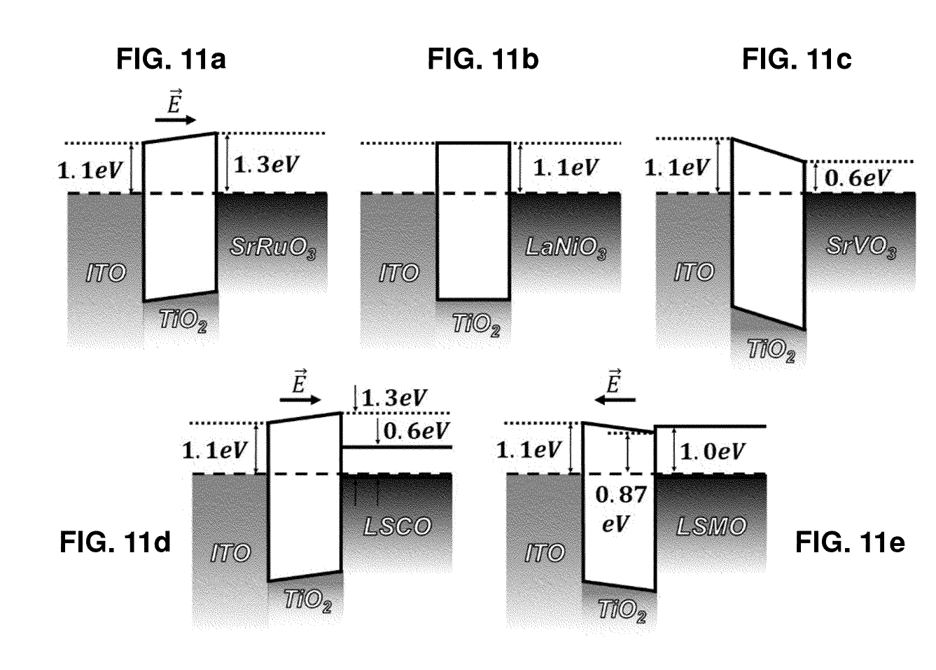

Based on the band gap of the TiO₂, light with energy <3.4 eV (or >364 nm) is not efficiently absorbed by the TiO₂ and, in turn, the existence of J_{SC} under illumination in those conditions demonstrates that the photocurrent is generated from light absorption in the “metallic” oxide as it is the only active light absorbing layer. Additionally, for all devices exhibiting J_{SC} above J₀, (roughly) an exponential increase in the J_{SC} with increasing cutoff energy was observed. The exponential trend is observed in both the n-n and p-n Schottky devices and suggests that as the higher energy light is filtered out, fewer of the photoexcited electrons produced in the “metallic” oxide have sufficient energy to overcome the Schottky barrier and therefore fewer of these electrons diffuse across the TiO₂/“metallic” oxide interface. It is concluded, therefore, that the mechanism of photocurrent generation in these devices is hot electron injection. Devices exhibiting J_{SC}≈J₀ (i.e., those based on SrVO₃) exhibit no photocurrent response because the ohmic junction does not provide a driving force for photocurrent flow (a more detailed description of each photovoltaic device as well as proposed device band diagrams are provided below and in FIGS. 11a-11e).

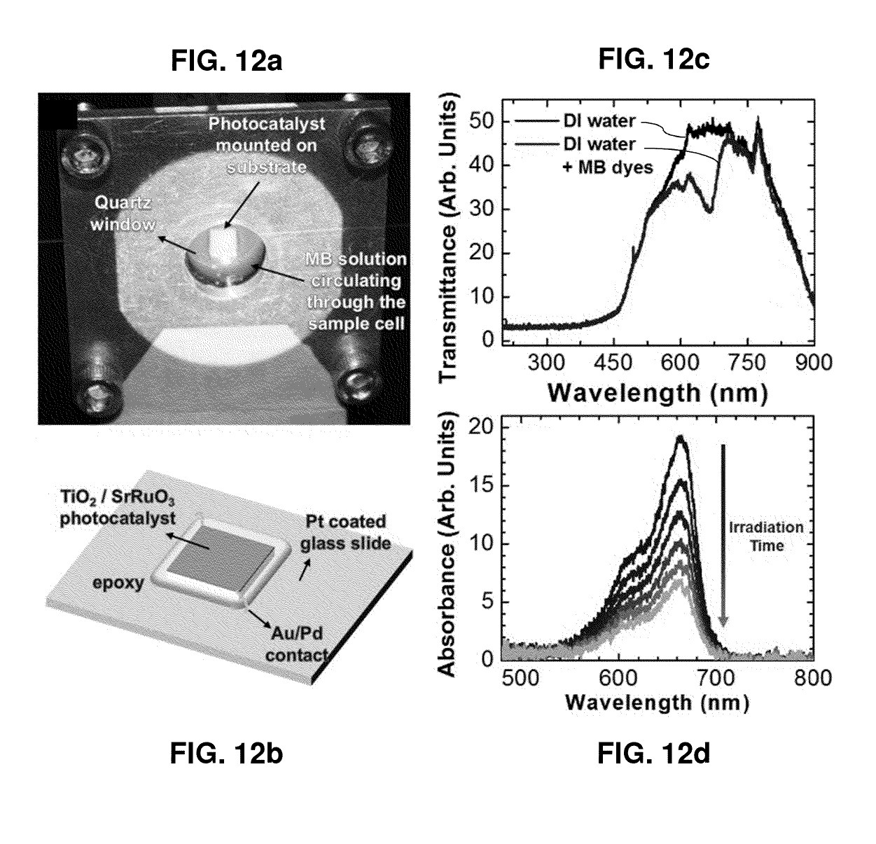

To assess the photocatalytic performance of the TiO₂/“metallic” oxide heterojunctions the degradation rate of methylene blue (MB) was measured, which is a widely used method to evaluate and compare the visible light activities of photocatalysts. All photocatalytic studies were completed on 10 nm TiO₂/50 nm “metallic” oxide heterojunctions where the thickness of the TiO₂ was chosen to be sufficient to protect the “metallic” oxide from photodegradation while still being thin enough to support efficient charge transport (details of the measurements are provided below, FIGS. 12a-12d).

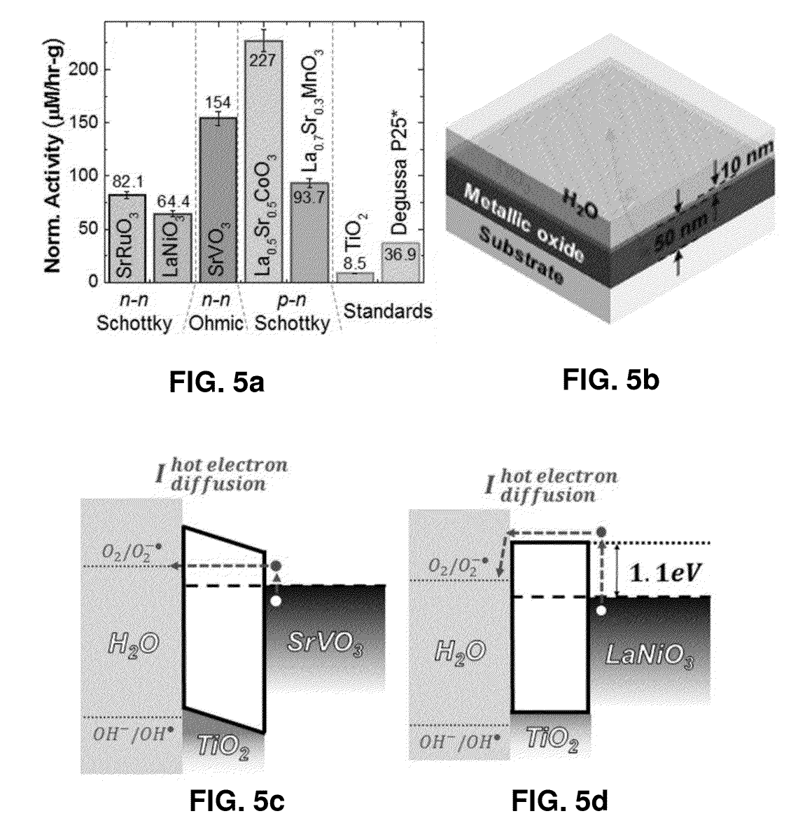

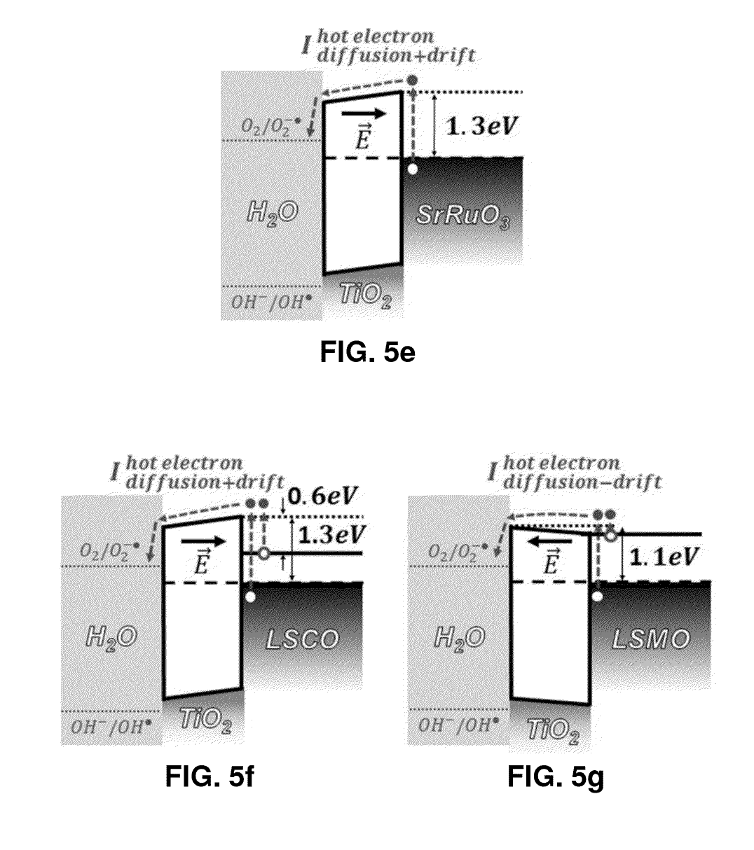

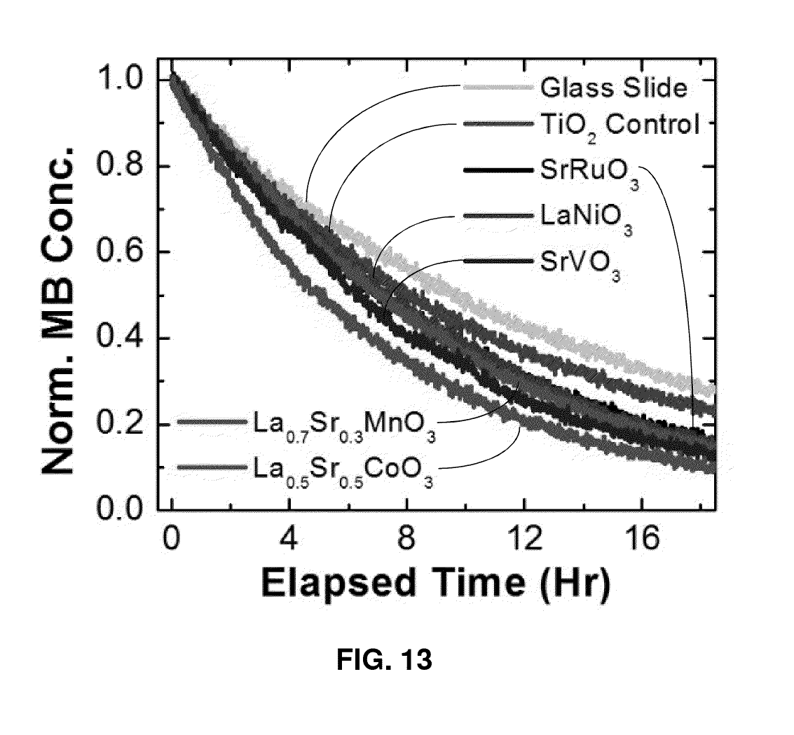

The normalized MB concentration time traces for all the heterojunctions and control samples showed pseudo-first order kinetics allowing the calculation of mass-normalized photocatalytic activity (FIG. 5a and FIG. 13). The highest mass-normalized activity was observed for the La_{0.5}Sr_{0.5}CoO₃-based devices and the lowest for the LaNiO₃-based devices. It should also be noted that the activity in the La_{0.5}Sr_{0.5}CoO₃-based devices is 27- and 6.2-times larger than that for a single-layer TiO₂ film and nanopowder Degussa P25 samples, respectively.

The trends in mass-normalized photocatalytic activity are not simply understandable in the context of light absorption alone, but are a complex function of the interplay of the electronic structure of the “metallic” oxide, light absorption, junction type, barrier height, and built-in electric field. Additionally, to understand the performance of the devices one generally needs to consider the contributions of both drift and diffusion currents to the overall response. Previous studies of electronic transport in anatase thin films, however, have revealed that the diffusion length of electrons in anatase is on the order of only 1 nm. Thus in the case of the photovoltaic device (where there is a 100 nm thick TiO₂ layer) the diffusion current is expected to be negligible and does not contribute significantly to the short-circuit current density while in the case of the photocatalytic device (where there is only a 10 nm thick TiO₂ layer) this likely will not be the case. To further facilitate this discussion and to aid understanding of the operation of the photocatalytic devices, proposed schematic band diagrams (FIGS. 5c-5g) are presented and are meant to qualitatively describe the proposed processes active in each layer. Construction of these band diagrams is informed by highlighting a few similarities among the various devices. First, for all Schottky devices, the TiO₂ layer is fully depleted as a result of the 4-to-6 order-of-magnitude difference in the carrier concentration between the TiO₂ (10¹⁵-10¹⁷ cm⁻³) and the “metallic” oxides. Second, because the “metallic” oxides have a carrier concentration of 10²¹⁻²² cm⁻³, the solution has low ionic conductivity (neutral pH, low MB concentration), and the TiO₂ is only 10 nm thick, the band alignment of the TiO₂ is likely predominantly controlled by the “metallic” oxide and not affected by the reduction/oxidation couples. In other words, there is not thought to be strong pinning or bending of the band structure of TiO₂ as a result of the contact with the solution.

With these similarities in mind, the differences among the various devices are discussed next: first, devices having no built-in electric field in the TiO₂ (SrVO₃ and LaNiO₃); second, devices in which the built-in electric field in the TiO₂ enhances the photocatalytic activity by adding a drift current in the same direction as the diffusion current (SrRuO₃ and La_{0.5}Sr_{0.5}CoO₃); and lastly, the case of the device which has a built-in electric field in the TiO₂ that inhibits (some) of the diffusion current by adding a drift current that opposes the diffusion current (La_{0.7}Sr_{0.3}MnO₃).

The SrVO₃- and LaNiO₃-based devices both have no built-in electric field in the TiO₂. In the case of the SrVO₃-based device (FIG. 5c), this is because the work function of the “metallic” oxide is lower than the E_{F} (i.e., the separation between the Fermi state and vacuum level) of the TiO₂ which results in the formation of an ohmic junction, just as in traditional semiconductor-metal devices. Because the junction is ohmic, there is an accumulation of charges in the TiO₂ and no barrier to hot electron diffusion from the SrVO₃ into the TiO₂. The absence of such a barrier accounts for the SrVO₃-based device possessing the second largest measured mass-normalized photocatalytic activity (154 μM/hr-g) despite having the lowest absorption of the AM1.5G spectrum (33%). For the LaNiO₃-based device (FIG. 5d), the work function of the “metallic” oxide and the E_{F} of TiO₂ are approximately the same magnitude, resulting in the formation of a flat-band Schottky junction with a barrier height of ˜1.0 eV and, as a result of the lack of band bending, no built-in electric field in the TiO₂. The Schottky barrier serves as a barrier to hot electron transport from the “metallic” oxide into the TiO₂ and the lack of any additional driving force (i.e., the lack of built-in electric field in the TiO₂) accounts for the LiNiO₃-based devices displaying the lowest observed mass-normalized photocatalytic activity despite having the second highest absorption of the AM1.5G spectrum (50%). This analysis demonstrates that in the design of all-oxide heterojunction devices based on correlated “metallic” oxides for photocatalysis an ohmic junction greatly enhances the photocatalytic activity by maximizing the hot electron transport via diffusion from the “metallic” oxides to the wide band gap oxide.

The SrRuO₃- and La_{0.5}Sr_{0.5}CoO₃-based devices (FIGS. 5e and 5f, respectively) both have a built-in electric field in the TiO₂ which enhances the photocatalytic activity by adding an additional driving force for the transfer of hot electrons injected into the TiO₂ from the “metallic” oxide to the solution interface. This electric field produces a drift current similar to that seen in traditionally Schottky junction devices. For both devices, the work function of the “metallic” oxide is larger than the E_{F} of the TiO₂ which results in the formation of a Schottky junction and barrier heights of 1.3±0.1 eV and 0.6±0.5 eV for the SrRuO₃— and La_{0.5}Sr_{0.5}CoO₃-based devices, respectively. It is this large difference in barrier heights along with the fact that La_{0.5}Sr_{0.5}CoO₃ absorbs a higher percentage of the AM1.5G spectrum (53%) than SrRuO₃ (44%) that accounts for the 2.7-times higher mass-normalized activity of the La_{0.5}Sr_{0.5}CoO₃ device compared to the SrRuO₃ device. It should also be noted that owing to the presence of a band gap in the La_{0.5}Sr_{0.5}CoO₃ which is not present in the SrRuO₃, there exists a small population of electrons in the conduction band of the La_{0.5}Sr_{0.5}CoO₃ for which there is a lower barrier to injection into the TiO₂. By combining this comparison with our previous discussion of the ohmic and Schottky flat-band devices, it is surmised that a lower Schottky barrier when combined with high light absorption and a built-in electric field that enhances hot electron transport to the solution interface yield the best performing all-oxide heterojunction devices based on correlated “metallic” oxides.

Lastly, the case of La_{0.7}Sr_{0.3}MnO₃-based devices (FIG. 5g) is discussed, where there is a p-n Schottky junction with the TiO₂ and a built-in electric field in the TiO₂ that opposes the hot electron diffusion current. The work function of the La_{0.7}Sr_{0.3}MnO₃ is smaller in value than the E_{F} of TiO₂, but, unlike the case of the SrVO₃ device in which an ohmic junction is formed, La_{0.7}Sr_{0.3}MnO₃ forms a Schottky junction with TiO₂ because La_{0.7}Sr_{0.3}MnO₃ is a p-type “metallic” oxide (i.e., the n-type TiO₂ is completely depleted of free electrons by the transfer of holes from the La_{0.7}Sr_{0.3}MnO₃ when the junction is formed). As in the case of La_{0.5}Sr_{0.5}CoO₃, the presence of a band gap results in a small population of electrons in the conduction band of the La_{0.7}Sr_{0.3}MnO₃ for which there is a significantly lower barrier (˜0.1 eV) to the injection of hot electrons into the TiO₂. The net result is that while the La_{0.7}Sr_{0.3}MnO₃ has the second lowest absorption, it exhibits a mass-normalized activity slightly higher than that of the SrRuO₃, but significantly lower than the La_{0.5}Sr_{0.5}CoO₃ devices due completing effects of barrier height, electric field, and electronic structure. This analysis suggests that it is crucial to understand the direction of band bending or the built-in electric field as it plays a significant role in driving the hot electrons in the devices.

In conclusion, this Example studies the optical, photovoltaic, and photocatalytic response of TiO₂/correlated “metallic” oxide heterojunctions. Ellipsometric studies of the “metallic” oxides reveal that as a result of the complex electronic structure of these materials, they possess low reflectance and high absorption coefficients that enable up to 53% of AM1.5G light to be absorbed by only 50 nm thick films. Upon studying the photovoltaic and photocatalytic response of heterojunctions based on these materials a number of important features were observed. First, by controlling the work function and carrier type of the “metallic” oxide, three different types of heterojunctions can be produced: n-n Schottky, n-n ohmic, and p-n Schottky junctions. In turn, this gives rise to a range of different photovoltaic responses that are dominated by hot electron injection from the “metallic” oxide into the TiO₂. Photocatalytic studies based on these materials reveal that the activity of the heterostructures is highest for Schottky junctions where the “metallic” oxide possesses strong light absorption, the device has a low barrier height, and the built-in electric field in the TiO₂ enhances hot electron transport from the “metallic” oxide to the solution interface. Additionally, heterostructures exhibiting ohmic junctions (i.e. no barrier to hot electron diffusion) can overcome limitations in light absorption to show enhanced activity. In turn, the combination of “metallic” oxide with TiO₂ enables the production of systems that greatly outperform TiO₂ films alone and other common TiO₂-based nanoparticle systems. These conclusions provide a framework for the rational design of photoelectrochemical all-oxide devices utilizing hot electron injection and illustrate how correlated electron systems can significantly enhance performance in energy systems.

“Metallic” Oxide Thin Film Growth.

Films were grown using pulsed-laser deposition. For all cases, both single-layer “metallic” oxide and TiO₂/“metallic” oxide heterojunctions were produced for study. For the single-layer “metallic” oxide films, all films were cooled from the deposition temperature in 760 Torr of oxygen following growth. For the TiO₂/“metallic” oxide heterojunctions, films were cooled at the growth pressure to the deposition temperature of the TiO₂ (600° C.) where the pressure in the chamber was set to 1 mTorr for the growth of TiO₂. Following growth, the TiO₂/“metallic” oxide films were cooled from the growth temperature in 1 mTorr of oxygen. Thin films of SrRuO₃ were grown at a laser fluence of 1.0 J/cm² at a laser repetition rate of 5 Hz at 660° C. in 100 mTorr of oxygen. Thin films of LaNiO₃ were grown at a laser fluence of 1.4 J/cm² with a laser repetition rate of 5 Hz at 650° C. in 100 mTorr of oxygen. Thin films of SrVO₃ were grown at a laser fluence of 1.0 J/cm² with a laser repetition rate of 3 Hz at 660° C. in 1×10⁻⁵ Torr. Thin films of La_{0.5}Sr_{0.5}CoO₃ were grown at a laser fluence of 1.4 J/cm² with a laser repetition rate of 3 Hz at 625° C. in 100 mTorr of oxygen. Thin films of La_{0.7}Sr_{0.3}MnO₃ were grown at a laser fluence of 1.6 J/cm² with a laser repetition rate of 5 Hz at 700° C. in 200 mTorr of oxygen. All TiO₂ films were grown at 600° C. at a laser fluence of 1.1 J/cm² with a laser repetition rate of 5 Hz in 1 mTorr of oxygen. Thickness of all films was measured ex situ via fitting of x-ray diffraction Kiessig fringes and x-ray reflectivity studies. The transparent conducting oxide used in this study was 10% SnO₂-doped In₂O₃ (ITO). 100 nm thick ITO thin films were deposited through photolithography defined photoresist masks at a laser fluence of 1.0 J/cm² at a laser repetition rate of 5 Hz at room temperature in 20 mTorr of oxygen. Following the growth process and the removal of photo-resist, samples were annealed at 300° C. for 30 minutes in 20 mTorr of oxygen and subsequently cooled to room temperature at 20 mTorr to improve electronic and optical properties of the ITO.

Electronic Transport Studies of Metallic Oxides.

Electronic transport measurements were completed in the four-point van der Pauw geometry. Electrical contact to the thin “metallic” oxide films was made by directly wire bonding 10 μm diameter aluminum wire to the films. Temperature and magnetic field dependent resistivity and Hall measurement studies were completed in a Quantum Design, Physical Property Measurement System (9 T).

Because the “metallic” oxides are utilized as both electrode and light absorber, both their optical (discussed above) and electronic transport properties must be considered in order to evaluate material quality and device performance. Thus, the temperature and magnetic field dependent transport properties of 50 nm epitaxial thin films of SrRuO₃, SrVO₃, and La_{0.7}Sr_{0.3}MnO₃ on SrTiO₃ (001) and of La_{0.5}Sr_{0.5}CoO₃ and LaNiO₃ on LaAlO₃ (001) were measured. Temperature-dependent resistivity in the films confirmed their quality and was consistent with previously published reports (FIG. 6a). From these measurements the majority carrier mobility (p), the room temperature resistivity (p), and the carrier concentration (N) have been extracted and summarized (FIG. 6b). The relatively small variation in transport properties among these materials is not expected to significantly impact the relative performance of the photovoltaic and photocatalytic devices and consideration of the light absorption, junction type, and barrier height are sufficient to make definitive comparisons among the “metallic” oxides.

Optical Property Measurements via Spectroscopic Ellipsometry.

Variable angle ellipsometry measurements were completed in a V.A.S.E. (J. A. Woollam Co, Inc.). The optical constants (refractive index, n, and extinction coefficient, k) were obtained by fitting a pseudo-n and -k value to generate best-fits to the measured Ψ and Δ using the V.A.S.E. program. The thickness of the “metallic” oxide films was known to within <1% error from x-ray reflectivity measurements and fitting the observed Kiessig fringe peaks from θ-2θ scans. The reflectance (R) is calculated from the equation

$$R = \frac{{( n - 1 )}^{2} + {k}^{2}}{{( n + 1 )}^{2} + {k}^{2}}$$

and absorption coefficient was calculated from the equation by

$$α = \frac{4 π k}{λ} .$$

A full characterization of the optical properties of the 50 nm epitaxial films of SrRuO₃, LaNiO₃, SrVO₃, La_{0.7}Sr_{0.3}MnO₃, and La_{0.5}Sr_{0.5}CoO₃ was completed (FIGS. 7a-7e).

AM1.5G Solar Light Absorption Calculations.

The amount of AM1.5G spectrum absorbed by a 50 nm thick “metallic” oxide thin film was found by the following procedure (SrRuO₃ is used here as an example): First, the reflectance for normal incidence light on the “metallic” oxide layer was calculated using

$$R = \frac{{( {n}_{SRO} - {n}_{air} )}^{2} + {k}_{SRO}}{{( {n}_{SRO} + {n}_{air} )}^{2} + {k}_{SRO}} ,$$

where the optical constants were found experimentally for our films from the ellipsometry measurements. The non-reflected light spectrum (I₁) was then calculated from the reference AM1.5G spectrum (I₀) (as obtained from the ASTM G-173-03 Reference Spectra) as I₁=I₀(1−R). This gives us a measure for the non-reflected light that enters of the SrRuO₃ layer. From there, by considering the absorption coefficient (as calculated by

$$α = \frac{4 π {k}_{SRO}}{λ} )$$

the transmitted light intensity (I₂) was calculated using the Beer-Lambert law (I₂=I₁e^{-αt}) where t is thickness of the SrRuO₃ film. Finally, the absorbed light spectrum is obtained by subtracting I₂ from I₁.

Dark and Light Current-Voltage Studies of Photovoltaic Devices.

To quantitatively determine the band structure of the TiO₂/“metallic” oxide heterojunctions, the Schottky barrier height between the 10% SnO₂-doped In₂O₃ (ITO) and TiO₂ was first characterized and then this information was used to determine the Schottky barrier height between the TiO₂ and the various “metallic” oxides. To find the Schottky barrier height between ITO and TiO₂, a 100 nm thick TiO₂ film on a 0.5% Nb-doped SrTiO₃ (001) substrate was prepared. This substrate was chosen because it has a relatively invariant work function of 4.1 eV. Via standard microfabrication processes, top contacts of ITO were defined and the current-voltage (1-V) characteristics of the devices were measured. The resulting diode curves (in dark) were fit in the forward voltage bias region (FIG. 8a) to the Richardson-Nordheim equation based on thermionic emission:

$${J}_{f} = {A}^{*} {T}^{2} exp ( \frac{- q φ}{kT} ) exp ( \frac{{qV}_{f}}{nkT} ) ,$$

where J_{f} is current density under forward voltage bias, A* (A*=m_{eff}×120 A cm⁻²K⁻²) is the effective Richardson constant, T is the temperature, q is electron charge, k is the Boltzmann constant, V_{f} is the forward voltage bias, and n is ideality factor. With known Richardson constants of 120-150 A cm⁻²K⁻² (the effective mass of anatase TiO₂ ranges from 1.0 to 1.25 m₀), a Schottky barrier height of ˜1.11 eV was obtained and an ideality factor of ˜1.5 for the ITO/TiO₂ interface. Based on this value, the proposed band diagram for ITO/TiO₂/0.5% Nb-doped SrTiO₃ was able to be generated (FIG. 8b). With this information about the barrier at this interface, studies of ITO/TiO₂/“metallic” oxide heterostructures were undertaken. As an example, shown here are the fit for the ITO/TiO₂/SrRuO₃ heterojunction (FIG. 8c). As before, dark diode curves were fit to the Richardson-Nordheim equation and combined with the previously measured ITO/TiO₂ Schottky barrier height to give a Schottky barrier height for the TiO₂/SrRuO₃ interface of ˜1.3 eV (ideality factor ˜1). It should be noted that this measured barrier height between TiO₂ and SrRuO₃ is consistent with the value calculated from the work function of SrRuO₃ (5.2 eV) and the electron affinity of anatase TiO₂ (3.9 eV). A complete set of dark- (and light-) based I-V studies for all devices are provided (FIGS. 9a-9e).

Using the same approach the remaining ITO/TiO₂/“metallic” oxide heterojunctions were characterized. For the TiO₂/LaNiO₃ heterojunction (FIG. 9b), rectifying behavior was observed with low reverse bias current. From measurements, the work function of the LaNiO₃ is estimated to be ˜5.0 eV. Note that this value is somewhat larger than the limited published values (4.65 eV) but that it has been observed that the work function of “metallic” oxides can vary depending on synthesis methods and conditions (for instance, the work function of SrRuO₃ has been reported between 4.8-5.2 eV). Additionally, the presence of a small reverse-bias current in the dark I-V data could also indicate the presence of trap and defect states (e.g. Ni⁺³) and electrons that are subsequently excited from those states (producing a “generation current”) at the TiO₂/“metallic” oxide interface could also impact the work function found by the diode curve fitting as seen by the high ideality factor. For the TiO₂/SrVO₃ heterojunction (FIG. 9c), based on published values of the work function of SrVO₃ (4.5 eV) ohmic contact is expected between the TiO₂ and SrVO₃. The dark I-V response is consistent with this prediction and nearly ideal ohmic behavior is observed. The TiO₂/p-type “metallic” oxide heterojunctions, are both predicted to form Schottky junctions based on the published work function values for La_{0.7}Sr_{0.3}MnO₃ (4.4-4.96 eV) and La_{0.5}Sr_{0.5}CoO₃ (4.2-5.2 eV), and the observed dark I-V diode response is consistent with these predictions (FIGS. 9d and 9e, respectively). Both heterojunctions also show a small reverse-bias current attributable to a “generation current” similar to that observed in the TiO₂/LaNiO₃ device and are possibly from Mn⁺³ and Co³⁺ defects in TiO₂ at the interface. Again, note that the fits for both the LaNiO₃ and La_{0.5}Sr_{0.5}CoO₃-based devices have ideality factors >2 making the fitting of dark I-V curve less accurate.

The light measurements were completed using a collimated 300 W Xe arc lamp with an AM1.5G filter and condenser lens (Newport Corp.) used to produce 100 mW/cm² power density as the light source. In the case of the I-V measurements, a condenser lens was used to focus the light into a single-fiber fiber optic cable with a focusing lens at the terminus to produce a light spot 2 mm in diameter on the sample producing light with power density 106 mW/cm². To further probe the light-dependent properties, a series of longpass glass filters were utilized to cut-off increasingly larger wavelengths of light from the UV to NIR range. A table with the various filters used in this study, the longpass optical density of 2 wavelength cut-off (λ_{OD2}), and the transmitted light intensity is provided (FIG. 10a). Graphical representations of the transmitted light from the various longpass glass filters is also shown (FIG. 10b) as are the transmitted light curves for each filter with an AM1.5G spectrum source (FIG. 10c). All of the longpass glass filters have sharp cut-off wavelengths and high transmittance of at least 80% across the remainder of the visible light range. Full light-based I-V studies of all devices are provided (FIGS. 9a-9e).

Photovoltaic Device Analysis.

Proposed band diagrams for TiO₂/“metallic” oxide heterojunctions are presented based on the published work functions of those materials and the calculation of barrier heights obtained from the fitting of Richardson-Nordheim equation (FIGS. 11a-11e). For TiO₂/SrRuO₃ heterojunctions the devices are strongly rectifying as a result of the Schottky junction formed at the TiO₂/SrRuO₃ interface. Light absorption in the SrRuO₃ produces hot carriers which diffuse into the TiO₂ via a random process and are then swept by the built-in electric field in TiO₂ toward the ITO top contacts (FIG. 11a). For TiO₂/LaNiO₃ heterojunctions there is a slightly lower barrier (˜1.1 eV) at the TiO₂/LaNiO₃ interface than that found in the SrRuO₃-based device; however, because the Fermi energy (E_{F}) (i.e., the separation of the Fermi state in TiO₂ and the vacuum level) of the TiO₂ has the same value as the work function of LiNiO₃, there is no band banding in the TiO₂ and thus no built-in electric field exists. The result is that there is no driving force for extraction of the hot electrons in the TiO₂ to the ITO contacts (FIG. 11b). For the TiO₂/SrVO₃ heterojunctions, the nature of the contact is ohmic and therefore there is no driving force for extraction of hot carriers to the ITO top contacts which results in no photocurrent in the photovoltaic devices (FIG. 11c). The TiO₂/La_{0.5}Sr_{0.5}CoO₃ heterojunctions function similarly to the SrRuO₃-based devices, in that the devices are Schottky and the built-in electric field in TiO₂ drives the hot electrons to the ITO contacts. The La_{0.5}Sr_{0.5}CoO₃-based devices, however, have two barrier heights: 0.6 eV for hot electrons excited from the conduction band of the “metallic” oxide, and 1.3 eV for hot electrons excited from the E_{F} of the “metallic” oxide (FIG. 11d). Lastly, the TiO₂/La_{0.7}Sr_{0.3}MnO₃ heterojunctions are also Schottky in nature and, like the La_{0.5}Sr_{0.5}CoO₃-based devices, have two different barrier heights: ˜0.1 eV for hot electrons excited from the conduction band and ˜1.1 eV for electrons excited from the E_{F} of La_{0.7}Sr_{0.3}MnO₃. Unlike all the other Schottky devices, because the work function of La_{0.7}Sr_{0.3}MnO₃ is larger than the E_{F} of TiO₂, the band banding in TiO₂ produces a built-in electric field which opposes the photocurrent of electrons to ITO top contacts (FIG. 11e).

Methylene Blue De-Coloration Photoactivity Studies.

The illumination source was a collimated 300 W Xe arc lamp with a filter and condenser lens to produce 3,760 mW/cm² of full AM1.5G spectrum light. Methylene blue (MB) de-coloration experiments were performed using a closed-loop test apparatus, which recirculates a MB solution from a reservoir open to atmospheric pressure with an initial concentration of 1.04 ppm in de-ionized water (pH=7) at a flow rate of 13.4 mL/min. The reaction chamber is composed of the mounted sample, a PDMS block with a cylindrical void containing penetrations for incoming and outgoing fluid connections, and a quartz window. This assembly is held in place vertically by a compression plate and the light from the condenser lens was centered on the sample (FIG. 12a, note that the light in the figure is without the condenser lens present for the purposes of obtaining a photograph). The size of the light spot was measured by exposure to thermal paper and was completely contained within the sample area so that no direct light was incident on the electrical connections or the platinum. The samples were mounted on platinum-coated borosilicate glass slides with 2-part epoxy. The total surface area of platinum was controlled to be 1.18 cm². Electrical connection was made from the “metallic” oxide to the platinum with silver paint and all electrical connections as well as the sides of the sample and substrate were covered with epoxy to prevent exposure to the solution (FIG. 12b). The samples were run for 2 hours in the dark to establish a base-line for the MB adsorption on the sample and then were exposed to 3,760 mW/cm² full AM1.5 spectrum light. The MB concentration was measured in situ by light absorption using a tungsten lamp with a Teflon UV-filter and photodetector (Ocean Optics) every minute at the peak light absorption wavelength of MB (665 nm) (FIGS. 12c and 12d).

Control samples (a plain glass slide with no platinum and a 10 nm TiO₂ film (no “metallic” oxide) on a platinum-coated slide) were run and the MB decomposition rate was found to be the same for both control samples within the error of the measurement (±5%). The time evolution of the MB solution concentration for each sample was normalized to the initial concentration and the resulting exponential decay curves (FIG. 13) indicative of a first-order or pseudo-first-order reaction) were fit to find the rate constant, k, i.e. C=C₀e^{-kt}. Because both the control samples and heterostructures had first-order kinetics, the rate constant for the control samples was subtracted from the measured rate constant of the TiO₂/“metallic” oxide heterojunctions to determine the rate constant of only the TiO₂/“metallic” oxide heterojunctions.

The data presented in FIG. 5a above includes error bars that include contributions to error from the measurement process and sample variation. Experimental error is thought to arise from variations in flow rate, starting solution mass, residual MB solution in the lines, light intensity and spot size, and other effects that give rise to an error of 4-5% across all samples. Additionally, from these studies, the standard deviation of the rate constants (and activities) observed for these samples is generally between 5-10%. Using a root-mean-square calculation of total uncertainty (experimental error and sample standard deviation) error bars are produced. Even with this aggressive error calculation, the trend in activity is unchanged.

Mass Normalized Photocatalysis Activity.

To put the observed photocatalytic activity of the heterostructures into context with the well-studied material Degussa P25, a mass normalized photocatalytic activity was calculated. This is found by multiplying the measured rate constant by the initial MB concentration. This value is then divided by the sum of the mass of the “metallic” oxide and the TiO₂ in the heterostructure as found by the product of the thickness and the bulk mass density. The results are shown in FIG. 5a above. As can be seen, the mass normalized activities for all the heterostructures in this study are higher than for Degussa P25 as measured under similar pH and illumination conditions. It is noteworthy that the La_{0.5}Sr_{0.5}CoO₃-based heterostructure has the mass normalized activity and is more than 27-times greater than Degussa P25.

### Example 2

### Strong Visible-Light Absorption and Hot-Carrier Injection in TiO₂/SrRuO₃ Heterostructures

The primary feature limiting the performance of oxide-based photovoltaic and/or photocatalytic systems has traditionally been the poor absorption of visible light in these often wide band gap materials. One candidate oxide material for such applications is anatase TiO₂ which is arguably the most widely-studied photocatalyst (due to its chemical stability, non-toxicity, low-cost, and excellent band alignment to several oxidation-reduction reactions) and the backbone of dye-sensitized solar cells where the presence of a light-absorbing dye accounts for the critical flaw of TiO₂: a large band gap (3.2-3.6 eV) which limits efficient usage of all but the UV portion of sunlight. When designing next generation solar energy conversion systems (i.e., photovoltaics, photocatalysis, etc.) the goal is clear: develop a way to more efficiently utilize the solar spectrum. To address this material deficiency, research has focused on two major approaches: 1) chemical modifications to tune the band gap of TiO₂ and 2) synthesis of composite heterojunctions that combine strong light absorbing materials with the catalytic activity of TiO₂.

In this spirit, considerable effort has focused on doping or alloying TiO₂ to change the band gap. This work falls into two main categories: 1) metal- or 2) non-metal doping. Metal-doping is believed to generate new energy levels (i.e., defect states) within the band gap and it is thought that transition metal doping can also improve the trapping of electrons to inhibit electron-hole recombination during irradiation but generally results in degraded charge carrier lifetimes. Non-metal doping is thought impact the band structure in one of a number of possible ways, but the most effective has been through band gap narrowing as was observed in N-doped TiO₂ where the band gap can be narrowed by ˜0.72 eV as a result of the N 2p states hybridizing with the O 2p states. Regardless of the mechanism at play, these approaches have been demonstrated to be only minimally effective at impacting the electronic structure and properties. At the same time, much work has explored the concept of what has generically been called photochemical diodes. By combining TiO₂ with another semiconductor (i.e., one that might promote additional light absorption or more efficient charge separation) the overall performance can be improved. Much work has been completed in this field including combining TiO₂ with small band gap semiconductors such as CdS and other oxide semiconductors such as SnO₂ and ZnO.

More recently, much attention has been given to a topic called hot-carrier injection. Hot-carrier injection has been demonstrated to be important for photovoltaics because it could provide a way to overcome classical theoretical efficiencies in traditional semiconductor devices by utilizing high-energy, photo-excited carriers with very short lifetimes instead of relying on minority carrier transport. Recently hot-carrier injection was observed in quantum-dot-PbSe/Rutile-TiO₂, wherein injection was attributed to the slow electronic relaxation of the PbSe and accepting surface states on the TiO₂ thereby avoiding losses resulting from the thermalization of photo-excited carriers. The role of hot-carrier injection has also been explored in the context of photocatalysis.

This example explores a new manifestation of a TiO₂-based composite heterojunction designed to promote more efficient utilization of the solar spectrum for energy applications. This example reports on photovoltaic and photocatalytic effects in heterojunctions of anatase TiO₂ together with a strongly absorbing “metallic” oxide SrRuO₃ that has structural, electronic, and chemical compatibility with TiO₂. SrRuO₃ is a correlated electron oxide which is known to possess metallic-like temperature dependence of its resistivity and itinerant ferromagnetism and for its widespread utility as a conducting electrode in oxide heterostructures. Referring to this material as a “metal,” however, is likely inappropriate as the electronic structure and properties are derived from a combination of complex electronic structures, electron correlations, and more. It is observed that the complex electronic structure of SrRuO₃ is also responsible for unexpected optical properties including high absorption across the visible spectrum and low reflection compared to traditional metals. By coupling this material to TiO₂ enhanced visible light absorption and large photocatalytic activities are demonstrated. The devices function by photo-excited hot-carrier injection from the SrRuO₃ to the TiO₂. This observation provides an exciting new approach to the challenge of designing visible-light photosensitive materials.

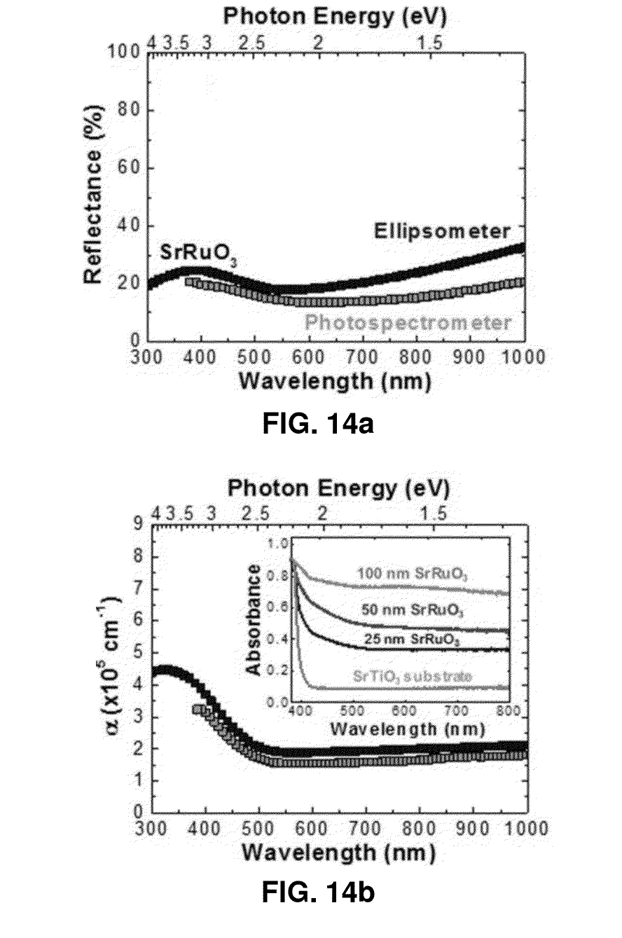

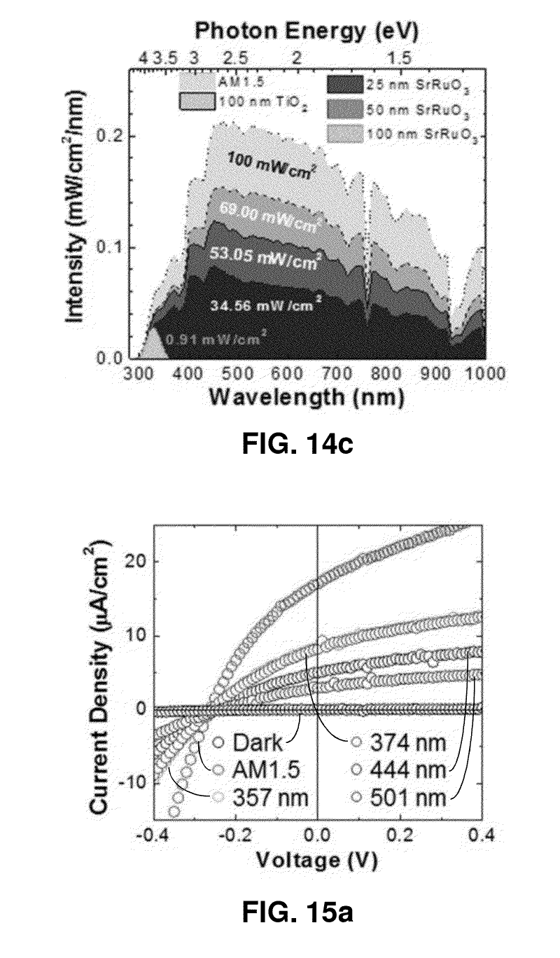

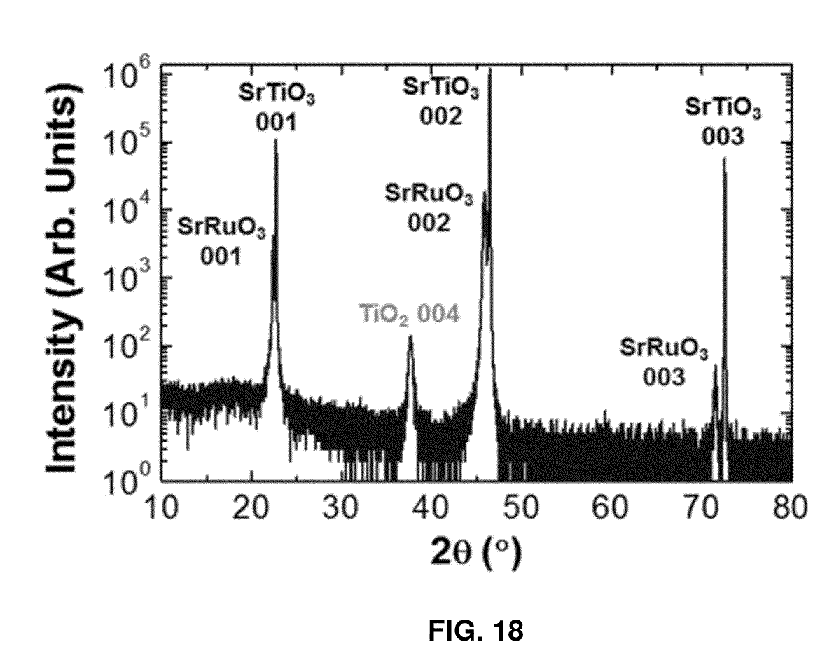

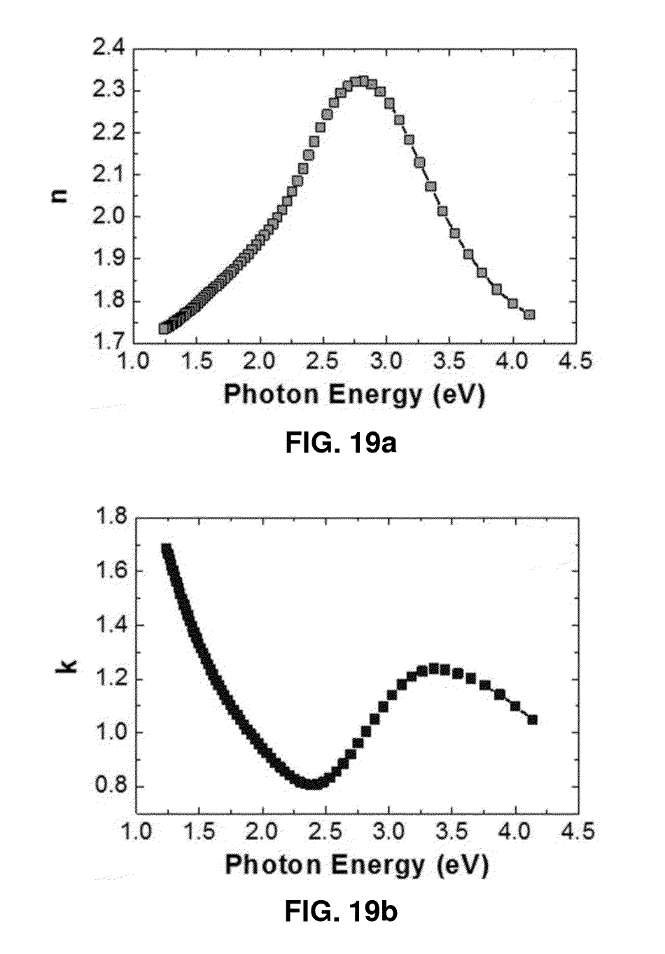

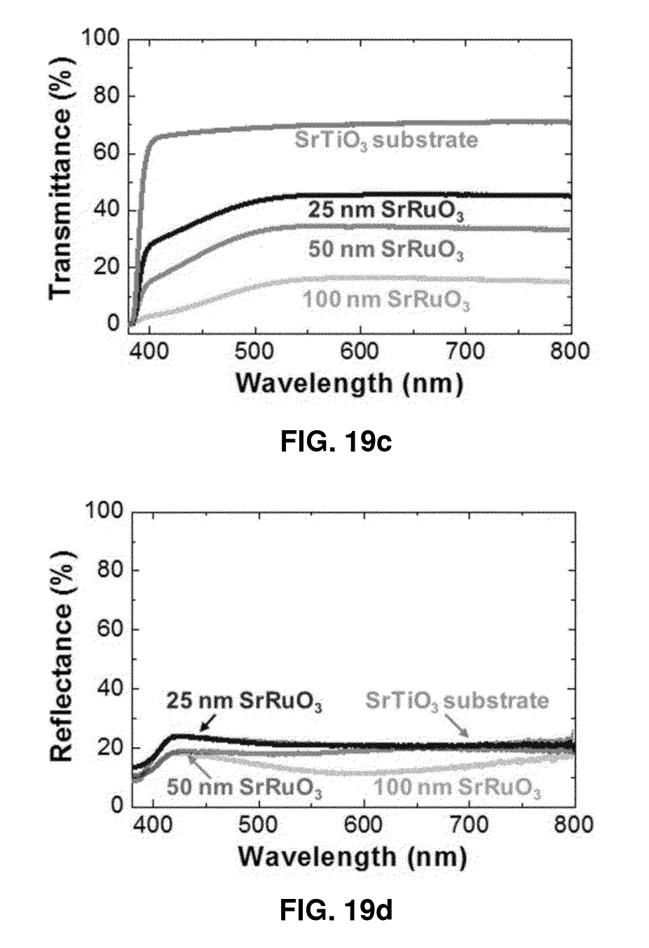

Epitaxial thin film versions of the materials of interest were grown via pulsed-laser deposition details of which are provided in the Experimental Section. For this work, SrRuO₃ thin films were varied from 5-100 nm, anatase TiO₂ films were varied from 10-100 nm, and all films were grown on SrTiO₃ (001) substrates. X-ray diffraction studies for single-layer TiO₂ and SrRuO₃ films and heterojunction films are provided below and in FIG. 18. Following growth and structural characterization, the optical properties of the SrRuO₃ thin films were studied in detail. The optical properties were characterized by photospectrometry (to probe UV-Visible-near-IR transmittance, reflectance, and absorbance) and variable-angle spectroscopic ellipsometry (to probe refractive index, n, and extinction coefficient, k). The reflectance of a 50 nm SrRuO₃/SrTiO₃ (001) heterostructure, as measured by photospectrometry and calculated from n and k (see FIGS. 19a and 19b), was found to be 20-25% across the entire range of visible light (FIG. 14a). As a comparison, the values of reflectance for representative elemental metals Al, Au, Pt, and Ti are generally in excess of 80-90% across the same range of wavelengths. The discrepancy between the low reflectance in the SrRuO₃ and the elemental metals indicates that the complex electronic structure of the former gives rise to dramatically different optical properties. Additionally, the absorption coefficient (a) (calculated from transmission and reflection data (see FIGS. 19c and 19d) and from k) (FIG. 14b), is found to peak at ˜320 nm and shows high values (in excess of 1.5×10⁵ cm⁻¹) across the entire visible light range. For comparison, the absorption coefficient for the widely used semiconductor silicon is approximately 1-to-3 orders-of-magnitude smaller than that of SrRuO₃ across this same range of wavelengths. Furthermore, the absorbance of the SrRuO₃ films is observed to increase with increasing film thickness and matches the trend expected from the Beer-Lambert law (FIG. 14b, inset).

The implication of this absorption for solar energy applications is illustrated by comparing the fraction of the AM1.5G light spectrum that is absorbed by SrRuO₃ and TiO₂ (FIG. 14c). A 100 nm TiO₂ thin film absorbs only 0.91 mW/cm² of the 100 mW/cm² AM1.5G spectrum (orange area, FIG. 14c) while a 100 nm SrRuO₃ thin film absorbs a remarkable 69 mW/cm² (FIG. 14c). These results indicate that SrRuO₃, despite exhibiting the electronic character of a bad metal (decreasing resistivity with decreasing temperature), behaves optically as a semiconductor. Again, for comparison, a 100 nm thick film of silicon would absorb only 6.9 mW/cm²—an order of magnitude less than the SrRuO₃ of the same thickness. Additionally, although SrRuO₃ has been widely studied in the condensed matter physics community and is utilized as a metal oxide electrode for the epitaxial growth of many functional oxide thin-film devices the use of this material as an optical absorber for photosensitive devices has not been considered.

This strong light absorption is supported by experimental and first-principle studies of the electronic structure. In SrRuO₃ there is a high electronic density-of-states (DOS) at the Fermi energy (E_{F}) associated with a quasiparticle band and occupied and unoccupied portions of the split Ru t_{2g} bands. This structure, which has been explained using dynamic mean field theory, arises because SrRuO₃ exists near a Mott transitions and thus its one-particle spectral function will be split into two Hubbard bands in addition to the quasiparticle band located at the E_{F}. Additionally, the upper Hubbard band may further split into states of t_{2g} and e_{g} symmetry. For SrRuO₃ electron-electron correlations are quite weak and the Hubbard bands merge to form a single partly filled band at E_{F}. The result is that in SrRuO₃ there is essentially a continuous DOS above E_{F} which allows for optical inter- and intra-band transitions between states and corresponding continuous light absorption across the solar spectrum. The combination of low reflection and high absorption, the lack of a distinct band gap, and a continuous DOS near and above E_{F} make SrRuO₃ an exciting light absorbing material.

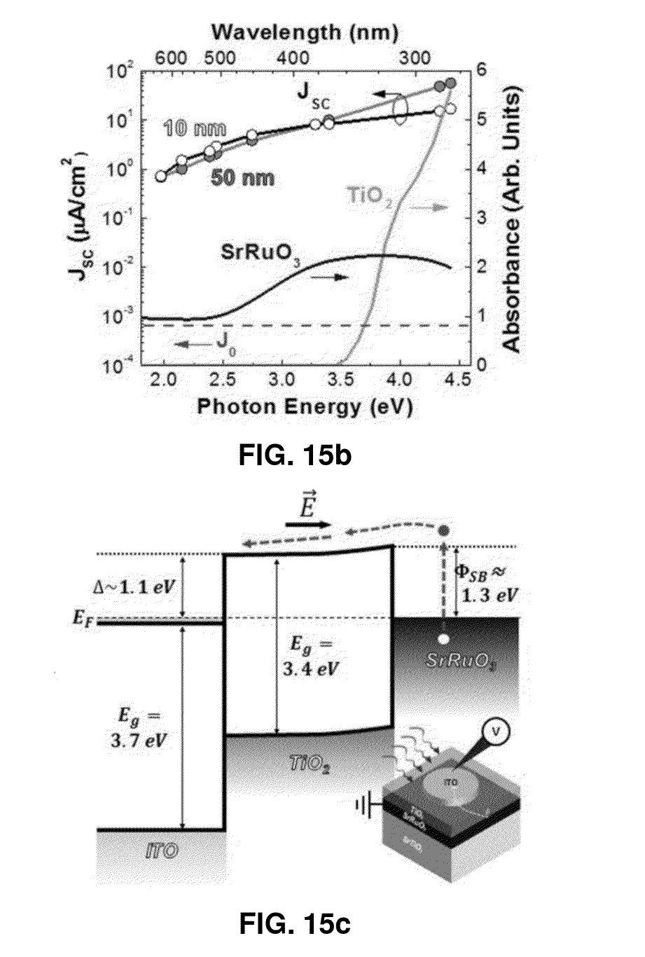

The potential of SrRuO₃-based heterostructures for solar applications was studied by investigating the photo-excited carrier generation and transport in 100 nm TiO₂/50 and 10 nm SrRuO₃/SrTiO₃ (001) Schottky junction photovoltaic devices. 100 nm thick, 100 μm diameter circular top contacts were created using the transparent conducting oxide 10% SnO₂-doped In₂O₃ (ITO) and the resulting devices were used to measure dark and light current-voltage (1-V) characteristics (FIG. 15a). Light measurements were completed using a range of longpass glass filters in order to differentiate the photocurrent generated from light absorption in the SrRuO₃ alone as compared to that from the entire TiO₂/SrRuO₃ heterojunction. In all cases, AM1.5G light was used as the starting illumination and longpass glass filters cutting off progressively more of the AM1.5 spectrum at increasing wavelengths were used to step through the solar spectrum (details of all light-based measurements and additional information on the various longpass glass filters are provided below and in FIGS. 10a-10c; throughout the remainder of the discussion the filters are referred to by the longpass wavelength cutoff below which they have an optical density (OD) of 2 or higher [λ_{OD2}]).

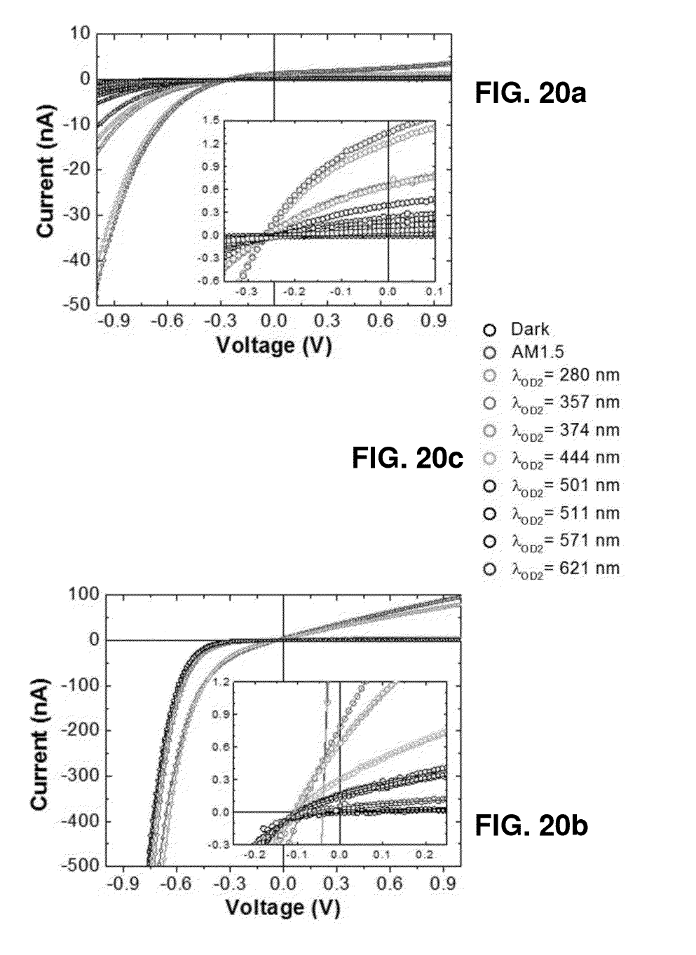

Dark measurements reveal a diode curve for a 100 nm TiO₂/10 nm SrRuO₃ heterostructure (black data, FIG. 15a). A Schottky barrier height of ˜1.3 eV was measured at the TiO₂/SrRuO₃ heterointerface. This measurement was made possible by measuring sister device structures designed to characterize the ITO/TiO₂ interface and fitting the various I-V curves with the diode and Richardson-Nordheim equations to extract the parameters of interest. A complete discussion of all supporting measurements and analyses are provided below and in FIGS. 8a-8c. Under AM1.5G light illumination, the diode curve is shifted in the positive current direction and a photovoltaic response is observed (note that the bias voltage is applied to the top ITO contacts for all measurements). When the vast majority of light absorption in TiO₂ is removed by utilizing longpass glass filters that cut-off light with energies larger than the band gap of TiO₂ (˜3.4 eV for our films as measured via transmission-absorption which corresponds to all longpass glass filters with a A_{OD2} 364 nm), a series of diode curves with short circuit current densities (J_{SC}) of 2-10 μA/cm² are observed. The existence of a J_{SC} that is several orders-of-magnitude larger than the dark current even when illuminated by light with energies below the band gap of TiO₂ clearly demonstrates that the photocurrent is generated from light absorption in the SrRuO₃ (the full set of 1-V data for the various devices as a function of cut-off wavelength are provided below and in FIGS. 20a and 20b).

To glean further information about the nature of the photovoltaic behavior in the TiO₂/SrRuO₃ heterojunctions, the J_{SC} observed is graphed as a function of the longpass glass filter λ_{OD2} for devices with both 10 and 50 nm of SrRuO₃ (FIG. 15b). Again, the J_{SC} values are at least two orders-of-magnitude higher than the dark current (J₀). Recall that the SrRuO₃ has strong, continuous absorption across the entire energy range probed here whereas the TiO₂ only effectively absorbs light with energies above ˜3.4 eV (FIG. 15b). Also observed is an exponential increase of the J_{SC} with decreasing cut-off wavelength which is a key to understanding the mechanism responsible for the visible light activity in these heterojunctions. The exponential dependence of the J_{SC} with λ_{OD2} suggests that fewer photoelectrons are transported over the Schottky barrier between the TiO₂ and SrRuO₃ as the longpass glass filters progressively remove more of the higher energy photons. It is obvious that the absorption of high-energy photons in the SrRuO₃ should result in the excitation of electrons to higher energy states thereby effectively increasing the probability that these excited electrons will have sufficient energy to overcome the Schottky barrier and be transported into the TiO₂. The driving force for this charge injection from the SrRuO₃ into the TiO₂ likely arises from the fact that there is a 4-to-6 order-of-magnitude difference in carrier concentration between TiO₂ (10¹⁶-10¹⁸ cm⁻³) and SrRuO₃ (10²² cm⁻³) which results in the TiO₂ layer being fully depleted and thus possessing a built-in electric field that drives charge extraction from the SrRuO₃. Additionally, it should be noted that the observed trends and values of the J_{SC} for heterojunctions based on both 10 nm and 50 nm SrRuO₃ films are essentially the same. This further supports the argument that the mechanism responsible for the observed photovoltaic effects is not bulk in nature, but arises from an effect near the TiO₂/SrRuO₃ interface since the 50 nm thick film should absorb ˜3.8 times more light than the 10 nm thick film, but both exhibit similar J_{SC} values as a function of cut-off wavelength.

Based on published values of work functions for these materials and the above detailed electronic measurements (see FIGS. 8a-8c), a proposed band diagram for this device is provided (FIG. 15c). The mechanism responsible for the observed effects is hot-carrier injection. Visible light absorption occurs in SrRuO₃ and excites electrons, producing hot carriers which then diffuse freely into the TiO₂. Once in the TiO₂, these hot carriers are swept away from the interface due to the built-in electric field in the depleted TiO₂ and are subsequently collected through the ITO top contacts and are measured as photocurrent. In comparison to previous studies of hot carriers, which relied on the presence of accepting surface states on the TiO₂ accepting photoelectrons from a traditional semiconducting material, in this system the carrier production and injection results from the unique electronic structure and resulting light absorption in the SrRuO₃ and the built-in electric field in the depleted TiO₂. Again, this is the first observation and utilization of the strong light absorption of the “metallic” complex oxide SrRuO₃ and hot-carrier injection in this system in the context of an energy application.

To assess the photocatalytic performance of the TiO₂/SrRuO₃ heterojunctions the photo-degradation of methylene blue (MB) was measured. MB photo-degradation is a widely used method to evaluate the visible light activities of photocatalysts and can be considered as a surrogate to photocatalytic water splitting when comparing one device to another. These studies were achieved using a collimated 300 W Xe arc lamp with an AM1.5G filter and condenser lens to produce 3,760 mW/cm² full AM1.5G spectrum light and 3,280 mW/cm²AM1.50 spectrum light filtered with a λ_{OD2}=416 nm (ΨC-11) longpass glass filter (which removes more than 99.97% of light with energy above the ˜3.4 eV band gap of TiO₂ and is henceforth referred to as UV-filtered light). Further details of the MB studies are provided below and in FIGS. 12a-12d.

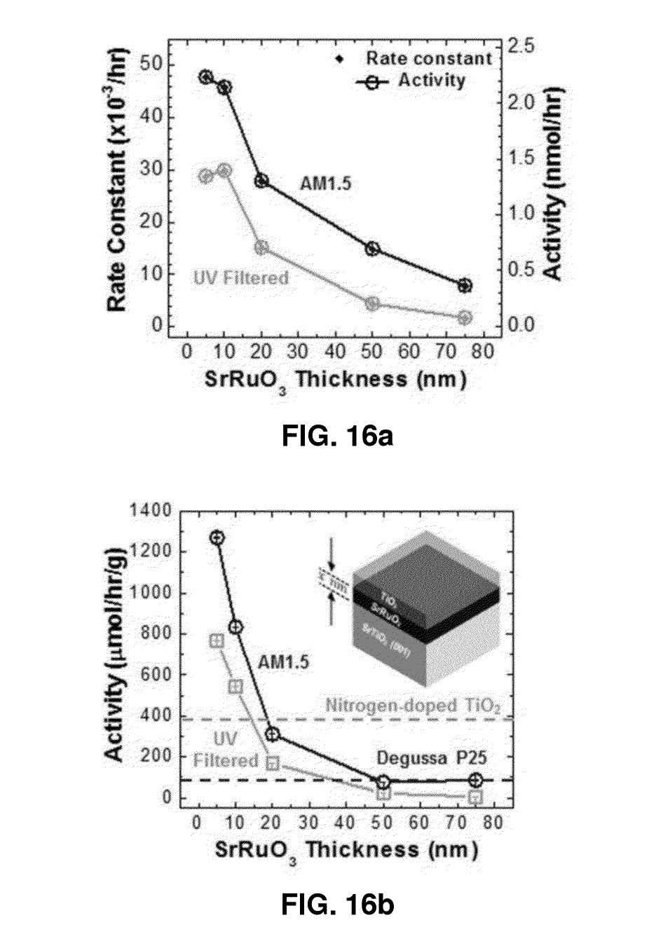

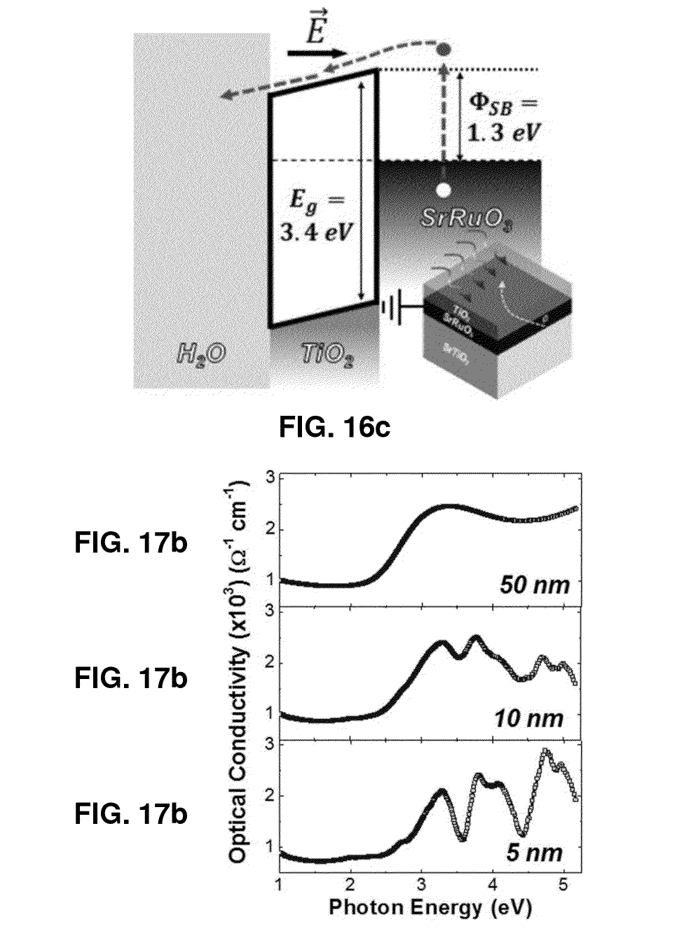

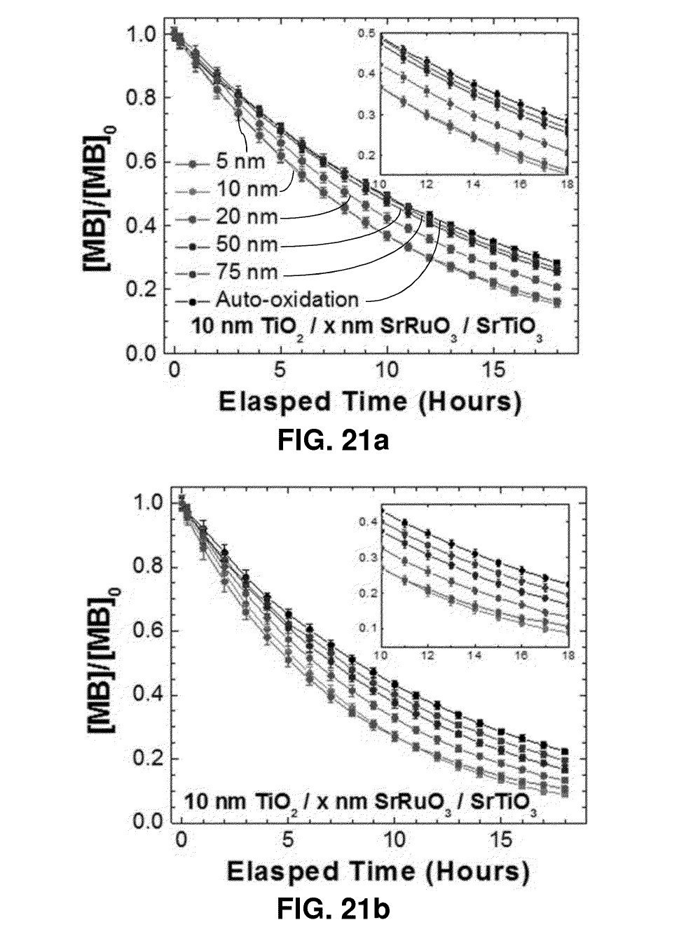

The photocatalytic activity of the heterostructures was studied as a function of the SrRuO₃ thickness and for the range of thicknesses studied, the rate constant and initial reaction rate (activity) was observed to increase with decreasing film thickness under both AM1.5G illumination and UV-filtered light (FIG. 16a) (the normalized MB concentration time trace data for all samples is provided below and in FIGS. 21a and 21b). To put this activity in context, the performance of the TiO₂/SrRuO₃ heterostructures is compared to that of a 10 nm TiO₂/SrTiO₃ control sample as well as other measurements of Degussa P25 and nitrogen-doped TiO₂ nano-powders. For the latter, direct comparisons are made to the results of another which were obtained under similar experimental conditions to those used here, i.e., high intensity light (390 nm laser light with a light intensity of 5,090 mW/cm²), pH=7 solution, and no electrolyte. The mass-normalized activities were compared [obtained by dividing by the total mass of the TiO₂/SrRuO₃ catalyst (assuming the theoretical densities of 6.489 and 4.23 g/cm³ for SrRuO₃ and TiO₂, respectively)] and it was found that the normalized activity of the highest performing TiO₂/SrRuO₃ photocatalyst is more than 3 times higher than the equivalently normalized activity for nitrogen-doped TiO₂ and more than 25 times higher than the Degussa P25 nanopowders (despite use of broad-band illumination with considerably less light intensity) (FIG. 16b). Additionally, the TiO₂/SrRuO₃ heterojunction has 25 times higher mass-normalized activity than the 10 nm TiO₂/SrTiO₃ control sample. This enhanced performance is likely the result of the enhanced light absorption in the SrRuO₃ layer.

To understand the increase in the photocatalytic activity with decreasing SrRuO₃ film thickness, a range of possible explanations was explored including potential electronic, optical, and chemical changes which are summarized here. For instance, based on the proposed model of hot-carrier injection, it was explored whether multiple reflections of the incident light in an ultra-thin film could account for the large thickness dependent increase in the photocatalytic activity due to increased light absorption in the top several nanometers where there is an enhanced probability of such hot-carriers being injected. Based on the measured absorptivity coefficient of SrRuO₃ and the calculated reflectance values for the TiO₂/SrRuO₃ and SrRuO₃/SrTiO₃ interfaces it was found that the amount of light absorbed in the top 2 nanometers of the SrRuO₃ could potentially be increased by ˜40% when going from a 50 nm to 5 nm thick SrRuO₃ film. These calculations included up to 5 passes of the light through the thickness of the films after which the absorbed light intensity was <1% of the initial absorbed intensity. Although impressive, this does not account for the ˜2500% increase in the observed raw photocatalytic activity. Another possible explanation that was considered was that the surface potential (i.e., the reduction/oxidation potential) of the TiO₂ changes as a function of SrRuO₃ thickness. Although plausible, this is unexpected as all heterojunctions studied have TiO₂ films prepared in the same manner with the same phase [anatase], exposed surface facet [(001)], thickness [10 nm], effective defect density, and (as will be expanded upon in the following section) all the TiO₂ films are uniformly depleted by the high carrier concentration of the underlying SrRuO₃ layer. Therefore the surface electrochemical properties of the TiO₂ films are expected to be the same for all heterojunction samples.

Additionally, the evolution of the electronic transport of the SrRuO₃ was explored as a function of thickness. Using temperature- and magnetic field-dependent resistivity studies, the resistivity, carrier density, and mobility for the SrRuO₃ films was extracted as a function of thickness and in TiO₂/SrRuO₃ heterojunctions. The room temperature resistivity (carrier concentration) for 50 nm and 10 nm SrRuO₃ films were found to 227 μΩ-cm (8.43×10²² cm⁻³) and 281 μΩ-cm (8.93×10²² cm⁻³), respectively. Even subsequent growth of a 10 nm TiO₂ layer on the SrRuO₃ film had little effect on the room temperature resistivity and carrier concentrations (267 μΩ-cm and 9.02×10²² cm⁻³, respectively). In all cases the room-temperature carrier mobility was found to be between 0.19-0.25 cm² V⁻¹ s⁻¹. These values are consistent with that expected for SrRuO₃ films from the extensive literature and with prior thickness dependent studies which suggest a critical thickness for changes in the near E_{F} electronic structure (and deviation from the expected metallic and magnetic properties) of 4-5 monolayers (˜1.5-2 nm) and relatively little effect on those properties within the range of thicknesses studied herein (5-50 nm).

Such studies probe the near and below E_{F} electronic structure of materials, but the process of photoexcitation generates electrons at higher energy states which cannot be probed with these techniques. In the context of the proposed mechanism of hot-carrier injection, it is important not only to understand the near and below E_{F} response of the material, but also the above E_{F} opto-electronic response of the material as a function of thickness. To do this, optical conductivity was utilized which is a powerful tool for studying above E_{F} electronic states in materials and can be correlated to the band structure in that it provides a quantitative measurement of the probability of optical transitions convoluted with the electronic DOS. According to Fermi's golden rule, the optical transition rate from an initial state to a final state is a function of the DOS of the initial and final states. For solids, the transition matrix element that describes the nature of this transition also depends on the overlap integral between the initial and final states. In SrRuO₃ the O 2p bands are hybridized with the Ru 4d and the Sr 4d bands resulting in a complex DOS. Researchers have identified a number of possible transitions in this system including transitions from the O 2p to the Ru t_{2g} and e_{g} and the Sr 4d states and additional inter- and intra-atomic transitions (which are possible due to the hybridization with the O 2p bands and/or local distortions) that include transitions from the occupied Ru t_{2g} states to the unoccupied Ru t_{2g} and e_{g} and the Sr 4d states.

The optical conductivity, σ, was calculated from the measured n and k values as σ=nkω/2π. Measurements of the optical conductivity of thick SrRuO₃ films (>25 nm) (FIG. 17a) are consistent with previous reports which reveal a lower optical conductivity to the high-energy side of the Drude peak (not shown in FIGS. 17a-17c) and smooth, undulating features at photon energies greater than ˜2.5 eV. Dramatic differences, however, are observed in thinner films where there is a clear evolution of fine structure and distinct separation of states in the SrRuO₃ optical conductivity spectra (FIGS. 17b and 17c). Although the electronic DOS well above E_{F} has only been studied in bulk-like films and samples (not ultra-thin films), the evolution of sharp features in the DOS is observed across a range of energies in first-principles calculations for ultra-thin SrRuO₃. It is proposed that the observed changes in the optical conductivity are indicative of changes in the electronic structure as noted in the literature and that this change in electronic structure could also produce changes in the excited (above E_{F}) electron dynamics thereby impacting the hot-carriers. To prove such a connection, additional studies of excited carrier dynamics (i.e., transient carrier lifetimes) should be completed. Such experiments, however, are expected to be difficult due to the potentially extremely short-lifetimes of these excited carriers and the relatively high energy of photons needed to probe the features in the optical conductivity and are beyond the scope of this treatment.

In conclusion, it was observed that the “metallic” oxide SrRuO₃ possesses a high absorption coefficient (>1.5×10⁵ cm⁻¹) and low reflectance (<25%) over the entire visible light spectrum due in part to a complex DOS and a nearly continuous range of inter- and intraband excitations that are possible in the material. From light-dark I-V studies, evidence was observed for photon-excited hot-carrier generation and injection from SrRuO₃ to TiO₂. The strong light absorption in SrRuO₃ can, in turn, be used to increase the efficiency of TiO₂ as a photovoltaic and photocatalyst. These novel optical properties and the resulting high photoelectrochemical performance of the TiO₂/SrRuO₃ heterostructures provide an interesting new approach that could advance the field of photocatalysis and further broaden the potential applications of other metallic oxides.

Experimental Section. Synthesis of Materials:

Films were grown using pulsed-laser deposition. Thin films of SrRuO₃ were grown at a laser fluence of 1.05 J/cm² and laser repetition rate of 5 Hz at 660° C. in 100 mTorr of oxygen. Following growth of single-layer SrRuO₃ films, the samples were cooled to room temperature in 760 Torr of oxygen. Thicknesses were measured ex situ via fitting of x-ray diffraction Kiessig fringes and x-ray reflectivity studies. For TiO₂/SrRuO₃ heterostructures, following the growth of the SrRuO₃ layer, the sample was cooled in situ to 600° C. where the TiO₂ layers were deposited at a laser fluence of 0.96 J/cm² and laser repetition rate of 10 Hz in 1 mTorr of oxygen. Following the growth, the films were cooled to room temperature in 1 mTorr of oxygen. All films were examined following growth via x-ray diffraction and atomic force microscopy. All films studied were single-phase, fully epitaxial anatase TiO₂ (00l-oriented) with root-mean-square surface roughness <0.5 nm regardless of the SrRuO₃ thickness. The transparent conducting oxide used in this study was 10% SnO₂-doped In₂O₃ (ITO). 100 nm thick ITO thin films were deposited through photolithography-defined photoresist masks at a laser fluence of 1.0 J/cm² and laser repetition rate of 5 Hz at room temperature in 20 mTorr of oxygen. Following growth and removal of photo-resist, samples were annealed at 300° C. for 30 minutes in 20 mTorr of oxygen and subsequently cooled to room temperature at 20 mTorr to improve electronic and optical properties of the ITO.

Structural Characterization of SrRuO₃ and TiO₂ Films.

The structure and epitaxial relationships between the TiO₂, SrRuO₃, and the underlying substrate SrTiO₃ (001) were obtained using x-ray diffraction (Philips X′ pert MRD-Pro). All films studied in this work were characterized by x-ray diffraction and a typical x-ray diffraction pattern for a TiO₂/SrRuO₃/SrTiO₃ (001) heterostructures is provided (FIG. 18). In all cases, the films were found to be single-phase, anatase TiO₂ and, based on off-axis phi-scan studies, the heterostructures were found to have the following epitaxial relationships: (001)_{TiO}_{₂}/(001)_{SrRuO}_{₃}/(001)_{SrTiO}_{₃} and [100]_{TiO}_{₂}/[100]_{SrRuO}_{₃}/[100]_{SrTiO}_{₃}.

Optical Properties of the SrRuO₃ Thin Films.

A full characterization of the optical properties of the SrRuO₃ films was completed via angle resolved ellipsometry (J. A. Woollam Co, Inc.) (FIGS. 19a 19b) and photospectrometry (Cary 5G, Agilent Technologies) (FIGS. 19c and 19d). For the ellipsometry studies, 5, 10, and 50 nm SrRuO₃/SrTiO₃ (001) heterostructures were measured. This example focuses on the data from 50 nm thin films for brevity. The optical constants (refractive index, n, and extinction coefficient, k) were obtained by fitting a pseudo-n and -k value to generate best-fits to the measured Ψ and Δ using the V.A.S.E. program. The thickness of the SrRuO₃ films was known to within <1% error from x-ray reflectivity measurements and fitting the observed Kiessig fringe peaks from θ-2θ scans. The refractive index (n) ranges from ˜1.7 (at 1.25 eV) to ˜2.33 (at 2.75 eV) to ˜1.8 (at 4.13 eV) (FIG. 19a). The extinction coefficient (k), which is closely related with the absorption behavior of material, is non-zero across the entire range of photon energies studied (1.25 eV to 4.13 eV) (FIG. 19b). This indicates that there is always absorption in the SrRuO₃ across the visible light spectrum. It should be noted that the light absorption in SrRuO₃ is significant in the red/near-IR region (below 2 eV) and above 2.5 eV. The optical conductivity, σ, was calculated from the measured n and k values as σ=nkω/2π.

Studies of transmittance and reflectance of 25 nm, 50 nm, and 100 nm SrRuO₃/SrTiO₃ (001) heterostructures as well as bare SrTiO₃ (001) substrates (as a reference) have been completed. The decreased transmittance (FIG. 19c) and the relatively constant reflectance (FIG. 19d) with increasing SrRuO₃ layer thickness indicate that the absorbance of SrRuO₃ increases with its thickness as would be expected. The absorbance shown above (FIG. 14b) was obtained by subtracting the transmittance and the reflectance from 100 percent incident light. The absorption coefficient (α, FIG. 14b) was calculated from the general Beer-Lambert law using the transmittance of the substrate and the 25 nm SrRuO₃/SrTiO₃ (001) heterostructure. The fact that the reflectance of the SrRuO₃ does not vary much as a function of its thickness suggests that the optical constants are relatively independent of thickness.

Light-Based Measurements of Heterojunctions.

To study the photocurrent response in the TiO₂/SrRuO₃ heterojunctions, a collimated 300 W Xe arc lamp was used with an AM1.5G filter and condenser lens (Newport Corp.). In the case of the current-voltage measurements, the condenser lens was focused into a single-fiber fiber optic cable with a focusing lens at the terminus to produce a light spot 2 mm in diameter on the sample. For the photocatalysis measurements, the same condenser lens assembly was used without the fiber optic cable to give a light spot the shape of an ellipse with major diameter 4 mm and minor diameter 3 mm. To further probe the light-dependent properties, a series of longpass glass filters were utilized to cut-off increasingly larger wavelengths of light from the UV to near-IR range. A table with the various filters used in this study, the longpass optical density of 2 wavelength cut-off (λ_{OD2}), and the transmitted light intensity is provided (FIG. 10a). Graphical representations of the transmitted light from the various longpass glass filters is also shown (FIG. 10b) as are the transmitted light curves for each filter with an AM1.5G spectrum source (FIG. 10c). All of the longpass glass filters have sharp cut-off wavelengths and high transmittance of at least 80% across the remainder of the visible light range.

Schottky Barrier Height and Band Diagram Determination.

To quantitatively determine the band structure of the TiO₂/SrRuO₃ heterojunction, the Schottky barrier height was first characterized between the 10% SnO₂-doped In₂O₃ (ITO) and TiO₂ and then used this information to determine the Schottky barrier height between SrRuO₃ and TiO₂. First, to find the Schottky barrier height between ITO and TiO₂, a 100 nm thick TiO₂ film was prepared on a 0.5% Nb-doped SrTiO₃ (001) substrate. This substrate was chosen because it has a relatively invariant work function of 4.1 eV. Standard microfabrication processes were used to define top contacts of ITO and measured the current-voltage (1-V) characteristics of the devices. The resulting diode curves (in dark) were fit in the forward voltage bias region (FIG. 8a) to the Richardson-Nordheim equation based on thermionic emission:

$${J}_{f} = {A}^{*} {T}^{2} exp ( \frac{- q φ}{kT} ) exp ( \frac{{qV}_{f}}{nkT} ) ,$$

where J_{f} is current density under forward voltage bias, A* (A*=m_{eff}×120 A cm⁻²K⁻²) is the effective Richardson constant, T is the temperature, q is electron charge, k is the Boltzmann constant, V_{f} is the forward voltage bias, and n is ideality factor. With known Richardson constants of 120-150 A cm⁻²K⁻² [the effective mass of anatase TiO₂ ranges from 1.0 to 1.25 m₀], a Schottky barrier height of ˜1.11 eV and an ideality factor of ˜1.5 for the ITO/TiO₂ interface were obtained. Based on this value, proposed band diagram for ITO/TiO₂/0.5% Nb-doped SrTiO₃ was generated (FIG. 8b). Armed with this information about the barrier at this interface, ITO/TiO₂/SrRuO₃ heterostructures were studied. As before, dark diode curves (FIG. 8c) were fit to the Richardson-ordheim equation and combined with the previously measured ITO/TiO₂ Schottky barrier height to give us a Schottky barrier height for the TiO₂/SrRuO₃ interface of ˜1.3 eV (ideality factor ˜2). It should be noted that this measured barrier height between TiO₂ and SrRuO₃ is consistent with the value calculated from the work function of SrRuO₃ (5.2 eV) and the electron affinity of anatase TiO₂ (3.9 eV). Based on the Schottky barrier heights estimated from these two devices (ITO/TiO₂/SrRuO₃ and ITO/TiO₂/Nb-doped SrTiO₃), the proposed band diagrams discussed above were constructed (FIGS. 15c and 16c).

Photocurrent Measurements with Various Longpass Glass Filters. The full set of light and dark current-voltage (I-V) studies of 100 nm ITO/100 nm TiO₂/10 and 50 nm SrRuO₃ Schottky devices are provided (FIGS. 20a and 20b, respectively). All I-V curves show diode behavior. As can be seen, the short circuit current density decreases as more of the high-energy light is cut-off, i.e., increasing the longpass glass filter cut-off wavelength. This effect, as discussed above, is a result of the average hot-carrier energy decreasing and the resulting exponentially decreasing probability that the hot carriers generated in the SrRuO₃ will be injected, over the Schottky barrier, into the TiO₂. Furthermore, comparing the 10 nm SrRuO₃ device to the 50 nm SrRuO₃ device, it was observed that the open circuit voltage changes very little in the former and a great deal in the latter. This can easily be explained by the larger series resistance imparted by the thin (10 nm) SrRuO₃ which dominates over the TiO₂ resistance, even when the device is illuminated by light with energies greater than the TiO₂ band gap energy, meaning that the series resistance of the 10 nm SrRuO₃ changes very little with light illumination thus making the open circuit voltage remain the same.

Methylene Blue Photo-Degradation Studies.

Methylene blue (MB) photo-degradation experiments were performed using a closed-loop test apparatus, which recirculates a MB solution from a reservoir open to atmospheric pressure with an initial concentration of 1.04 ppm in de-ionized water (pH=7) at a flow rate of 13.4 mL/min. The reaction chamber is composed of the mounted sample, a PDMS block with a cylindrical void containing penetrations for incoming and outgoing fluid connections, and a quartz window. This assembly is held in place vertically by a compression plate and the light from the condenser lens was centered on the sample (FIG. 12a, note that the light in the figure is without the condenser lens present for the purposes of obtaining a photograph). The size of the light spot was measured by exposure to thermal paper and was completely contained within the sample area so that no direct light was incident on the electrical connections or the platinum. The samples were mounted on platinum-coated borosilicate glass slides with 2-part epoxy. The total surface area of platinum was repeatedly controlled to be 1.18 cm². Electrical connection was made from the SrRuO₃ to the platinum with silver paint and all electrical connections as well as the sides of the sample and substrate were covered with epoxy to prevent exposure to the solution (FIG. 12b). The samples were run for 2 hours in the dark to establish a base-line for the MB adsorption on the sample and then were exposed to 3,760 mW/cm² full AM1.5G spectrum light and 3,280 mW/cm²AM1.5G spectrum with a λ_{OD2}=416 nm (ΨC-11) longpass glass filter. The MB concentration was measured in situ by light absorption using a tungsten lamp with a Teflon UV-filter and photodetector (Ocean Optics) every minute at the peak light absorption wavelength of MB (665 nm) (FIGS. 12c and 12d).

Control samples (a plain glass slide with no platinum and a 10 nm TiO₂ film (no SrRuO₃) on a platinum-coated slide) were run and the MB decomposition rate was found to be the same for both control samples within the error of the measurement (±5%). The time evolution of the MB solution concentration for each sample was normalized to the initial concentration and the resulting exponential decay curves (FIGS. 21a and 21b) (indicative of a first-order or pseudo-first-order reaction) were fit to find the rate constant, k, i.e., C=C₀e^{-kt}. Because both the control samples and heterostructures had first-order kinetics, the rate constant for the control samples was subtracted from the measured rate constant of the TiO₂/SrRuO₃ heterostructures to determine the rate constant of only the TiO₂/SrRuO₃ heterojunctions.

### REFERENCES

U.S. Patent Application Publications 2010/0051932, 2003/0148881, 2012/0152337, 2013/0065065.
T. A. Abshere, G. L. Richmond, J. Phys. Chem. B 2000, 104, 1602.
P. B. Allen, H. Berger, O. Chauvet, L. Forro, T. Jarborg, A. Junod, B. Revaz, G. Santi, Phys. Rev. B 1996, 53, 4393.
S. Aizaki, T. Yoshida, K. Yoshimatsu, M. Takizawa, M. Minohara, S. Ideta, A. Fujimori, K. Gupta, P. Mahadevan, K. Horiba, H. Kumigashira, M. Oshima, Phys. Rev. Lett. 2012, 109, 056401.
R. Asahi, T. Morikawa, T. Ohwaki, K. Aoki, Y. Taga, Science 2001, 293, 269.
G. Cao, S. McCall, M. Shepard, J. E. Crow, R. P. Guertin, Phys. Rev. B 1997, 56, 321.
Y. J. Chang, C. H. Kim, S.-H. Phark, Y. S. Kim, J. Yu, T. W. Noh, Phys. Rev. Lett. 2009, 103, 057201.
C. L. Chen, Y. Cao, Z. J. Huang, Q. D. Jiang, Z. Zhang, Y. Y. Sun, W. N. Kang, L. M. Dezaneti, W. K. Chu, C. W. Chu, Appl. Phys. Lett. 1997, 71, 1047.
W. Choi, A. Termin, M. R. Hoffmann, J. Phys. Chem. 1994, 98, 13669.
E. Dagotto, T. Hotta, A. Moreo, Phys. Rep. 2001, 344, 1.
E. Dagotto, Y. Tokura, MRS Bull. 2008, 33, 1037.
P. Dougier, J. C. C. Fan, J. B. Goodenough, J. Solid State Chem. 1975, 14, 247.
G. Dresselhaus, M. S. Dresselhaus, Optical Properties of Solids, Ed. J. Tauc, Academic, New York, N.Y. USA 1966.
X. Fang, T. Kobayashi, Appl. Phys. A Suppl. 1999, 69, S587.
M. A. Fox, M. T. Dulay, Chem. Rev. 1993, 92, 341.
K. Fujioka, J. Okamoto, T. Mizokawa, A. Fujimori, I. Hase, M. Abbate, H. J. Lin, C. T. Chen, Y. Takeda, M. Takano, Phys. Rev. B 1997, 56, 6380.
A. Fujishima, X. T. Zhang, D. A. Tryk, Surf. Sci. Rep. 2008, 63, 515.
A. Fujishima, T. N. Rao, D. A. Tryk, J. Photochem. and Photobiology C 2000, 1, 1.
A. Georges, G. Koltiar, W. Krauth, M. J. Rezenberg, Rev. Mod. Phys. 1996, 68, 13.
K.-H. Goetz, D. Bimberg, H. Jurgensen, J. Selders, A. V. Solomonov, G. F. Glinskii, M. Razeghi, J. Appl. Phys. 1993, 54, 4543.
J. L. Gole, J. D. Stout, C. Burda, Y. Lou, X. Chen, J. Phys. Chem. B 2004, 108, 1230.
A. X. Gray, A. Janotti, J. Son, J. M. LeBeau, S. Ueda, Y. Yamashita, K. Kobayashi, A. M. Kaiser, R. Sutarto, H. Wadati, G. A. Sawatzky, C. G. Van de Walle, S. Stemmer, C. S. Fadley, Phys. Rev. B 2011, 84, 075104.
A. J. Hartmann, M. Neilson, R. N. Lamb, K. Watanabe, J. F. Scott, Appl. Phys. A 2000, 70, 239.
H. Huang, D. Li, Q. Lin, W. Zhang, Y. Shao, Y. Chen, M. Sun, X. Fu, Environ. Sci. Technol. 2009, 43, 4164-4168.
Y. J. Hwang, A. Boukai, P. Yang, Nano Lett. 2008, 9, 410.
M. Imada, A. Fujimori, Y. Tokura, Rev. Mod. Phys. 1998, 70, 1039.
G. E. Jellison, L. A. Boatner, J. D. Budai, B.-S. Jeong, D. P. Norton, J. Appl. Phys. 2003, 93, 9537.
H. L. Ju, C. Kwon, Q. Li, R. L. Greene, T. Venkatesan, Appl. Phys. Lett. 1994, 65, 2108.
J. H. Jung, K. H. Kim, D. J. Eom, T. W. Noh, E. J. Choi, J. Yu, Y. S. Kwon, Y. Chung, Phys. Rev. B 1997, 55, 15489.
R. C. Kainthla, B. Zelenay, J. O'M Bockris, J. Electrochem. Soc. 1986, 133, 248.
M. Karolak, T. O. Wehling, F. Lechermann, A. I. Lichtenstein, J. Phys.: Condens. Matter. 2011, 23, 085601.
J. Kim, J. Chung, S.-J. Oh, Phys. Rev. B 2005, 71, 121406.
K. W. Kim, J. S. Lee, T. W. Noh, S. R. Lee, K. Char, Phys. Rev. B 2005, 71, 125104.
Y. J. Kim, B. Gao, S. Y. Han, M. H. Jung, A. K. Chakraborty, T. Ko, C. Lee, W. I. Lee, J. Phys. Chem. C. 2009, 113, 19179-19184.
G. Koster, L. Klein, W. Siemons, G. Rijnders, J. S. Dodge, C.-B. Eom, D. H. A. Blank, M. R. Beasley, Rev. Mod. Phys. 2012, 84, 253.
A. Kowalczyk, A. Slebarski, A. Szajek, J. Baszynski, A. Winiarski, J. Magn. Magn. Mater. 2000, 212, 107.
T. Kudo, M. Tachiki, T. Kashiwai, T. Kobayashi, Jpn. J. Appl. Phys. 1998, 37, L999.
S. Lee, B. A. Apgar, L. W. Martin, Adv. Energy Mater., DOI: 10.1002/aenm.201201116.
S. Lee, Y. Hu, Thin Solid Films 2012, 520, 2238.
J. S. Lee, Y. S. Lee, T. W. Noh, K. Char, Jonghyurk Park, S.-J. Oh, J.-H. Park, C. B. Eom, T. Takeda, R. Kanno, Phys. Rev. B 2001, 64, 245107.
M.-R. Li, J. P. Carbotte, Phys. Rev. B 2002, 66, 155114.
C. Ma, Z. Yang, S. Picozzi, J. Phys.: Condens. Matter. 2006, 18, 7717.
K. Maeda, K. Domen, J. Phys. Chem. Lett. 2010, 1, 2655.
K. Maiti, R. S. Singh, Phys. Rev. B 2005, 71, 161102.
L. W. Martin, Y.-H. Chu, R. Ramesh, Mat. Sci. Eng. R 2010, 68, 89.
R. W. Matthews, Water Res. 1991, 25, 1169.
J. Micallef, B. L. Weiss, Opt. Quant. Electron. 1991, 23, 669.
A. J. Millis, Optical Conductivity and Correlated Electron Physics in Strong Interactions in Low Deminsions, Ed. D. Baeriswyl, L. Degiorgi, Springer-Verlag, Berlin, 2004.
M. Minohara, I. Ohkubo, H. Kumigashira, M. Oshima, Appl. Phys. Lett. 2007, 90, 132123.
M. Minohara, R. Yasuhara, H. Kumigashira, M. Oshima, Phys. Rev. B 2010, 81, 235322.
G. K. Mor, O. K. Varghese, M. Paulose, K. Shankar, C. A. Grimes, Sol. Energ. Mat. Sol. C 2006, 90, 2011.
A. Moreo, S. Yunoki, E. Dagotto, Science 1999, 283, 2034.
S. Mukherjee, R. Ranganathan, P. S. Anilkumar, P. A. Joy, Phys. Rev. B 1996, 54, 9267.
Y. Nagao, A. Yoshikawa, K. Koumoto, T. Kato, Y. Ikuhara, Appl. Phys. Lett. 2010, 97, 172112.
B. Nagaraj, S. Aggarwal, R. Ramesh. J. Appl. Phys. 2001, 90, 375.
L. V. Nomerovannaya, A. A. Makhnev, A. Yu. Rumyantsev, Phys. Solid State 1999, 41(8), 1322.
A. J. Nozik, Appl. Phys. Lett. 1977, 30, 567.
A. J. Nozik, Physica E 2002, 14, 115.
A. J. Nozik, R. Memming, J. Phys. Chem. 1996, 100, 13061.
M. Ocana, W. P. Hsu, E. Matijevic, Langmuir 1991, 7, 2911.
J. Okamoto, T. Mizokawa, A. Fujimori, I. Hase, M. Nohara, H. Takagi, Y. Takeda, M. Takano, Phys. Rev. B 1999, 60, 2281.
B. Oregan, M. A. Gratzel, Nature 1991, 353, 737.
F. E. Osterloh, Chem. Mater. 2008, 20, 35.
E. D. Palik, Handbook of Optical Constants of Solids, Academic Press, Boston, Mass., USA 1985.
A. Paracchino, V. Laport, K. Sivula, M. Graetzel, E. Thimsen, Nature Mater. 2011, 10, 456.
J. Park, S.-J. Oh, J.-H. Park, D. M. Kim, C.-B. Eom, Phys. Rev. B 2004, 69, 085108.
J. Qiu, K.-j. Jin, P. Han, H.-b. Lu, C.-I. Hu, B.-p. Wang, G.-z. Yang, Europhys. Lett. 2007, 79, 57004.
M. Quintana, T. Edvinsson, A. Hagfeldt, G. Boschloo, J. Phys. Chem. C 2007, 111, 1035.
A. D. Rakic, Appl. Opt. 1995, 34, 4755.
P. Ravindran, P. A. Korzhavyi, H. Fjellvag, A. Kjekshus, Phys. Rev. B 1999, 60, 16423.
D. L. Ritums, N. J. Wu, D. Liu, Q. Zhong, Y. M. Chen, X. Zhang, P. C. Chou, A. Ignatiev, Proceedings Of The Tenth IEEE International Symposium On Applications Of Ferroelectrics, Applications of Ferroelectrics, 1996, 2, 417.
J. M. Rondinelli, N. M. Caffrey, S. Sanvito, N. A. Spaldin, Phys. Rev. B 2008, 78, 155107.
S. Sadashivan, S. Aggarwal, T. K. Song, R. Ramesh, J. T. Evans, B. A. Tuttle, W. L. Warren, D. Dimos, J. Appl. Phys. 1998, 83, 2165.
T. Saitoh, T. Mizokawa, A. Fujimori, M. Abbate, Y. Takeda, M. Takano, Phys. Rev. B 1997, 56, 1290.
M. B. Salamon, M. Jaime, Rev. Mod. Phys. 2001, 73, 583.
J. B. Sambur, T. Novet, B. A. Parkinson, Science 2010, 330, 63.
K. M. Satyalakshmi, R. M. Mallya, K. V. Ramanathan, X. D. Wu, B. Brainard, D. C. Gautier, N. Y. Vasanthacharya, M. S. Hegde, Appl. Phys. Lett. 1993, 62, 1233.
A. Sawa, A. Yamamoto, H. Yamada, T. Fujii, M. Kawasaki, J. Matsuno, Y. Tokura, Appl. Phys. Lett. 2007, 90, 252102.
N. Serpone, E. Borgarello, M. Gratzel, J. Chem. Soc. Chem. Commun. 1984, 342.
J. F. Scott, Jpn. J. Appl. Phys. 1999, 38, 2272.
Y. P. Song, R. L. Van Meirhaeghe, W. H. Laflère, F. Cardon, Solid-State Elect 1986, 29, 633.
M. K. Stewart, C.-H. Yee, Jian Liu, M. Kareev, R. K. Smith, B. C. Chapler, M. Varela, P. J. Ryan, K. Haule, J. Chakhalian, D. N. Basov, Phys. Rev. B 2011, 83, 075125.
B. G. Streetman, S. K. Banerjee, Solid State Electronic Devices, Prentice Hall, Englewood Cliffs, N.J., USA, 2006.
H. Tang, K. Prasad, R. Sanjinès, P. E. Schmid, F. Lévy, J. Appl. Phys. 1994, 75, 2042.
W. A. Tisdale, K. J. Williams, B. A. Timp, D. J. Norris, E. S. Aydil, X.-Y. Zhu, Science 2010, 328, 1543.
Y. Tokura, N. Nagaosa, Science 2000, 288, 462.
M. A. Torija, M. Sharma, M. R. Fitzsimmons, M. Varela, C. Leighton, J. Appl. Phys. 2008, 104, 023901.
J. B. Torrance, P. Lacorre, A. I. Nazzal, E. J. Ansaldo, Ch. Niedermayer, Phys. Rev. B 1992, 45, 8209.
D. Toyota, I. Ohkubo, H. Kumigashira, M. Oshima, T. Ohnishi, M. Lippmaa, M. Takizawa, A. Fujimori, K. Ono, M. Kawasaki, H. Koinuma, Appl. Phys. Lett. 2005, 87, 162508.
J. A. Turner, A. J. Nozik, Appl. Phys. Lett. 1982, 41, 101.
A. Urushibara, Y. Moritomo, T. Arima, A. Asamitsu, G. Kido, Y. Tokura, Phys. Rev. B 1995, 51, 14103.
K. Vinodgopal, I. Bedja, P. V. Kamat, Chem. Mater. 1996, 8, 2180.
M. G. Walter, E. L. Warren, J. R. McKone, S. W. Boettcher, Q. Mi, E. A. Santori, N. S. Lewis, Chem. Rev. 2010, 110, 6446.
J. Xia, W. Siemons, G. Koster, M. R. Beasley, A. Kapitulnik, Phys. Rev. B 2009, 79, 140407.
G. Xiong, R. Shao, T. C. Droubay, A. G. Joly, K. M. Beck, S. A. Chambers, W. P. Hess, Adv. Funct. Mater. 2007, 17, 2133.
X. Q. Xu, J. L. Peng, Z. Y. Li, H. L. Ju, R. L. Greene, Phys. Rev. B 1993, 48, 1112.
P. D. Ye, J. Vac. Sci. Technol. A 2008, 26, 697.
P. Y. Yu, M. Cardona, Fundamentals of Semiconductors: Physics and Materials Properties, Springer, New York, N.Y., USA 2005.
A. Zaleska, Rec. Patents Eng. 2008, 2, 157.

### STATEMENTS REGARDING INCORPORATION BY REFERENCE AND VARIATIONS

All references throughout this application, for example patent documents including issued or granted patents or equivalents; patent application publications; and non-patent literature documents or other source material; are hereby incorporated by reference herein in their entireties, as though individually incorporated by reference, to the extent each reference is at least partially not inconsistent with the disclosure in this application (for example, a reference that is partially inconsistent is incorporated by reference except for the partially inconsistent portion of the reference).

All patents and publications mentioned in the specification are indicative of the levels of skill of those skilled in the art to which the invention pertains. References cited herein are incorporated by reference herein in their entirety to indicate the state of the art, in some cases as of their filing date, and it is intended that this information can be employed herein, if needed, to exclude (for example, to disclaim) specific embodiments that are in the prior art. For example, when a compound is claimed, it should be understood that compounds known in the prior art, including certain compounds disclosed in the references disclosed herein (particularly in referenced patent documents), are not intended to be included in the claim.

When a group of substituents is disclosed herein, it is understood that all individual members of those groups and all subgroups and classes that can be formed using the substituents are disclosed separately. When a Markush group or other grouping is used herein, all individual members of the group and all combinations and subcombinations possible of the group are intended to be individually included in the disclosure. As used herein, “and/or” means that one, all, or any combination of items in a list separated by “and/or” are included in the list; for example “1, 2 and/or 3” is equivalent to “‘1’ or ‘2’ or ‘3’ or ‘1 and 2’ or ‘1 and 3’ or ‘2 and 3’ or ‘1, 2 and 3’”.

Every formulation or combination of components described or exemplified can be used to practice the invention, unless otherwise stated. Specific names of materials are intended to be exemplary, as it is known that one of ordinary skill in the art can name the same material differently. One of ordinary skill in the art will appreciate that methods, device elements, starting materials, and synthetic methods other than those specifically exemplified can be employed in the practice of the invention without resort to undue experimentation. All art-known functional equivalents, of any such methods, device elements, starting materials, and synthetic methods are intended to be included in this invention. Whenever a range is given in the specification, for example, a temperature range, a time range, or a composition range, all intermediate ranges and subranges, as well as all individual values included in the ranges given are intended to be included in the disclosure.

As used herein, “comprising” is synonymous with “including,” “containing,” or “characterized by,” and is inclusive or open-ended and does not exclude additional, unrecited elements or method steps. As used herein, “consisting of” excludes any element, step, or ingredient not specified in the claim element. As used herein, “consisting essentially of” does not exclude materials or steps that do not materially affect the basic and novel characteristics of the claim. Any recitation herein of the term “comprising”, particularly in a description of components of a composition or in a description of elements of a device, is understood to encompass those compositions and methods consisting essentially of and consisting of the recited components or elements. The invention illustratively described herein suitably may be practiced in the absence of any element or elements, limitation or limitations which is not specifically disclosed herein.

The terms and expressions which have been employed are used as terms of description and not of limitation, and there is no intention in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

1. A solar terrestrial light absorbing composite comprising:
a chemically-stable catalytic oxide structure; and
a solar terrestrial light absorbing conductive metallic oxide structure positioned in contact with the chemically-stable catalytic oxide;
wherein absorption of electromagnetic radiation by the solar terrestrial light absorbing conductive metallic oxide structure forms charge carriers in the solar terrestrial light absorbing conductive metallic oxide structure that are transferred to the chemically-stable catalytic oxide structure.

2. The solar terrestrial light absorbing composite of claim 1, wherein the solar terrestrial light absorbing conductive metallic oxide structure has an absorption coefficient greater than 1.0×10⁴ cm⁻¹ for electromagnetic radiation having wavelengths between 280 nm and 1000 nm.

3. (canceled)

4. The solar terrestrial light absorbing composite of claim 1, wherein the solar terrestrial light absorbing conductive metallic oxide structure has a reflectance less than 50% for electromagnetic radiation having wavelengths between 280 nm and 1000 nm.

5. (canceled)

6. The solar terrestrial light absorbing composite of claim 1, wherein the solar terrestrial light absorbing conductive metallic oxide structure comprises a film having a thickness of 25 nm or greater and an absorbance greater than 25% for AM1.5G solar spectrum radiation having wavelengths between 280 nm and 1000 nm; or wherein the solar terrestrial light absorbing conductive metallic oxide structure comprises a film having a thickness of 50 nm or greater and an absorbance greater than 40% for AM1.5G solar spectrum radiation having wavelengths between 280 nm and 1000 nm; or wherein the solar terrestrial light absorbing conductive metallic oxide structure comprises a film having a thickness of 100 nm or greater and an absorbance greater than 60% for AM1.5G solar spectrum radiation having wavelengths between 280 nm and 1000 nm.

7. The solar terrestrial light absorbing composite of claim 1, wherein the solar terrestrial light absorbing composite is a visible light absorbing composite or wherein the solar terrestrial light absorbing conductive metallic oxide structure is a visible light absorbing conductive metallic oxide structure.

8. The solar terrestrial light absorbing composite of claim 1, wherein the solar terrestrial light absorbing conductive metallic oxide structure has a carrier concentration greater than 10²⁰ cm⁻³.

9. The solar terrestrial light absorbing composite of claim 1, wherein a ratio of a first carrier concentration of the solar terrestrial light absorbing conductive metallic oxide structure to a second carrier concentration of the chemically-stable catalytic oxide is 1000 or more.

10.-13. (canceled)

14. The solar terrestrial light absorbing composite of claim 1, wherein the solar terrestrial light absorbing conductive metallic oxide structure comprises a correlated metal oxide.

15. (canceled)

16. The solar terrestrial light absorbing composite of claim 1, wherein the solar terrestrial light absorbing conductive metallic oxide structure comprises a metal oxide selected from the group consisting of: SrRuO₃, LaNiO₃, SrVO₃, La_{0.7}Sr_{0.3}MnO₃, La_{0.5}Sr_{0.5}CoO₃, La₁, SrₓMnO₃, La₁, SrₓCoO₃, CaₓSrₓ₋₁RuO₃, Ca₂₋ₓSrₓRuO₄, La₁₋ₓCaₓMnO₃, CaₓSrₓ₋₁VO₃, LaₓSrₓ₋₁VO₃, LaₓSrₓ₋₁NiO₃, Sr₁₋ₓNbO₃, LaₓSr₁₋ₓTiO₃, LaₓSrₓ₋₁CuO₃, LaₓSrₓ₋₁Mn_{y}Co_{1-y}O₃, SrFeO₃, CoₓNi₁₋ₓFeO₄, NiₓMg₁₋ₓFe₂O₄, ZnₓFe₁₋ₓO, SrTiO₃, La₂ₓSr₂₋₂ₓTiO₅, La₂ₓSr₂₋₂ₓTi₃O₃, La₂ₓSr₂₋₂ₓTi₂O₇, Sr₃Ti₂O₇, PbTiO₃, Sm₂Ti₂S₂O₅, K_{2-x-y}RbₓCs_{y}La₂Ti₃O₁₀, PbBi₄Ti₄O₁₅, BaTi₄O₉, K_{2-x-y}RbₓNa_{y}Ti₆O₁₃, La₄CaTi₅O₁₇, TiₓZr_{1.x}(PO₄)₄, Rb₄ₓK₄₋₄ₓTaₘNb₆₋ₘO₁₇, Li_{1-x-y}NaₓKₓTaO₃, La_{1/3}TaO₃, InTaO₄, Sr_{1-x-y}BaₓSn_{y}Ta₂O₆, Ni_{1-x-y}MnₓCo_{y}Ta₂O₆, Cr₁₋ₓFeₓTaO₄, Ca₂Ta₂O₇, BiLa₁₋ₓYₓTaO₇, Sr₂₋₂ₓLa₂ₓTa₂O₇, H₂₋₂ₓK₂ₓLa_{2/3}Ta₂O₇, H₂SrTa₂O₇, K₂Sr_{1.5}Ta₃O₁₀, KBa₂Ta₃O₁₀, Sr₄₋₄ₓBa₄ₓTa₂O₉, Sr₅₋₅ₓBa₅ₓTa₄O₁₅, K₃Ta₃Si₂O₁₃, K₃Ta₃B₂O₁₂, Y_{3-x-y}YbₓGd_{y}TaO₇, LnTaO₄ wherein Ln is La, Ce, Pr, Nd or Sm, RbLnTa₂O₇ wherein Ln is La, Pr, Nd or Sm, M₄Nb₆O₁₇ wherein M is K or Rb and K₄Nb₆O₁₇—TiO₂ intercalated, wherein 0≦x≦1 and wherein 0≦y≦1 and any combination of these.

17. (canceled)

18. (canceled)

19. The solar terrestrial light absorbing composite of claim 1, wherein the solar terrestrial light absorbing conductive metallic oxide structure comprises a metal oxide having a formula Aₘ₊₁MₘO₃ₘ₊₁, AMO₃ or A′_{y}A″_{y-1}MO₃; wherein A, A′ and A″ are independently an alkali metal, an alkaline earth metal, a rare earth metal or a transition metal; wherein M is a transition metal; wherein m is an integer greater than or equal to 1; and wherein 0≦y≦1.

20. The solar terrestrial light absorbing composite of claim 19, wherein A, A′ and A″ are independently Na, K, Ca, Sr, La, Ba, Bi, Pr, Nd, Sm, Gd or Y and wherein M is Ti, V, Cr, Mn, Fe, Co, Ni, Co, Zn, Zr, Nb, Mo, Tc, Ru, or Rh.

21. (canceled)

22. The solar terrestrial light absorbing composite of claim 1, wherein the solar terrestrial light absorbing conductive metallic oxide structure is an epitaxial-oriented film, a (001)-oriented film, a (110)-oriented film or a (111)-oriented film.

23. The solar terrestrial light absorbing composite of claim 1, wherein the solar terrestrial light absorbing conductive metallic oxide structure is a non-epitaxial film or a polycrystalline film.

24. The solar terrestrial light absorbing composite of claim 1, wherein the solar terrestrial light absorbing conductive metallic oxide structure comprises a metal oxide having a perovskite structure.

25. (canceled)

26. The solar terrestrial light absorbing composite of claim 1, wherein the solar terrestrial light absorbing conductive metallic oxide structure comprises a metal oxide having a non-perovskite structure, a pyrochlore structure having a formula A₂BO₇, a wüstite structure having a formula AₓB₁₋ₓO, a magnetite structure having a formula A₂ₓB₂₋₂ₓO₃, a layered perovskite structure having a formula AₘBₘO₃ₘ₊₂, AₘBₘ₋₁O₃ₘ, A_{m/2}BₘO₃ₘ₊₁ or AₘBₘ₋₁O₃ₘ₊₂, a Dion-Jacobsen structure having a formula A[Bₘ₋₁CₘO₃ₘ₊₁], a Ruddlesden-Popper structure having a formula A₂[Bₘ₋₁CₘO₃ₘ₊₁] or Bₘ₋₁CₘO₃ₘ₊₁, an Aurivillius structure having a formula (Bi₂O₂)₂+[Bₘ₋₁CₘO₃ₘ₊₁]²⁻, a Columbite structure having a formula AB₂O₆, a Brownmillerite structure having a formula A₂B₂₋₂ₓC₂ₓO₆ or a Ilmenite structure having a formula ABO₃, wherein A, B and C are independently an alkali metal, an alkaline earth metal, a rare earth metal or a transition metal and wherein m is an integer greater than or equal to 1; and wherein 0≦x≦1.

27. The solar terrestrial light absorbing composite of claim 1, wherein the solar terrestrial light absorbing conductive metallic oxide structure comprises a metal oxide having an oxypnictide structure having a formula LaOₓF₁₋ₓFeAs, LaOₓF₁₋ₓFeAs, CeFeAsOₓF₁₋ₓ, SmFeAsOₓF₁₋ₓ, LaₓY₁₋ₓFeAsO_{y}, NdFeAsOₓF₁₋ₓ, PrFeAsOₓF₁₋ₓ, GdFeAsOₓ or SmFeAsOₓ wherein 0≦x≦1 and wherein 0≦y≦1, or wherein the solar terrestrial light absorbing conductive metallic oxide structure comprises a cuprate superconducting oxide selected from the group consisting of a YBa₂Cu₃O₇ type superconductor, a Bi₂Sr₂Ca₂Cu₃O₁₀ type superconductor HgBa₂Ca₂Cu₃O₈ type superconductor and any combination of these.

28.-30. (canceled)

31. The solar terrestrial light absorbing composite of claim 1, wherein the chemically-stable catalytic oxide structure comprises a semiconducting metal oxide having a band gap greater than or equal to 1.0 eV.

32.-34. (canceled)

35. The solar terrestrial light absorbing composite of claim 1, wherein the chemically-stable catalytic oxide structure comprises a material that makes an electronic contact with the solar terrestrial light absorbing conductive metallic oxide structure that is ohmic in nature, Schottky in nature or flat band.

36. (canceled)

37. (canceled)

38. The solar terrestrial light absorbing composite of claim 1, wherein the chemically-stable catalytic oxide structure comprises titanium dioxide and wherein the solar terrestrial light absorbing conductive metallic oxide structure comprises SrRuO₃, LaNiO₃, SrVO₃, La_{0.7}Sr_{0.3}MnO₃ or La_{0.5}Sr_{0.5}CoO₃.

39.-51. (canceled)

52. The solar terrestrial light absorbing composite of claim 1 comprising an n-n Schottky junction, an n-n ohmic junction, a p-n Schottky junction or a p-n ohmic junction.

53. (canceled)

54. The solar terrestrial light absorbing composite of claim 1, wherein absorption of electromagnetic radiation having a wavelength between 280 nm and 1000 nm by the solar terrestrial light absorbing conductive metallic oxide structure forms photo-excited charge carriers.

55. The solar terrestrial light absorbing composite of claim 1, wherein absorption of electromagnetic radiation having a wavelength between 280 nm and 1000 nm by the solar terrestrial light absorbing conductive metallic oxide structure forms hot-carriers that are injected to the chemically-stable metal oxide from the solar terrestrial light absorbing conductive metallic oxide structure.

56.-60. (canceled)

61. The solar terrestrial light absorbing composite of claim 1 comprising a photovoltaic device, wherein the photovoltaic device comprises:
a substrate and a multilayer film;
wherein a first layer of the multilayer film comprises the solar terrestrial light absorbing conductive metallic oxide structure provided as a layer over at least a portion of the substrate, wherein a second layer of the multilayer film comprises the chemically-stable catalytic oxide structure provided as a layer over and in contact with at least a portion of the first layer and wherein a third layer of the multilayer film comprises a transparent conducting electrode layer provided over and in contact with at least a portion of the second layer.

62.-64. (canceled)

65. The solar terrestrial light absorbing composite of claim 1 comprising a multilayer film comprising a plurality of layers of different solar terrestrial light absorbing conductive metallic oxide structures positioned beneath a layer of the chemically-stable catalytic oxide structure.

66.-82. (canceled)

83. The solar terrestrial light absorbing composite of claim 1 comprising a photocatalytic material, wherein the chemically-stable catalytic oxide structure and the solar terrestrial light absorbing conductive metallic oxide structure are provided as a colloid, an emulsion, a solution, a dispersion, a suspension, a foam, a paint, a coating, a particle, a nanoparticle, a core-shell material, a nanowire, a nanotube, a porous material, a thin film, a thick film, a plate, a ceramic part, a ceramic tile, a gel, a network structure, a mesh, a foil, a gauze, a sponge, a membrane or any combination of these.

84. (canceled)

85. (canceled)

86. A method of creating hot-carriers, the method comprising the steps of:
providing a solar terrestrial light absorbing composite comprising:
a chemically-stable catalytic oxide structure; and
a solar terrestrial light absorbing conductive metallic oxide structure positioned in contact with the chemically-stable catalytic oxide structure;
exposing the solar terrestrial light absorbing composite to solar terrestrial electromagnetic radiation, wherein absorption of electromagnetic radiation by the solar terrestrial light absorbing conductive metallic oxide structure forms charge carriers in the solar terrestrial light absorbing conductive metallic oxide structure that are transferred to the chemically-stable catalytic oxide structure.

87. (canceled)

88. (canceled)

89. A method of generating a photocurrent or a photovoltage, the method comprising the steps of:
providing a photovoltaic device comprising:
a substrate;
a solar terrestrial light absorbing conductive metallic oxide layer provided over at least a portion of the substrate;
a chemically-stable catalytic oxide layer provided over and in contact with at least a portion of the solar terrestrial light absorbing conductive metallic oxide layer; and
a transparent conducting electrode layer provided over and in contact with at least a portion of the chemically-stable catalytic oxide layer; and
exposing the photovoltaic device to solar terrestrial electromagnetic radiation, wherein absorption of electromagnetic radiation by the solar terrestrial light absorbing conductive metallic oxide layer forms charge carriers in the solar terrestrial light absorbing conductive metallic oxide layer that are transferred to the chemically-stable catalytic oxide layer, thereby generating a photocurrent or photovoltage.

90. (canceled)

91. (canceled)

92. A method for photocatalytically oxidizing, reducing or producing radical species from a substance, the method comprising the steps of:
providing a photocatalytic material, wherein the photocatalytic material comprises:
a chemically-stable catalytic oxide structure; and
a solar terrestrial light absorbing conductive metallic oxide structure positioned in contact with the chemically-stable catalytic oxide structure;
contacting the photocatalytic material with the substance;
exposing the photocatalytic material to solar terrestrial electromagnetic radiation, wherein absorption of electromagnetic radiation by the solar terrestrial light absorbing conductive metallic oxide structure forms charge carriers in the solar terrestrial light absorbing conductive metallic oxide structure that are transferred to the chemically-stable catalytic oxide structure; and
oxidizing, reducing or producing radical species from at least a portion of the substance in contact with the photocatalytic material.

93.-99. (canceled)
